(19) United States
(12) Patent Application Publication
(10) Pub. No.: US 2021/0017196 A1
(43) Pub. Date: Jan. 21, 2021

(54) COMPOUND, DISPLAY PANEL AND DISPLAY APPARATUS

(71) Applicant: Shanghai Tianma AM-OLED Co., Ltd., Shanghai (CN)

(72) Inventors: Ying LIU, Shanghai (CN); Wenpeng DAI, Shanghai (CN); Dongyang DENG, Shanghai (CN); Dong JIANG, Shanghai (CN); Yang LI, Shanghai (CN); Yan LU, Shanghai (CN); Hongyan ZHU, Shanghai (CN); Jinghua NIU, Shanghai (CN)

(21) Appl. No.: 17/036,158

(22) Filed: Sep. 29, 2020

(30) Foreign Application Priority Data
Aug. 6, 2020 (CN) 202010781133.2

(51) Int. Cl. C07F 5/02; H01L 51/50; H01L 51/00; H01L 51/42

(52) U.S. Cl. CPC C07F 5/02; H01L 51/5092; H01L 51/4273; H01L 51/008; H01L 51/5096

(57) ABSTRACT

Provided are a compound represented by formula 1, a display panel and display apparatus. In formula 1, L₁-L₅ are each a linking group independently selected from the group consisting of a single bond, C1-C10 alkylene, C6-C30 arylene, C6-C30 fused arylene, C4-C30 heteroarylene, and C4-C30 fused heteroarylene; R₁-R₅ are each independently selected from the group consisting of hydrogen, aryl and heteroaryl; and a, b, c, d, and e are each independently 0, 1, 2, or 3. The compound has a spirane structure containing a boron heterocyclic ring and can be used as a light-emitting host material of OLEDs. By introducing the bipolar host material into the OLED, charge transfer balance is beneficially balanced in the light-emitting layer, which broadens exciton recombination region, simplifies device structure, and improves device efficiency.

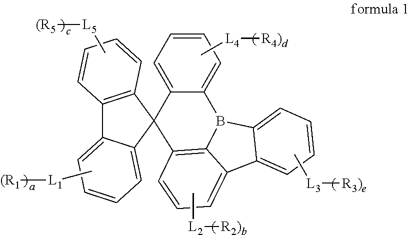

### CROSS-REFERENCE TO RELATED APPLICATION

The present application claims priority to Chinese Patent Application No. 202010781133.2, filed on Aug. 6, 2020, the content of which is incorporated herein by reference in its entirety.

### TECHNICAL FIELD

The present disclosure relates to the technical field of organic electroluminescent materials, and particularly, to a compound that can be used as a light-emitting host material of organic light emitting diodes (OLEDs), and a display panel including the compound, and a display apparatus.

### BACKGROUND

As a new generation of display technology, organic electroluminescent OLEDs have been widely used in flat-panel displays, flexible displays, solid-state lighting and vehicle displays, due to their advantageous low thickness, self-luminousity, wide viewing angle, fast response, high efficiency, good temperature adaptability, simple manufacturing process, low driving voltage, low energy consumption and the like.

Electroluminescence can be classified into electrofluorescence and electrophosphorescence depending upon the luminescence mechanism. Fluorescence is a result of a radiation attenuation transition of singlet excitons, and phosphorescence is a result of light emitted during attenuation transition to the ground state of triplet excitons. According to the spin-statistics theory, a probability ratio of forming singlet excitons and triplet excitons is 1:3. The internal quantum efficiency of the electrofluorescent material is no more than 25%, and the external quantum efficiency is generally less than 5%. Theoretically, the internal quantum efficiency of the electrophosphorescent material can reach 100%, and the external quantum efficiency can be up to 20%. In 1998, Professor Yuguang Ma from Jilin University in China and Professor Forrest from Princeton University in the United States both have reported that ruthenium complexes and platinum complexes were used as dyes doped into the light-emitting layer, a phenomenon of electrophosphorescence was explained, and applied the prepared phosphorescent material to an electroluminescent device.

The long lifetime (s) of phosphorescent heavy metal materials may lead to triplet state-triplet state quenching and concentration quenching at high current densities and further result in a degradation of device performance. Therefore, phosphorescent heavy metal materials are usually doped into suitable host materials to form a host-guest doping system. In this way, energy transfer is enhanced, and luminous efficiency and lifetime are increased. At present, heavy metal doping materials have been commercialized, and however, development of alternative doping materials has proven challenging. Thus, it is urgent to develop a novel phosphorescent host material.

So far, many typical host materials, such as a carbazole derivative, 9,9′-(1,3-phenyl)-di-9H-carbazole (mCP), have been widely used in OLED devices. However, their glass transition temperatures are relatively low (about 55° C.), which leads to poor thermal stability and poor film formation performance, and these materials are unstable during device evaporation. In addition, the lack of electron-withdrawing groups in mCP makes it difficult to realize phase balance between holes and electrons in the OLED devices. Therefore, in order to achieve better OLED device performance, it is necessary to develop more excellent OLED light-emitting host materials.

### SUMMARY

In view of this, the present disclosure provides a compound that can be used as a light-emitting host material, and the compound has a chemical structure represented by formula 1:

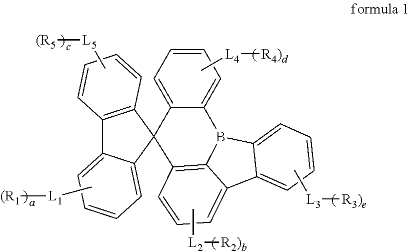

in which, L₁-L₅ are each a linking group independently selected from the group consisting of a single bond, C1-C10 alkylene, C6-C30 arylene, C6-C30 fused arylene, C4-C30 heteroarylene, and C4-C30 fused heteroarylene;

R₁-R₅ are each independently selected from the group consisting of hydrogen, a substituted or unsubstituted phenyl, a substituted or unsubstituted biphenyl, a substituted or unsubstituted naphthyl, a substituted or unsubstituted anthryl, a substituted or unsubstituted phenanthryl, a substituted or unsubstituted acenaphthylenyl, a substituted or unsubstituted pyrenyl, a substituted or unsubstituted perylenyl, a substituted or unsubstituted fluorenyl, a substituted or unsubstituted spirobifluorenyl, a substituted or unsubstituted chrysenyl, a substituted or unsubstituted triphenylenyl, a substituted or unsubstituted benzoanthryl, a substituted or unsubstituted fluoranthenyl, a substituted or unsubstituted picenyl, a substituted or unsubstituted furyl, a substituted or unsubstituted benzofuryl, a substituted or unsubstituted dibenzofuryl, a substituted or unsubstituted thienyl, a substituted or unsubstituted benzothienyl, a substituted or unsubstituted dibenzothienyl, a substituted or unsubstituted triazinyl, a substituted or unsubstituted phenanthrolinyl, a substituted or unsubstituted quinolinyl, carbazolyl and a carbazolyl-derived group, acridinyl and an acridinyl-derived group, diphenylamino and a diphenylamino-derived group, and triphenylamino and a triphenylamino-derived group;

and a, b, c, d, and e are each independently 0, 1, 2, or 3.

### BRIEF DESCRIPTION OF DRAWINGS

FIG. 1 is a formula of a compound provided by an embodiment of the present disclosure;

FIG. 2 is a schematic structural diagram of an OLED device provided by an embodiment of the present disclosure; and

FIG. 3 is a schematic diagram of a display apparatus provided by an embodiment of the present disclosure.

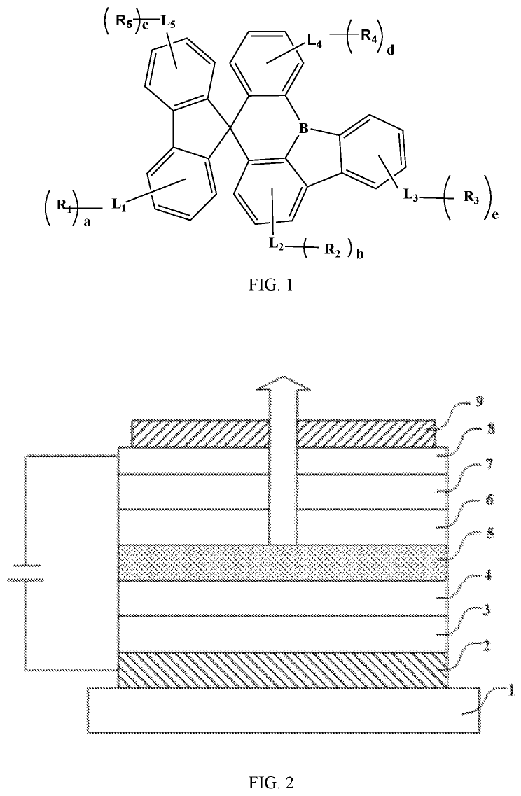

### DESCRIPTION OF EMBODIMENTS

The present disclosure will be further described below through examples and comparative examples. The following examples are only used to illustrate the present disclosure, but not to limit the present disclosure. Without departing from the scope of the technical solution of the present disclosure, any modification or equivalent replacement of the technical solution of the present disclosure should be included in the protection scope of the present disclosure.

One aspect of the present disclosure provides a compound having a chemical structure represented by formula 1:

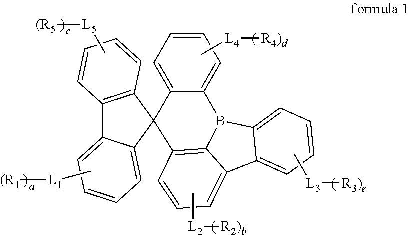

in which, L₁-L₅ are each a linking group independently selected from the group consisting of a single bond, C1-C10 alkylene, C6-C30 arylene, C6-C30 fused arylene, C4-C30 heteroarylene, and C4-C30 fused heteroarylene;

R₁-R₅ are each independently selected from the group consisting of hydrogen, a substituted or unsubstituted phenyl, a substituted or unsubstituted biphenyl, a substituted or unsubstituted naphthyl, a substituted or unsubstituted anthryl, a substituted or unsubstituted phenanthryl, a substituted or unsubstituted acenaphthylenyl, a substituted or unsubstituted pyrenyl, a substituted or unsubstituted perylenyl, a substituted or unsubstituted fluorenyl, a substituted or unsubstituted spirobifluorenyl, a substituted or unsubstituted chrysenyl, a substituted or unsubstituted triphenylenyl, a substituted or unsubstituted benzoanthryl, a substituted or unsubstituted fluoranthenyl, a substituted or unsubstituted picenyl, a substituted or unsubstituted furyl, a substituted or unsubstituted benzofuryl, a substituted or unsubstituted dibenzofuryl, a substituted or unsubstituted thienyl, a substituted or unsubstituted benzothienyl, a substituted or unsubstituted dibenzothienyl, a substituted or unsubstituted triazinyl, a substituted or unsubstituted phenanthrolinyl, a substituted or unsubstituted quinolinyl, carbazolyl and a carbazolyl-derived group, acridinyl and an acridinyl-derived group, diphenylamino and a diphenylamino-derived group, and triphenylamino and a triphenylamino-derived group; and

a, b, c, d, and e are each independently 0, 1, 2, or 3.

In the compound of the present disclosure, the spirane structure has relatively weaker conjugation, which can increase a triplet energy level of the compound, thereby enhancing solubility of the material. The compounds having the spirane structure and containing a boron heteroatom are molecular building blocks centered by sp3 hybridized carbon atom and having broken 7-conjugate with a spatially orthogonal configuration. The compounds having the spirane structure and containing a boron heteroatom have a spiro conjugation effect caused by the broken 7-conjugation, which is beneficial to increase the triplet energy level of the compound. The compounds having the spirane structure have good chemical stability, electrochemical stability and photochemical stability, also have a high glass transition temperature, and thus have high thermal stability.

The compound of the present disclosure is a compound having a structure in which a boron heterobiphenyl serves as an electron-accepting group, and the boron heterocycle is spiro-conjugated with the fluorenyl group. The compound, when used as a host material in an electroluminescent device, has a higher triplet energy level ET, a higher molecular density, a higher glass transition temperature and a higher molecular thermal stability, and thus it can effectively improve a equilibrium migration of carriers, broaden the exciton recombination region and effectively improve the light extraction efficiency, thereby increasing a light-emitting efficiency and lifetime of the device to a great extent.

The molecular structure of the compound of the present disclosure is conducive to the combination of holes and electrons to generate excitons, thereby improving the electron mobility of the material and improving the efficiency of the device.

In an embodiment of the compound of the present disclosure, L₁ and L₂ are each independently selected from the group consisting of phenylene, naphthylene, anthrylene, phenanthrylene, pyridylidene, furylidene, pyrimidinylidene, triazinylene, benzofurylene, thienylene, benzothienylene, pyrrolylene, indolylidene, carbazolylene, oxazolylene, benzoxazolylene, thiazolylene, benzothiazolylene, imidazolylene, benzoimidazolylene, indazolylene, quinolylene, and isoquinolylene.

According to an embodiment of the compound of the present disclosure, three of L₁-L₅ are each a single bond, and the remaining two of L-L₅ are each a connecting group selected from the group consisting of C1-C10 alkylene, C6-C30 arylene, C6-C30 fused arylene, C4-C30 heteroarylene, and C4-C30 fused heteroarylene; three of R₁-R₅ are hydrogen, and the remaining two of R₁-R₅ are substituents other than hydrogen. One of the substituents other than hydrogen is an electron-donating group, and the other one is an electron-accepting group. Under such a limitation, the compound itself is more flexible, thereby improving the solubility of the compound. Moreover, since R₁-R₅ include both an electron-donating group and an electron-accepting group, the energy level of the compound can be further adjusted, and thus the compound has a higher matching with other organic functional layers.

According to an embodiment of the compound of the present disclosure, R₁-R₅ are each independently selected from the following groups:

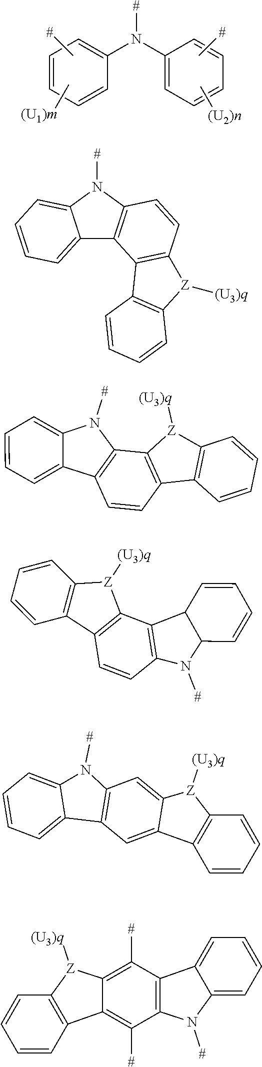

in which, U₁ and U₂ are each independently selected from the group consisting of hydrogen, C1-C6 alkyl, C1-C6 alkoxy, and C6-C12 aryl; m and n are each independently 0, 1, or 2;

Z is a carbon atom, a nitrogen atom, an oxygen atom or a sulfur atom;

U₃ is selected from the group consisting of hydrogen, C1-C6 alkyl, C1-C6 alkoxy, and C6-C12 aryl; q is 0, 1, or 2; when Z is an oxygen atom or a sulfur atom, q is 0; and

# indicates a possible bonding position.

According to an embodiment of the compound of the present disclosure, R₁-R₅ are each independently selected from the following groups:

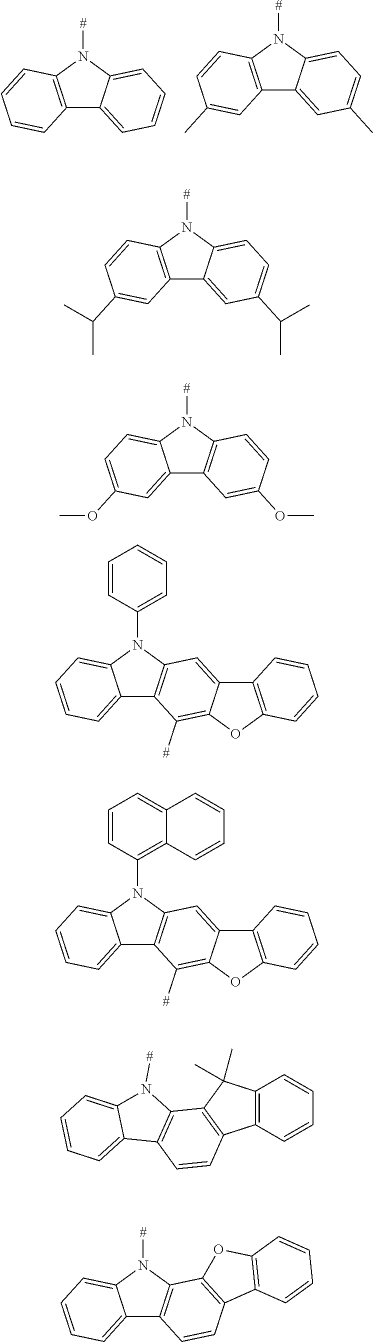

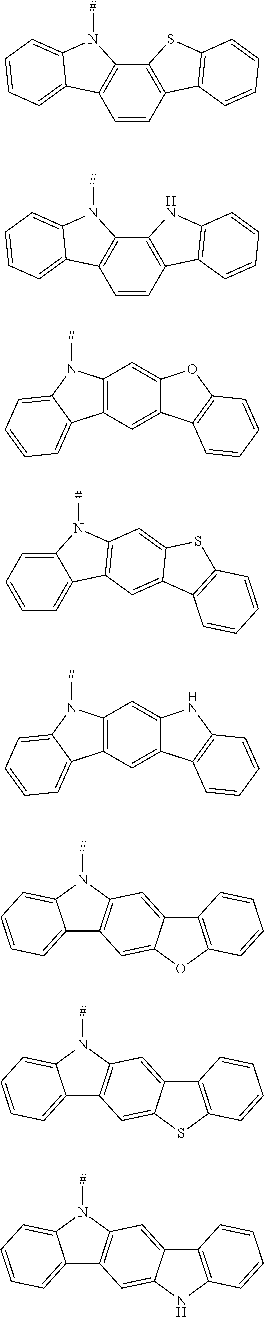

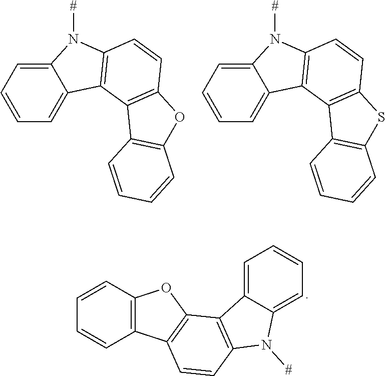

Carbazole-like groups are a type of weaker electron-donating groups with twisted molecular structures. A red shift effect of molecular spectrum can be effectively avoided in the compound of the present disclosure when the compound includes the carbazole-like group and is used in an organic light-emitting device.

According to an embodiment of the compound of the present disclosure, D₁ and D₂ are each independently selected from the following groups.

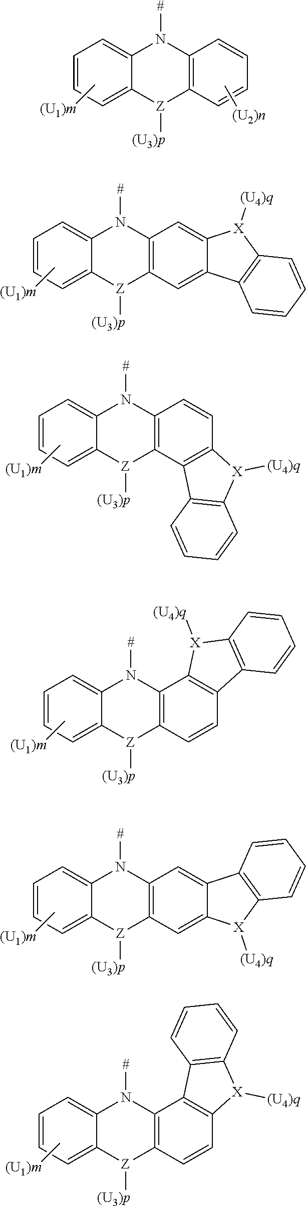

in which, U₁ and U₂ are each independently selected from the group consisting of hydrogen, C1-C6 alkyl, C3-C6 cycloalkyl, C1-C6 alkoxy, C6-C12 aryl, and a substituted or unsubstituted C12-C20 diphenylamino; m and n are each independently 0, 1, or 2;

Z is selected from the group consisting of C, N, O, S and Si; X is a carbon atom, a nitrogen atom, an oxygen atom, a sulfur atom, or a silicon atom;

U₃ and U₄ are each independently selected from the group consisting of hydrogen, C1-C6 alkyl, C3-C6 cycloalkyl, C1-C6 alkoxy, C6-C12 aryl, and a substituted or unsubstituted C12-C20 diphenylamino; p and q are each independently 0, 1 or 2; when Z or X is an oxygen atom or a sulfur atom, p or q is 0; and

# indicates a bonding position.

According to an embodiment of the compound of the present disclosure, R₁-R₅ are each independently selected from the following groups:

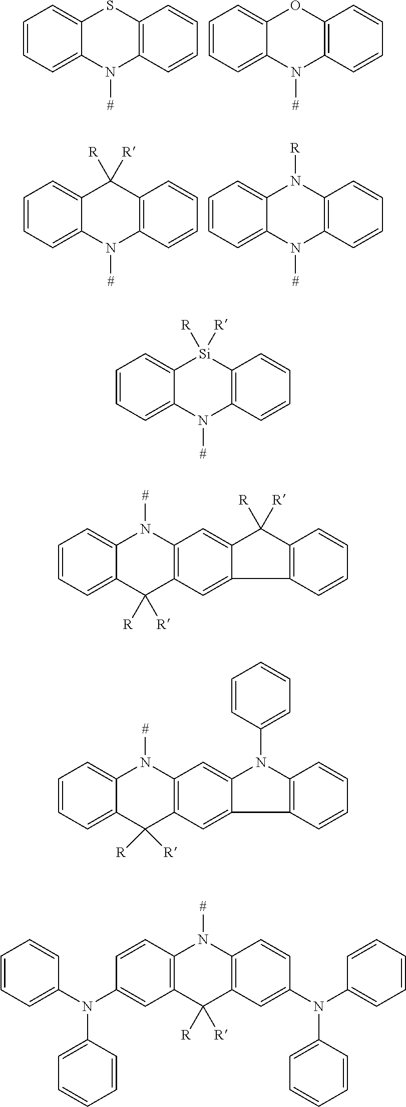

in which, R and R′ are each independently selected from the group consisting of hydrogen, C1-C6 alkyl, C1-C6 alkoxy, C1-C6 cycloalkyl, C6-C12 aryl, and C4-C12 heteroaryl.

Acridine-like groups, such as phenothiazinyl, phenoxazinyl, etc., have good morphological stability. When an acridine-like group is introduced into the molecules of the compounds of the present disclosure and the compound is applied to an organic light-emitting device, it is conducive to a formation of amorphous film, thereby improving the stability of the organic film in the organic light-emitting device.

According to an embodiment of the compound of the present disclosure, R₁-R₅ are each independently selected from the following groups:

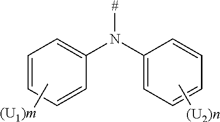

in which U₁ and U₂ are each independently selected from the group consisting of hydrogen, C1-C6 alkyl, and C1-C6 alkoxy;

m and n are each independently 0, 1, or 2; and

# indicates a bonding position.

According to an embodiment of the compound of the present disclosure, R₁-R₅ are each independently selected from the following groups:

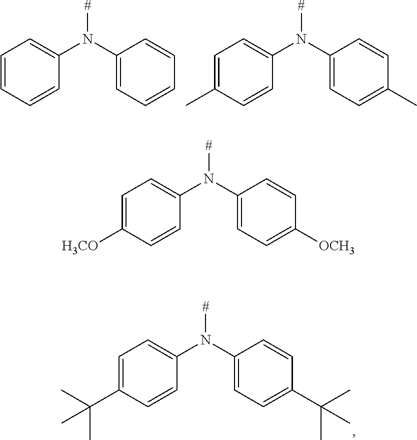

in which # indicates a bonding position.

Phenylamine-like groups can be considered as another type of carbazole-like groups with weaker rigidity, which have better thermal stability and hole transmission properties. When a phenylamine-like group is introduced into molecules and the compound is applied to an organic light-emitting device, the charge transfer performance can be effectively balanced.

According to an embodiment of the compound of the present disclosure, one of R₁-R₅ is carbazolyl, and another one of R₁-R₅ is an azaaromatic group. In this embodiment, the one of R₁ to R₅ is an electron-donating group (i.e., carbazolyl), another one of R₁ to R₅ is an electron-accepting group (i.e., the azaaromatic group). The presence of both of the two groups in the compound of the present disclosure can adjust the HOMO and LUMO energy levels, and thus the compound can have a better compatibility with other organic layer materials.

According to an embodiment of the compound of the present disclosure, one to four of R₁-R₅ are selected from the group consisting of triphenylamino, carbazolyl, biphenyl, and naphthyl, and the remaining group of R₁-R₅ is selected from the group consisting of hydrogen, phenanthrolinyl, and triazinyl. In the embodiment, the boron-containing core structure determines the LUMO energy level, and the HOMO energy level of the molecule can be adjusted by triarylamine, carbazolyl, biphenyl and naphthyl, and the LUMO energy level can be finely tuned by the electron-accepting group of phenanthrolinyl or triazinyl.

In the compound of the present disclosure, the spiro ring core structure containing the boron heterocyclic ring has a relatively strong electron transmission ability. By connecting triphenylamino, carbazolyl, biphenyl or naphthyl to the core structure, a suitable HOMO energy level provided, which is beneficial to the transmission of holes. By connecting phenanthrolinyl or triazinyl to the core structure, the LUMO energy level can be adjusted, thereby achieving carrier balance and improving the light-emitting efficiency.

According to an embodiment of the compound of the present disclosure, the compound is independently selected from the following compounds:

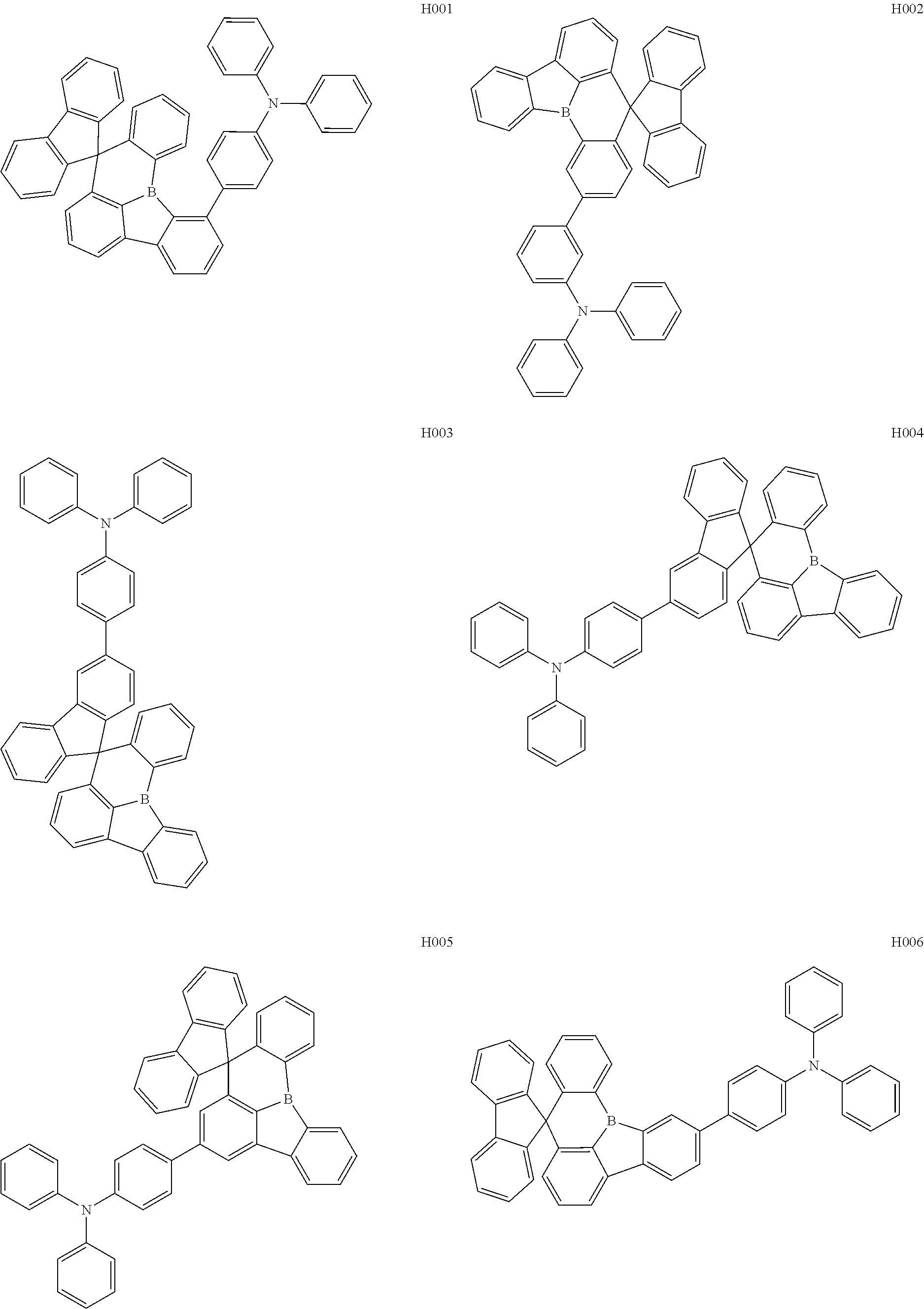

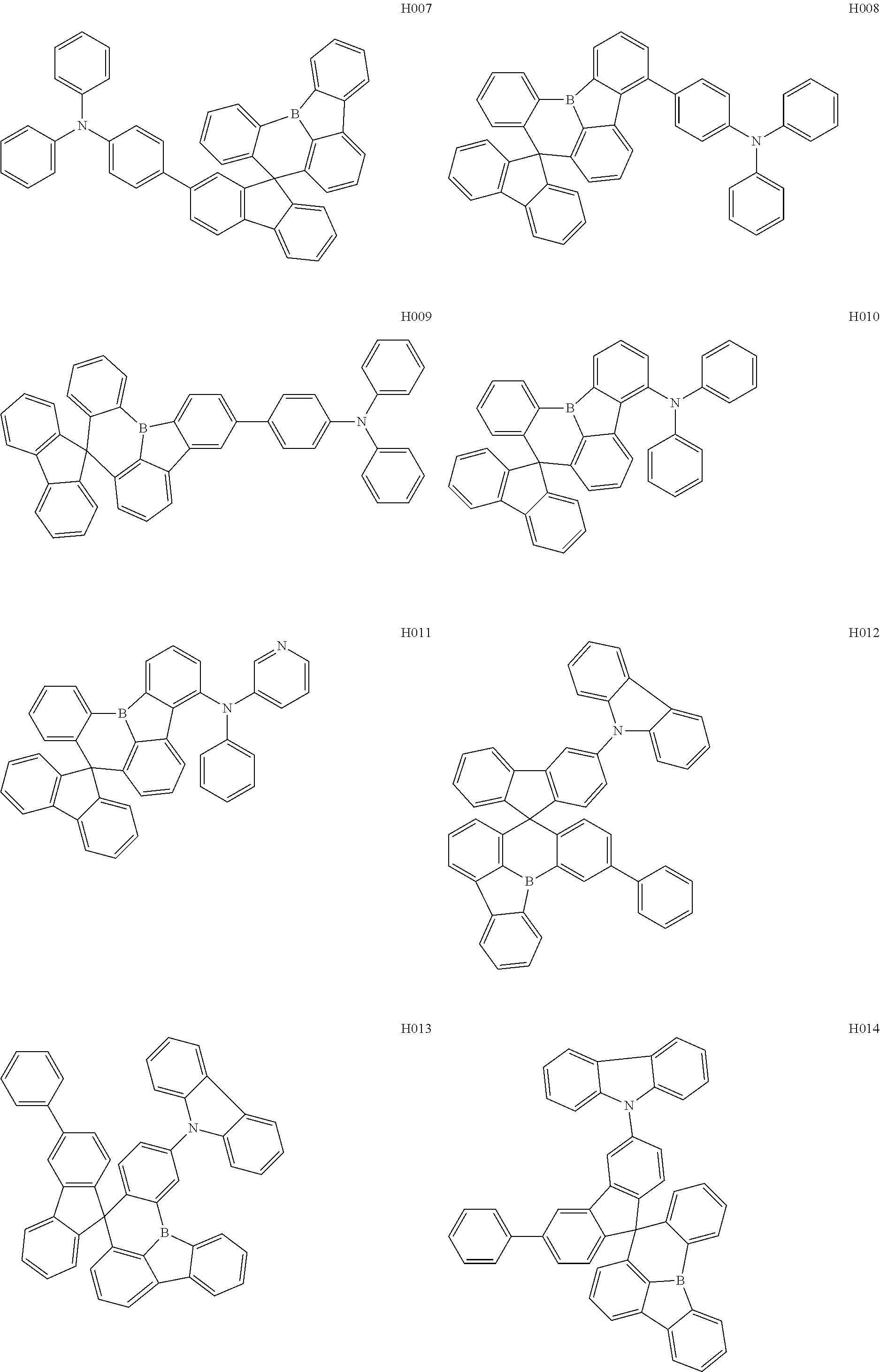

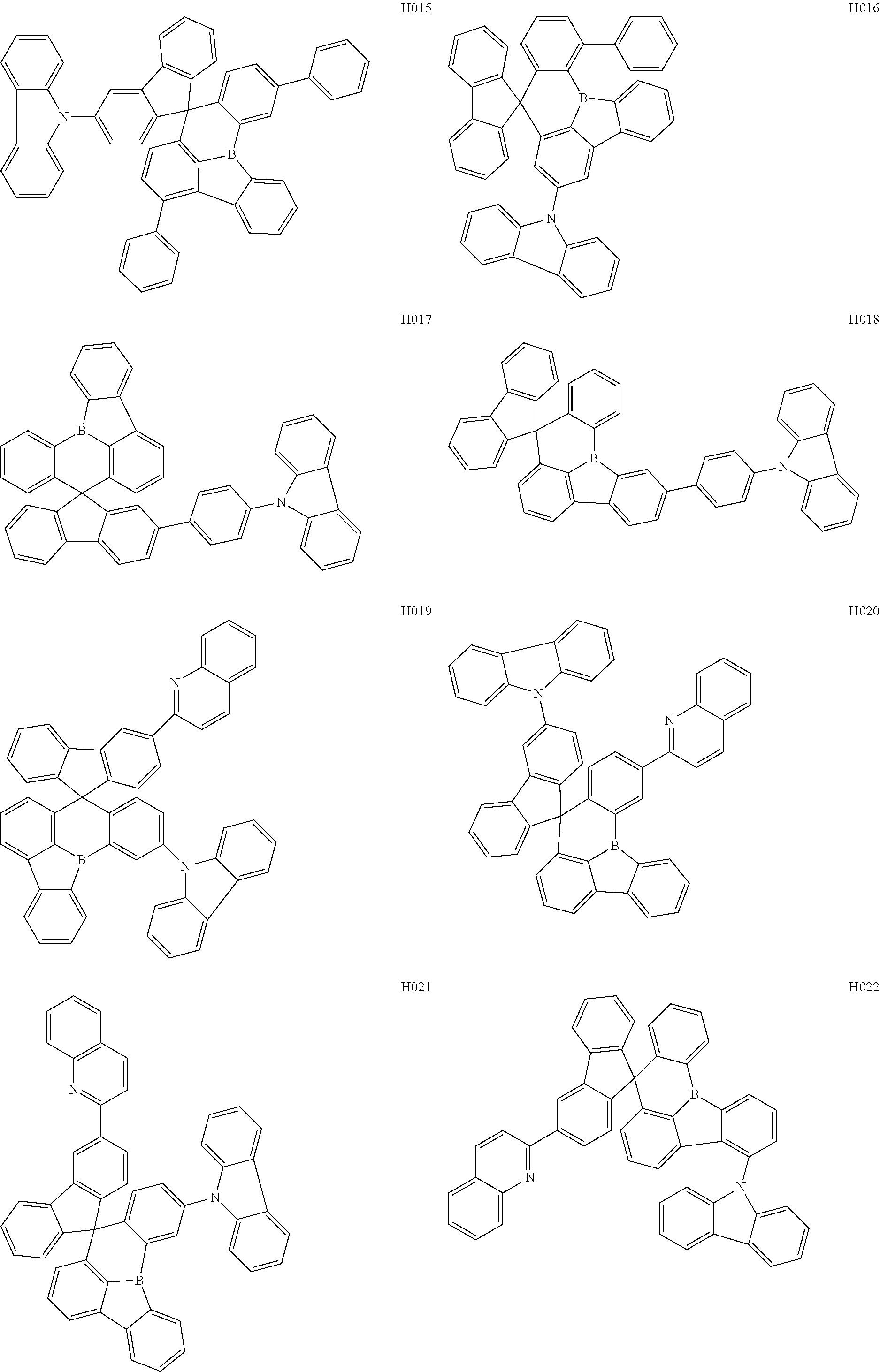

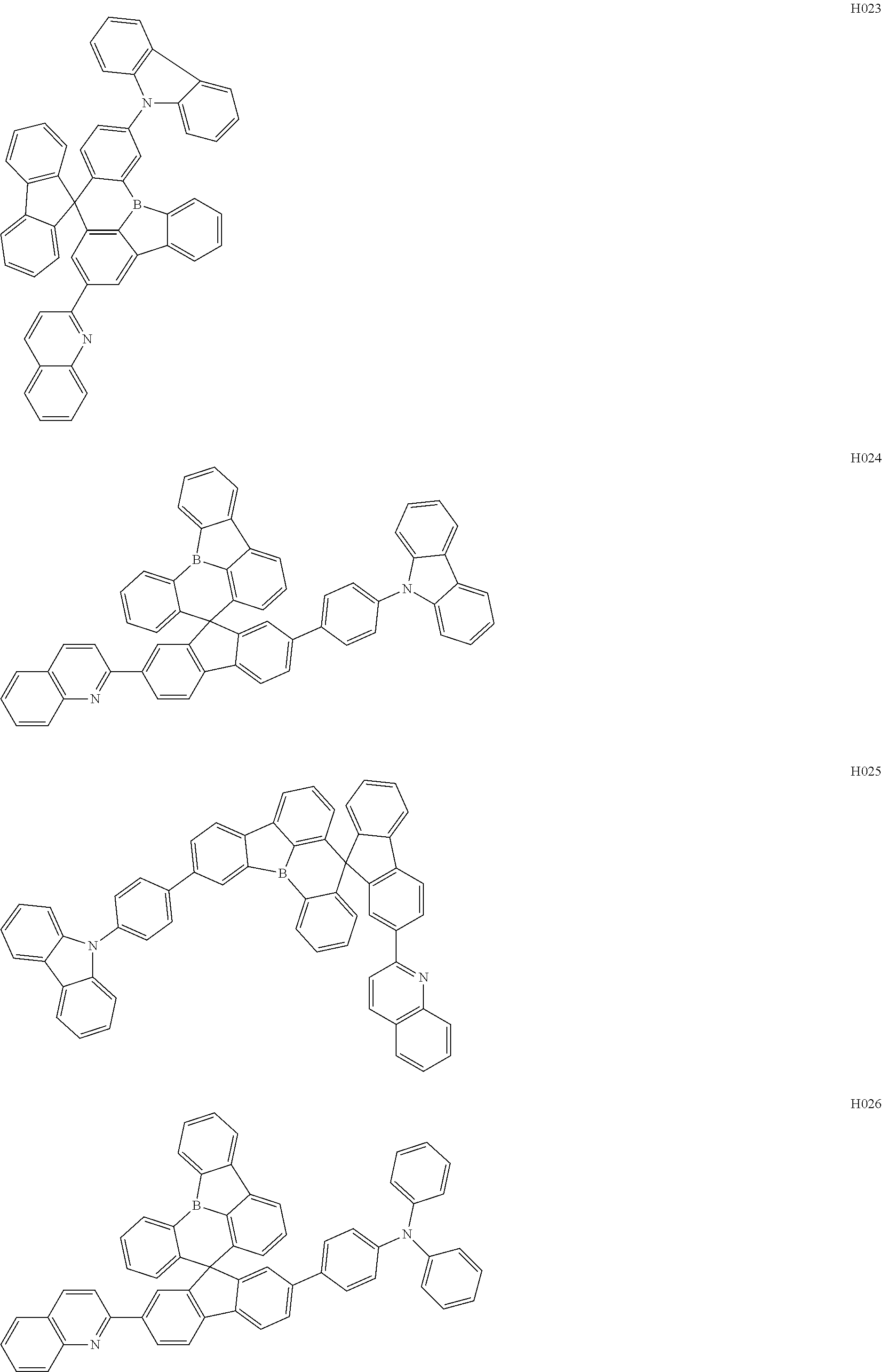 [SMILES: c1ccc2c(c1)B1c3cc(-n4c5ccccc5c5ccccc54)ccc3C3(c4ccccc4-c4ccccc43)c3cc(-c4ccc5ccccc5n4)cc-2c31 ; c1ccc2c(c1)B1c3ccccc3C3(c4cc(-c5ccc(-n6c7ccccc7c7ccccc76)cc5)ccc4-c4ccc(-c5ccc6ccccc6n5)cc43)c3cccc-2c31 ; c1ccc2c(c1)B1c3cc(-c4ccc(-n5c6ccccc6c6ccccc65)cc4)ccc3-c3cccc(c31)C21c2ccccc2-c2ccc(-c3ccc4ccccc4n3)cc21 ; c1ccc(N(c2ccccc2)c2ccc(-c3ccc4c(c3)C3(c5ccccc5B5c6ccccc6-c6cccc3c65)c3cc(-c5ccc6ccccc6n5)ccc3-4)cc2)cc1]

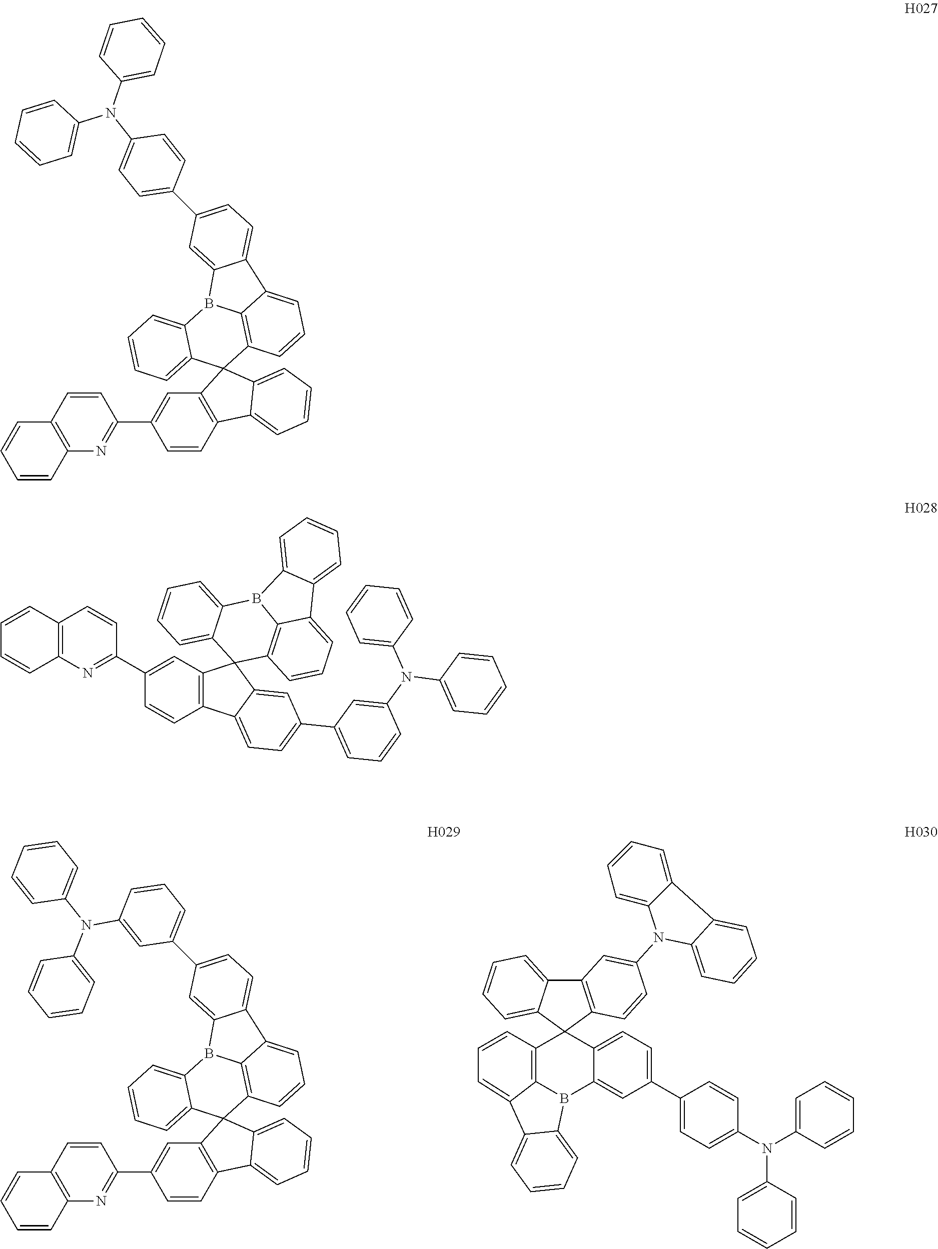 [SMILES: c1ccc(N(c2ccccc2)c2ccc(-c3ccc4c(c3)B3c5ccccc5C5(c6ccccc6-c6ccc(-c7ccc8ccccc8n7)cc65)c5cccc-4c53)cc2)cc1 ; c1ccc(N(c2ccccc2)c2cccc(-c3ccc4c(c3)C3(c5ccccc5B5c6ccccc6-c6cccc3c65)c3cc(-c5ccc6ccccc6n5)ccc3-4)c2)cc1 ; c1ccc(N(c2ccccc2)c2cccc(-c3ccc4c(c3)B3c5ccccc5C5(c6ccccc6-c6ccc(-c7ccc8ccccc8n7)cc65)c5cccc-4c53)c2)cc1 ; c1ccc(N(c2ccccc2)c2ccc(-c3ccc4c(c3)B3c5ccccc5-c5cccc(c53)C43c4ccccc4-c4cc(-n5c6ccccc6c6ccccc65)ccc43)cc2)cc1]

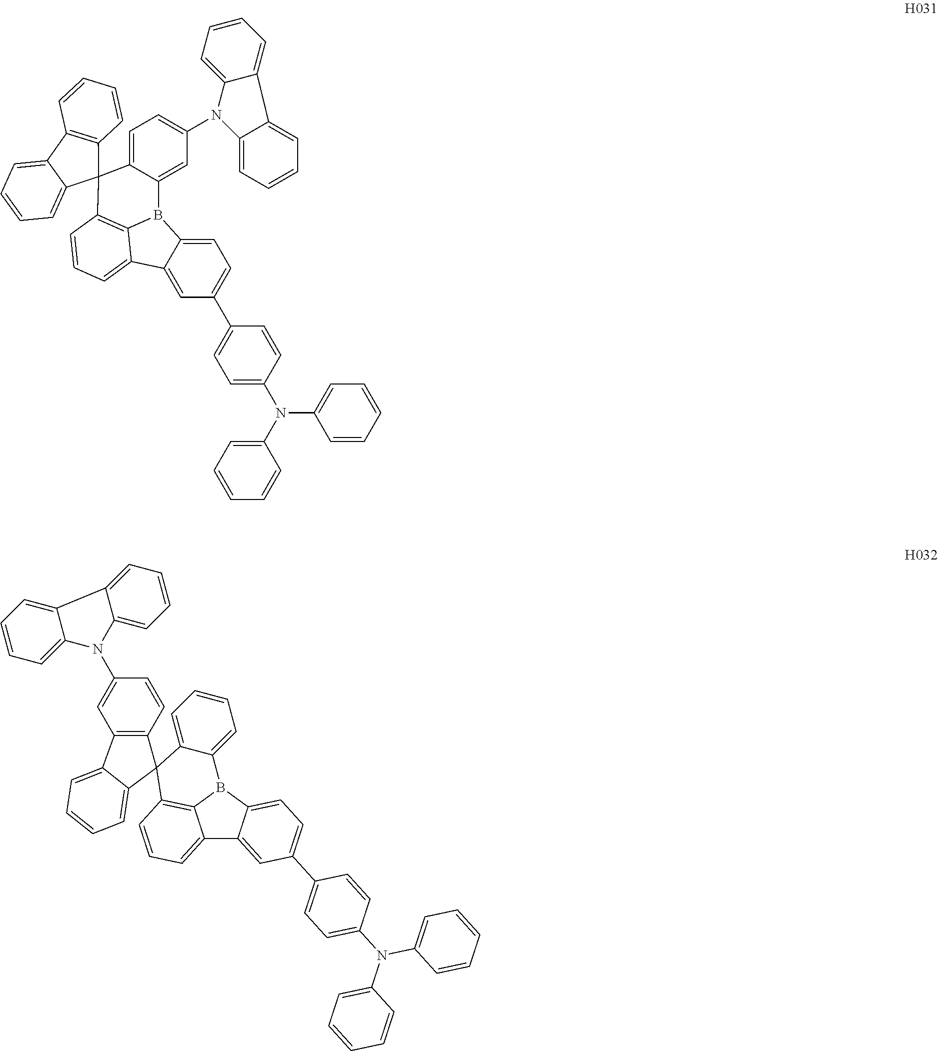 [SMILES: c1ccc(N(c2ccccc2)c2ccc(-c3ccc4c(c3)-c3cccc5c3B4c3cc(-n4c6ccccc6c6ccccc64)ccc3C53c4ccccc4-c4ccccc43)cc2)cc1 ; c1ccc(N(c2ccccc2)c2ccc(-c3ccc4c(c3)-c3cccc5c3B4c3ccccc3C53c4ccccc4-c4cc(-n5c6ccccc6c6ccccc65)ccc43)cc2)cc1]

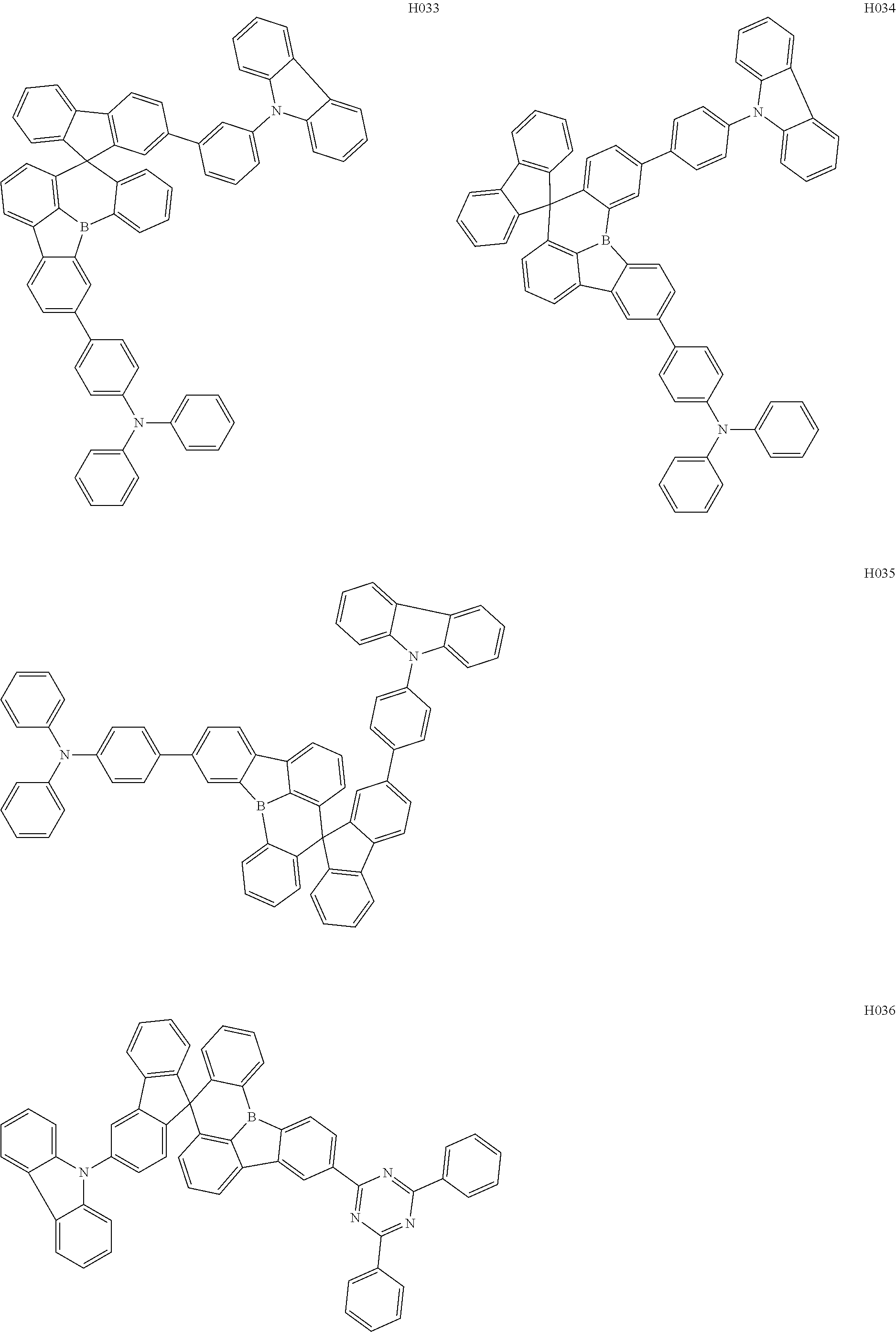 [SMILES: c1ccc(N(c2ccccc2)c2ccc(-c3ccc4c(c3)B3c5ccccc5C5(c6ccccc6-c6ccc(-c7cccc(-n8c9ccccc9c9ccccc98)c7)cc65)c5cccc-4c53)cc2)cc1 ; c1ccc(N(c2ccccc2)c2ccc(-c3ccc4c(c3)-c3cccc5c3B4c3cc(-c4ccc(-n6c7ccccc7c7ccccc76)cc4)ccc3C53c4ccccc4-c4ccccc43)cc2)cc1 ; c1ccc(N(c2ccccc2)c2ccc(-c3ccc4c(c3)B3c5ccccc5C5(c6ccccc6-c6ccc(-c7ccc(-n8c9ccccc9c9ccccc98)cc7)cc65)c5cccc-4c53)cc2)cc1 ; c1ccc(-c2nc(-c3ccccc3)nc(-c3ccc4c(c3)-c3cccc5c3B4c3ccccc3C53c4ccccc4-c4cc(-n5c6ccccc6c6ccccc65)ccc43)n2)cc1]

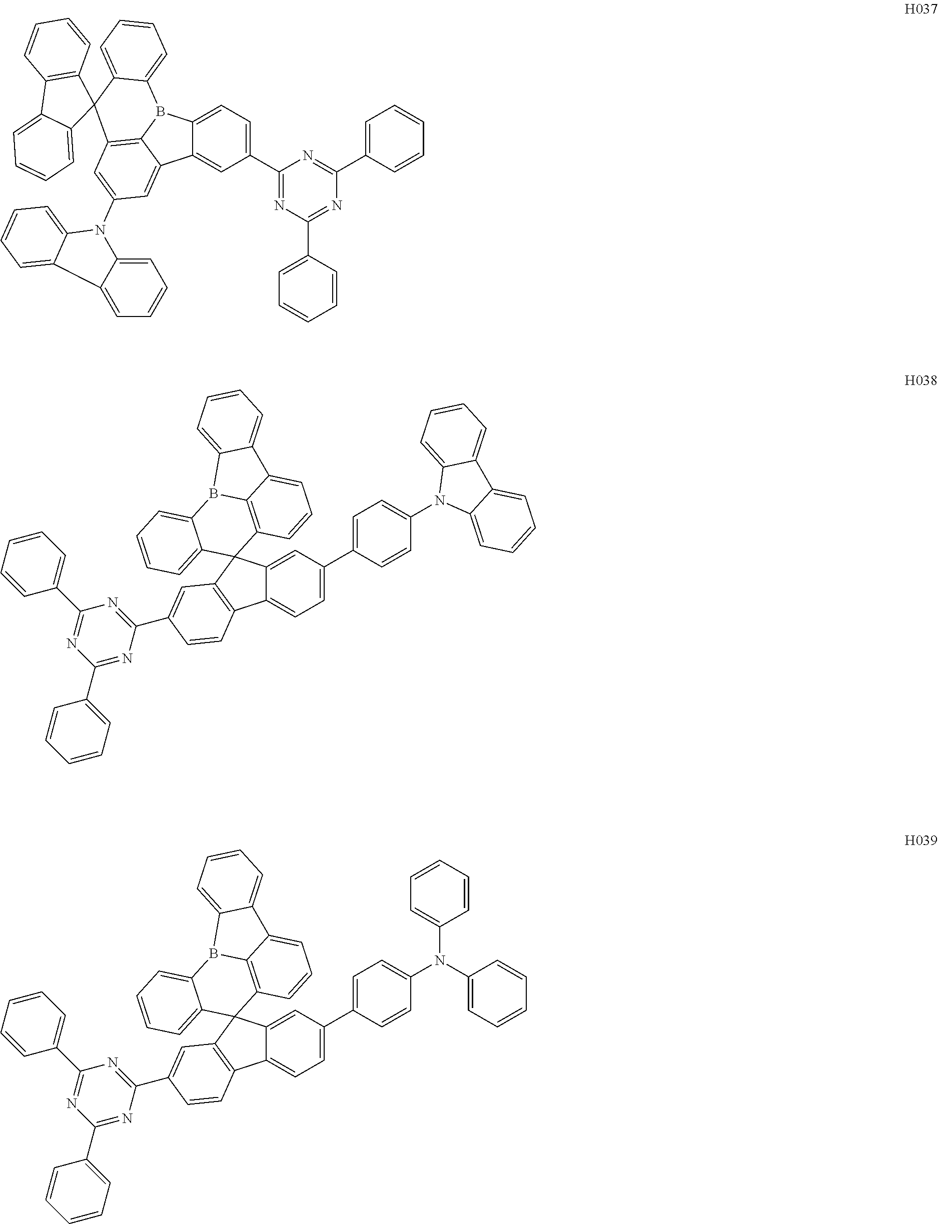 [SMILES: c1ccc(-c2nc(-c3ccccc3)nc(-c3ccc4c(c3)-c3cc(-n5c6ccccc6c6ccccc65)cc5c3B4c3ccccc3C53c4ccccc4-c4ccccc43)n2)cc1 ; c1ccc(-c2nc(-c3ccccc3)nc(-c3ccc4c(c3)C3(c5ccccc5B5c6ccccc6-c6cccc3c65)c3cc(-c5ccc(-n6c7ccccc7c7ccccc76)cc5)ccc3-4)n2)cc1 ; c1ccc(-c2nc(-c3ccccc3)nc(-c3ccc4c(c3)C3(c5ccccc5B5c6ccccc6-c6cccc3c65)c3cc(-c5ccc(N(c6ccccc6)c6ccccc6)cc5)ccc3-4)n2)cc1]

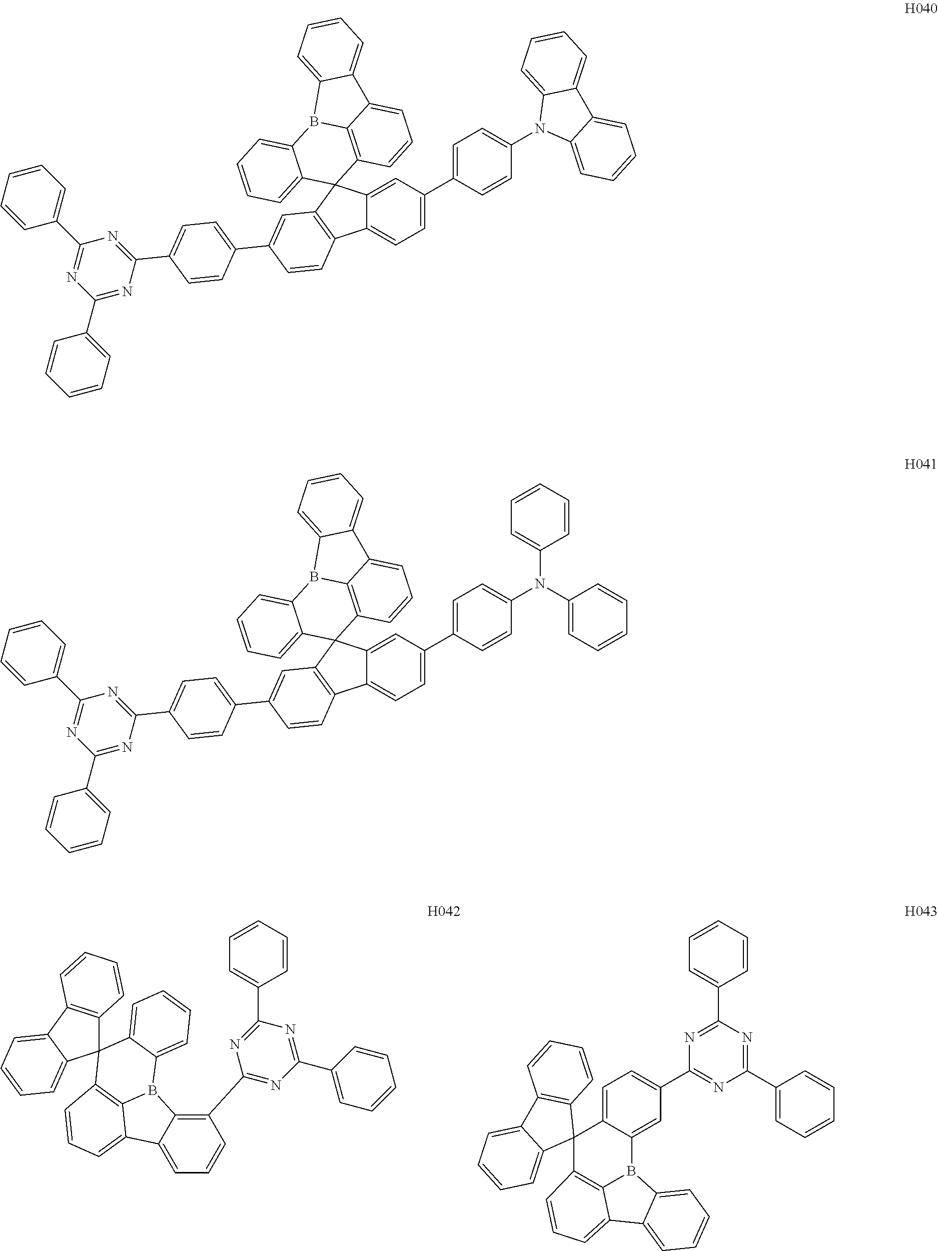 [SMILES: c1ccc(-c2nc(-c3ccccc3)nc(-c3ccc(-c4ccc5c(c4)C4(c6ccccc6B6c7ccccc7-c7cccc4c76)c4cc(-c6ccc(-n7c8ccccc8c8ccccc87)cc6)ccc4-5)cc3)n2)cc1 ; c1ccc(-c2nc(-c3ccccc3)nc(-c3ccc(-c4ccc5c(c4)C4(c6ccccc6B6c7ccccc7-c7cccc4c76)c4cc(-c6ccc(N(c7ccccc7)c7ccccc7)cc6)ccc4-5)cc3)n2)cc1 ; c1ccc(-c2nc(-c3ccccc3)nc(-c3cccc4c3B3c5ccccc5C5(c6ccccc6-c6ccccc65)c5cccc-4c53)n2)cc1 ; c1ccc(-c2nc(-c3ccccc3)nc(-c3ccc4c(c3)B3c5ccccc5-c5cccc(c53)C43c4ccccc4-c4ccccc43)n2)cc1]

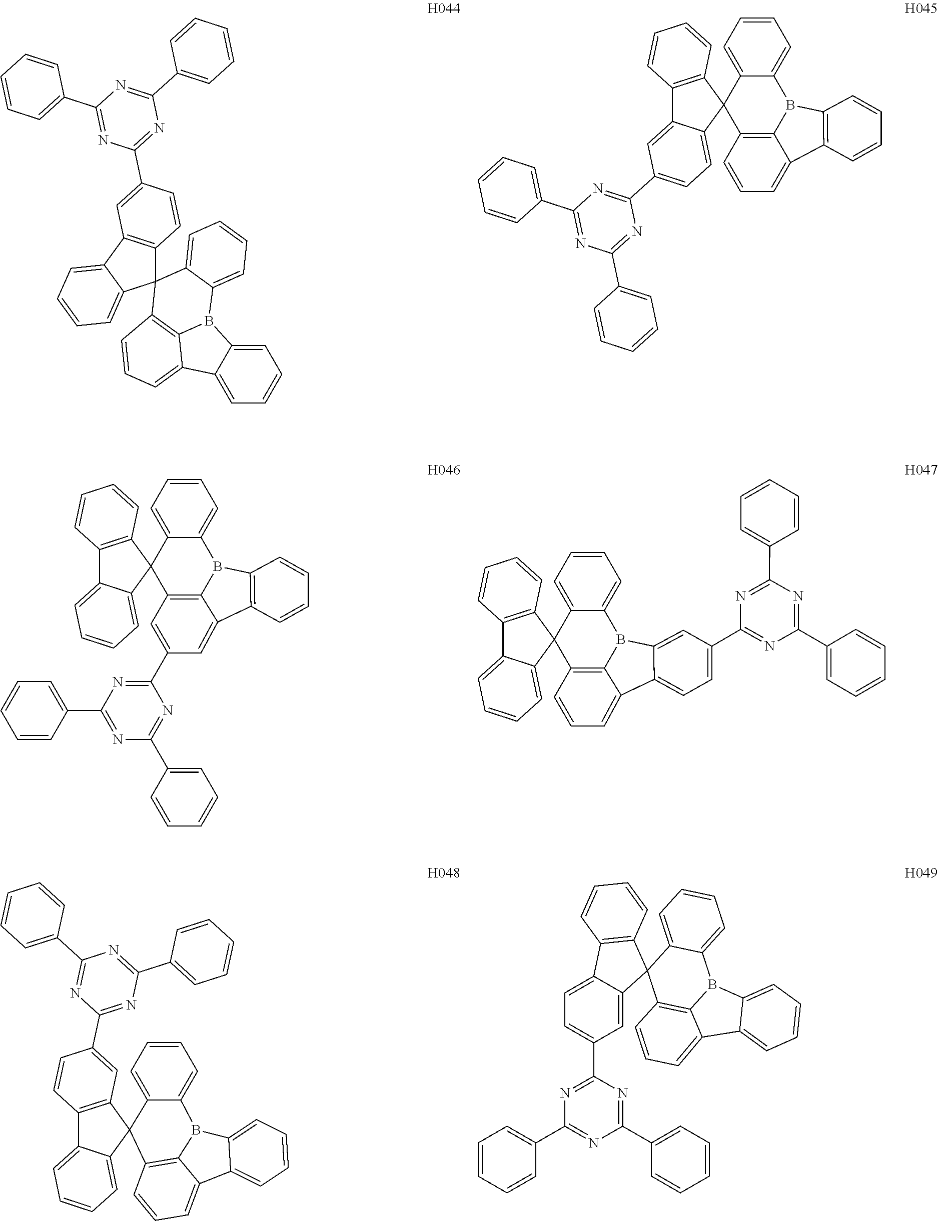

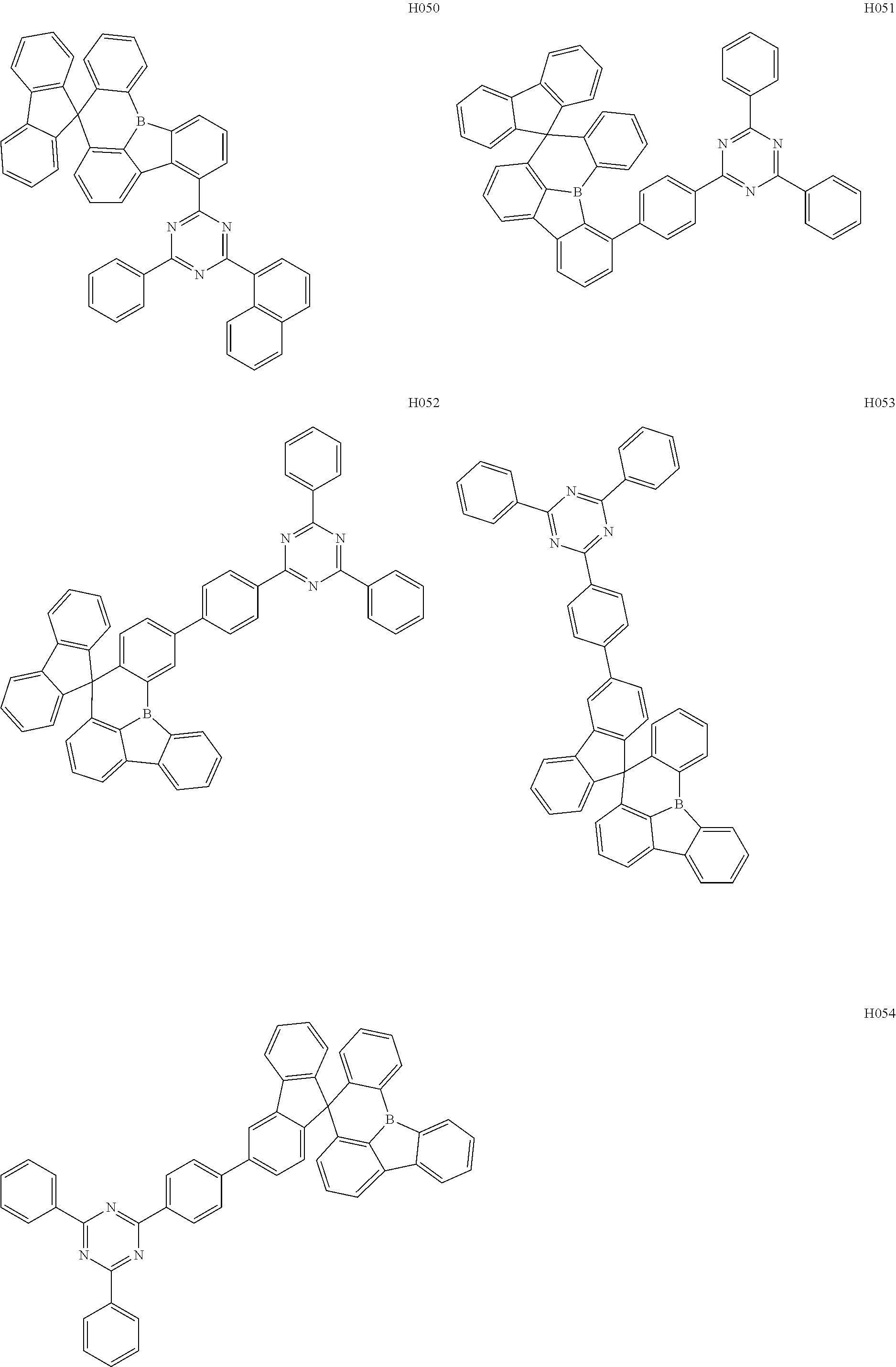 [SMILES: c1ccc(-c2nc(-c3cccc4c3-c3cccc5c3B4c3ccccc3C53c4ccccc4-c4ccccc43)nc(-c3cccc4ccccc34)n2)cc1 ; c1ccc(-c2nc(-c3ccccc3)nc(-c3ccc(-c4cccc5c4B4c6ccccc6C6(c7ccccc7-c7ccccc76)c6cccc-5c64)cc3)n2)cc1 ; c1ccc(-c2nc(-c3ccccc3)nc(-c3ccc(-c4ccc5c(c4)B4c6ccccc6-c6cccc(c64)C54c5ccccc5-c5ccccc54)cc3)n2)cc1 ; c1ccc(-c2nc(-c3ccccc3)nc(-c3ccc(-c4ccc5c(c4)-c4ccccc4C54c5ccccc5B5c6ccccc6-c6cccc4c65)cc3)n2)cc1 ; c1ccc(-c2nc(-c3ccccc3)nc(-c3ccc(-c4ccc5c(c4)-c4ccccc4C54c5ccccc5B5c6ccccc6-c6cccc4c65)cc3)n2)cc1]

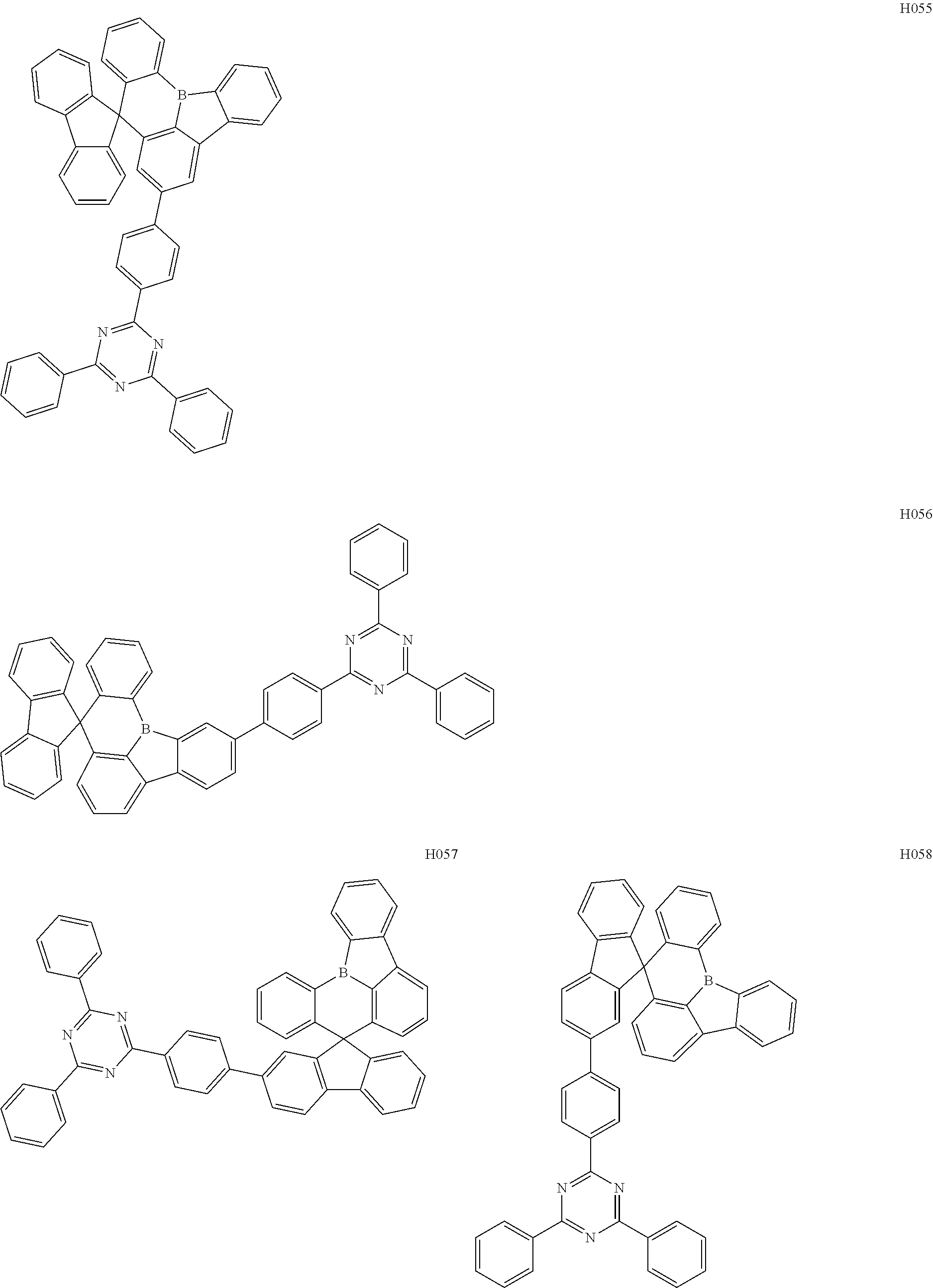 [SMILES: c1ccc(-c2nc(-c3ccccc3)nc(-c3ccc(-c4cc5c6c(c4)C4(c7ccccc7B6c6ccccc6-5)c5ccccc5-c5ccccc54)cc3)n2)cc1 ; c1ccc(-c2nc(-c3ccccc3)nc(-c3ccc(-c4ccc5c(c4)B4c6ccccc6C6(c7ccccc7-c7ccccc76)c6cccc-5c64)cc3)n2)cc1 ; c1ccc(-c2nc(-c3ccccc3)nc(-c3ccc(-c4ccc5c(c4)C4(c6ccccc6B6c7ccccc7-c7cccc4c76)c4ccccc4-5)cc3)n2)cc1 ; c1ccc(-c2nc(-c3ccccc3)nc(-c3ccc(-c4ccc5c(c4)C4(c6ccccc6B6c7ccccc7-c7cccc4c76)c4ccccc4-5)cc3)n2)cc1]

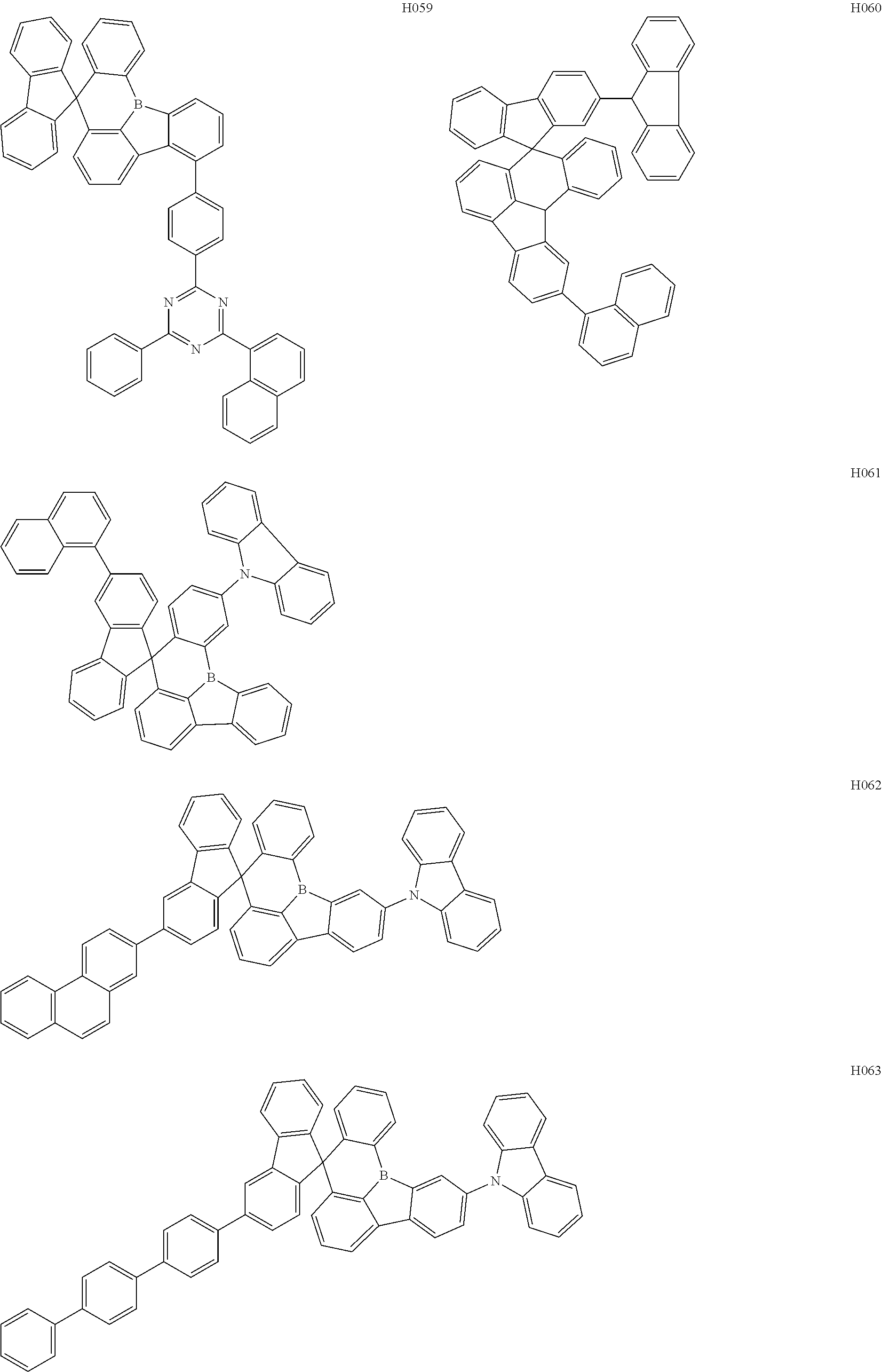

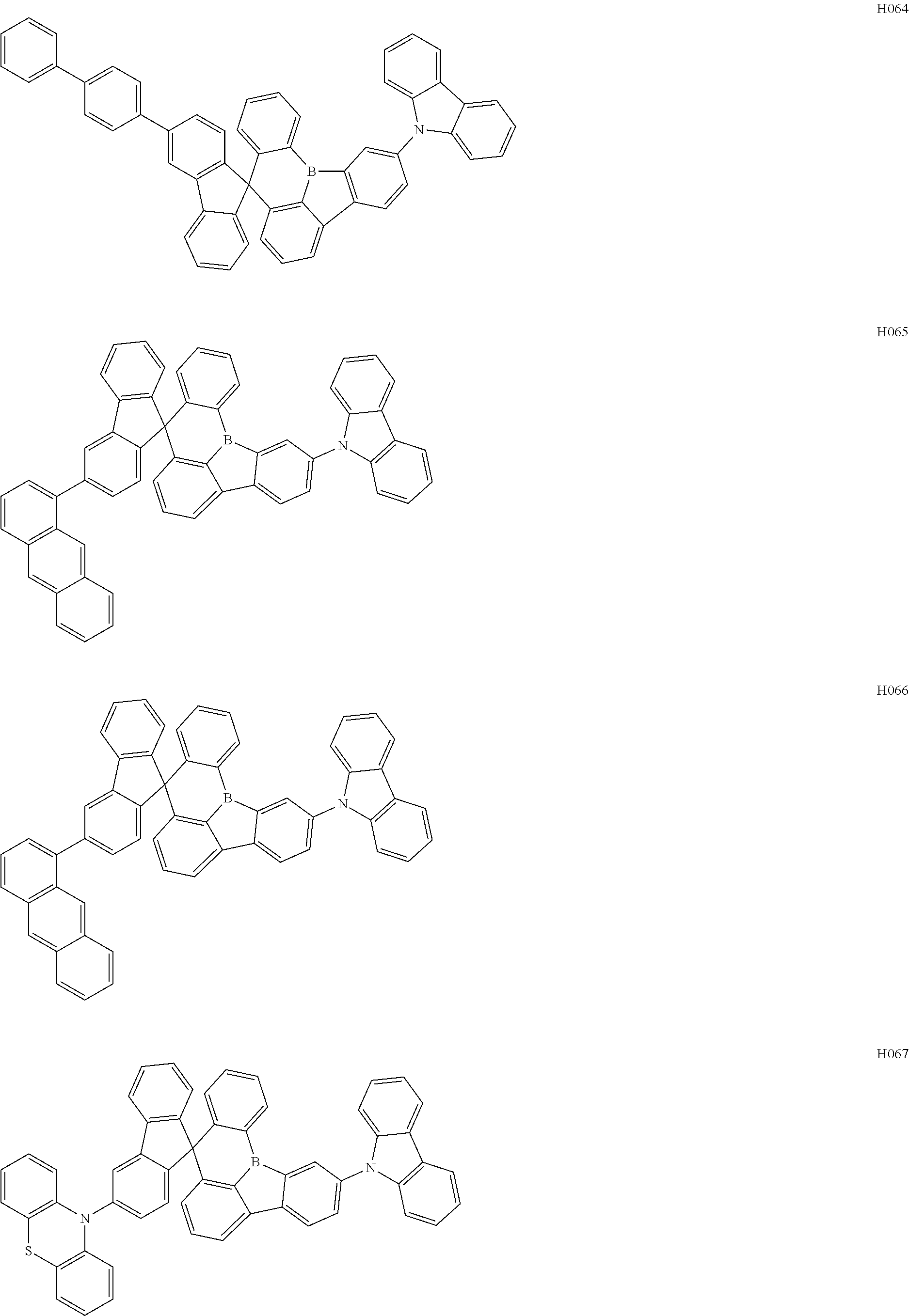 [SMILES: c1ccc(-c2ccc(-c3ccc4c(c3)-c3ccccc3C43c4ccccc4B4c5cc(-n6c7ccccc7c7ccccc76)ccc5-c5cccc3c54)cc2)cc1 ; c1ccc2c(c1)B1c3cc(-n4c5ccccc5c5ccccc54)ccc3-c3cccc(c31)C21c2ccccc2-c2cc(-c3cccc4cc5ccccc5cc34)ccc21 ; c1ccc2c(c1)B1c3cc(-n4c5ccccc5c5ccccc54)ccc3-c3cccc(c31)C21c2ccccc2-c2cc(-c3cccc4cc5ccccc5cc34)ccc21 ; c1ccc2c(c1)Sc1ccccc1N2c1ccc2c(c1)-c1ccccc1C21c2ccccc2B2c3cc(-n4c5ccccc5c5ccccc54)ccc3-c3cccc1c32]

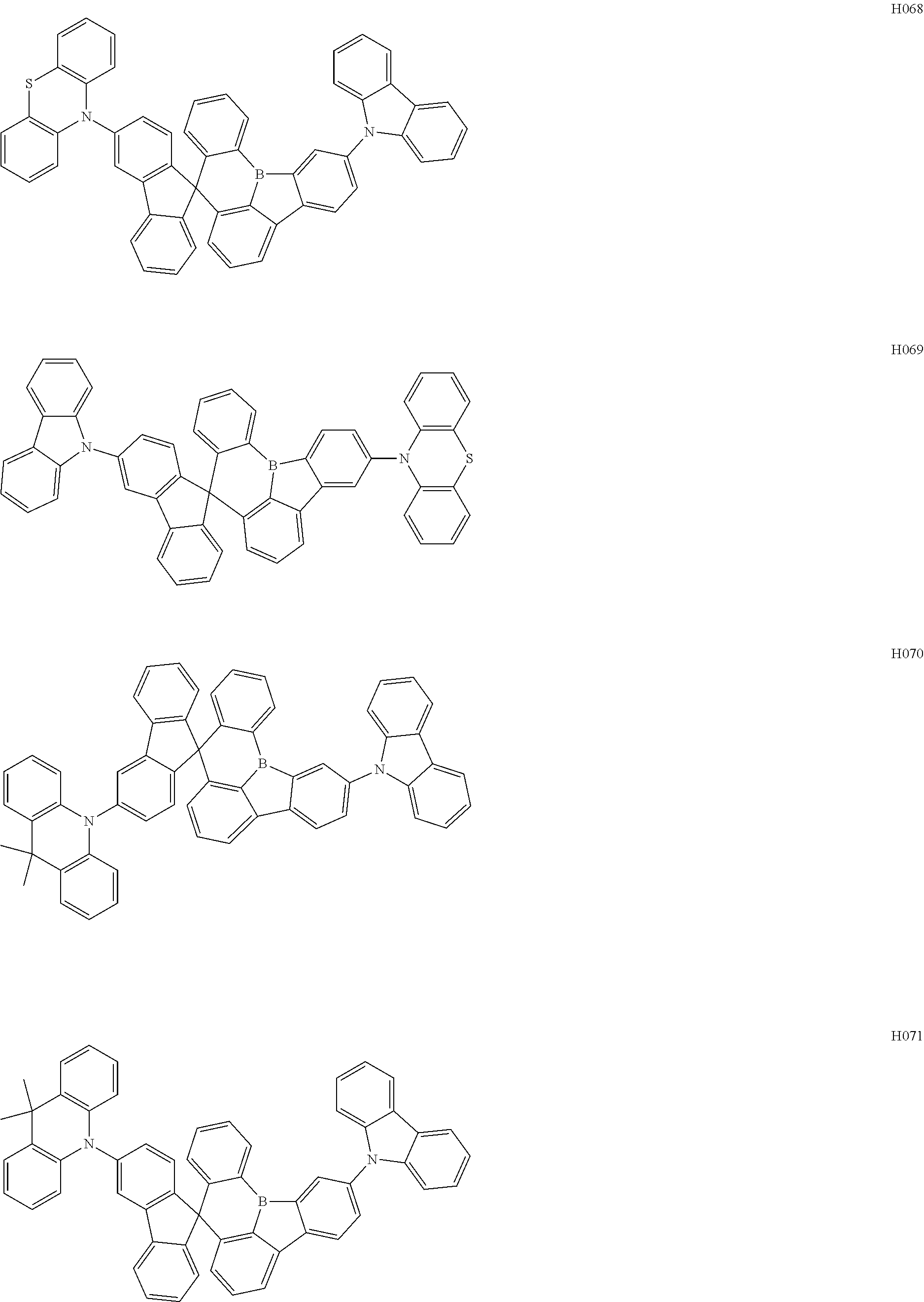 [SMILES: c1ccc2c(c1)Sc1ccccc1N2c1ccc2c(c1)-c1ccccc1C21c2ccccc2B2c3cc(-n4c5ccccc5c5ccccc54)ccc3-c3cccc1c32 ; c1ccc2c(c1)Sc1ccccc1N2c1ccc2c(c1)-c1cccc3c1B2c1ccccc1C31c2ccccc2-c2cc(-n3c4ccccc4c4ccccc43)ccc21 ; CC1(C)c2ccccc2N(c2ccc3c(c2)-c2ccccc2C32c3ccccc3B3c4cc(-n5c6ccccc6c6ccccc65)ccc4-c4cccc2c43)c2ccccc21 ; CC1(C)c2ccccc2N(c2ccc3c(c2)-c2ccccc2C32c3ccccc3B3c4cc(-n5c6ccccc6c6ccccc65)ccc4-c4cccc2c43)c2ccccc21]

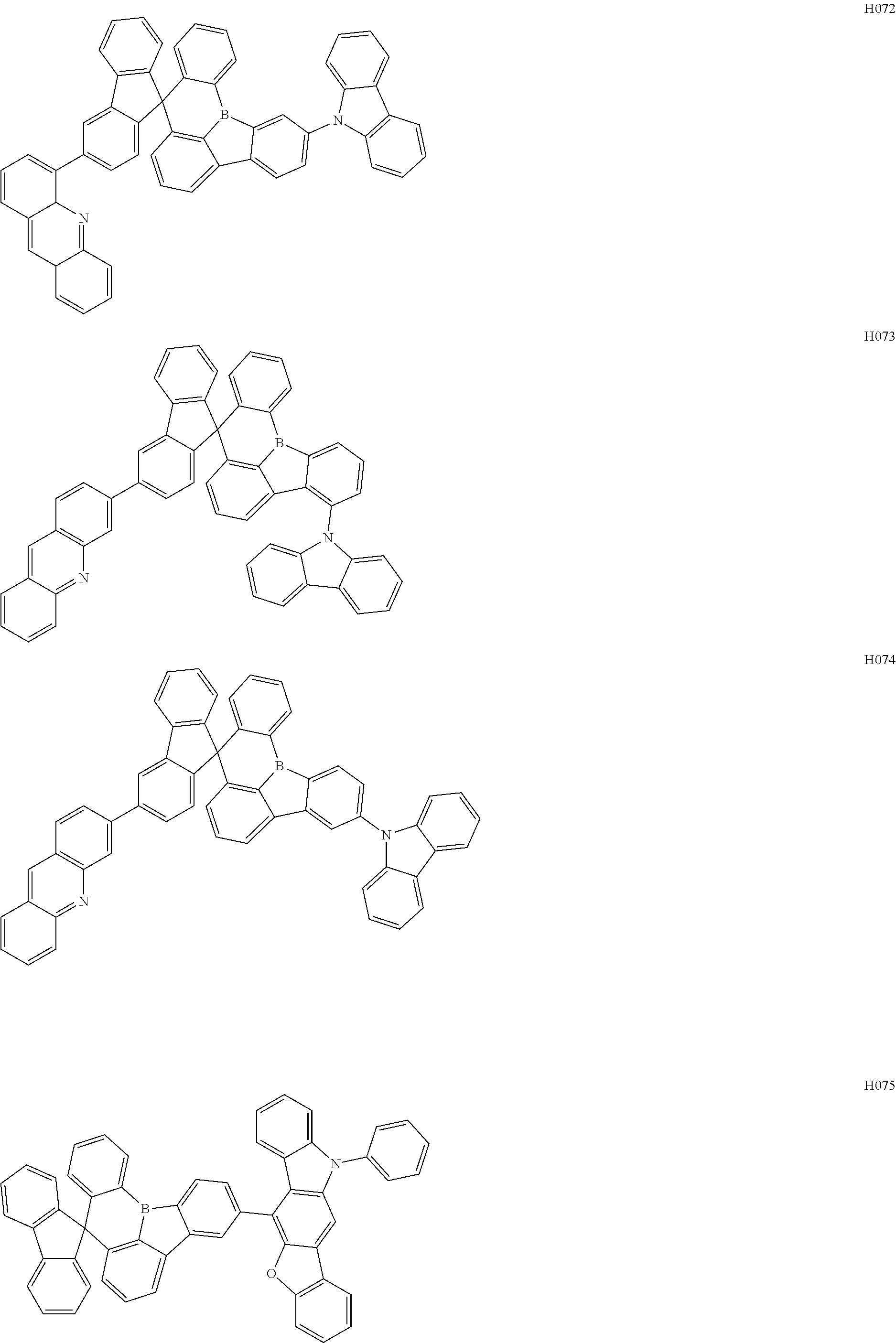 [SMILES: C1=CC2=CC3C=CC=CC3=NC2C(c2ccc3c(c2)-c2ccccc2C32c3ccccc3B3c4cc(-n5c6ccccc6c6ccccc65)ccc4-c4cccc2c43)=C1 ; c1ccc2c(c1)B1c3cccc(-n4c5ccccc5c5ccccc54)c3-c3cccc(c31)C21c2ccccc2-c2cc(-c3ccc4cc5ccccc5nc4c3)ccc21 ; c1ccc2c(c1)B1c3ccc(-n4c5ccccc5c5ccccc54)cc3-c3cccc(c31)C21c2ccccc2-c2cc(-c3ccc4cc5ccccc5nc4c3)ccc21 ; c1ccc(-n2c3ccccc3c3c(-c4ccc5c(c4)-c4cccc6c4B5c4ccccc4C64c5ccccc5-c5ccccc54)c4oc5ccccc5c4cc32)cc1]

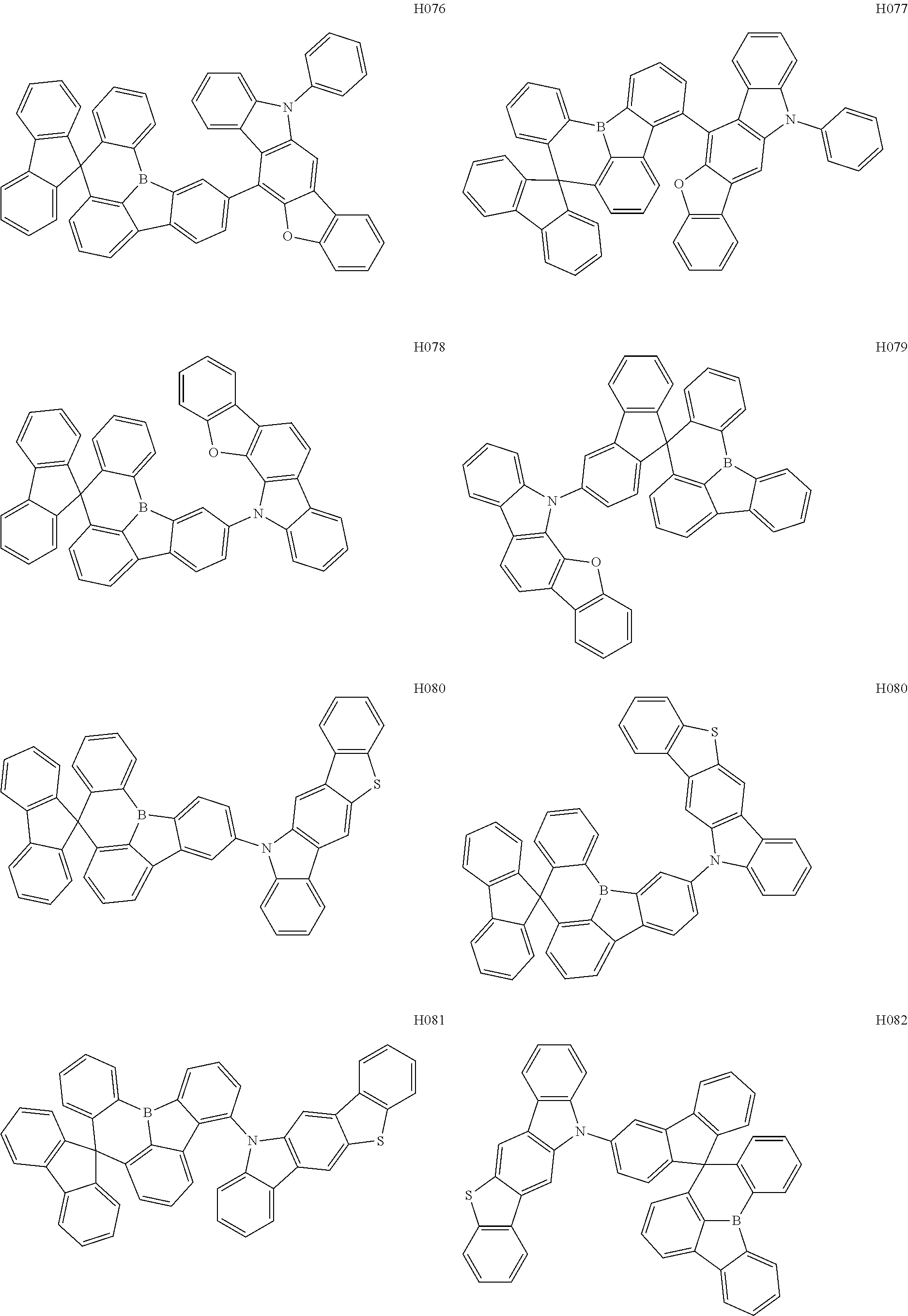

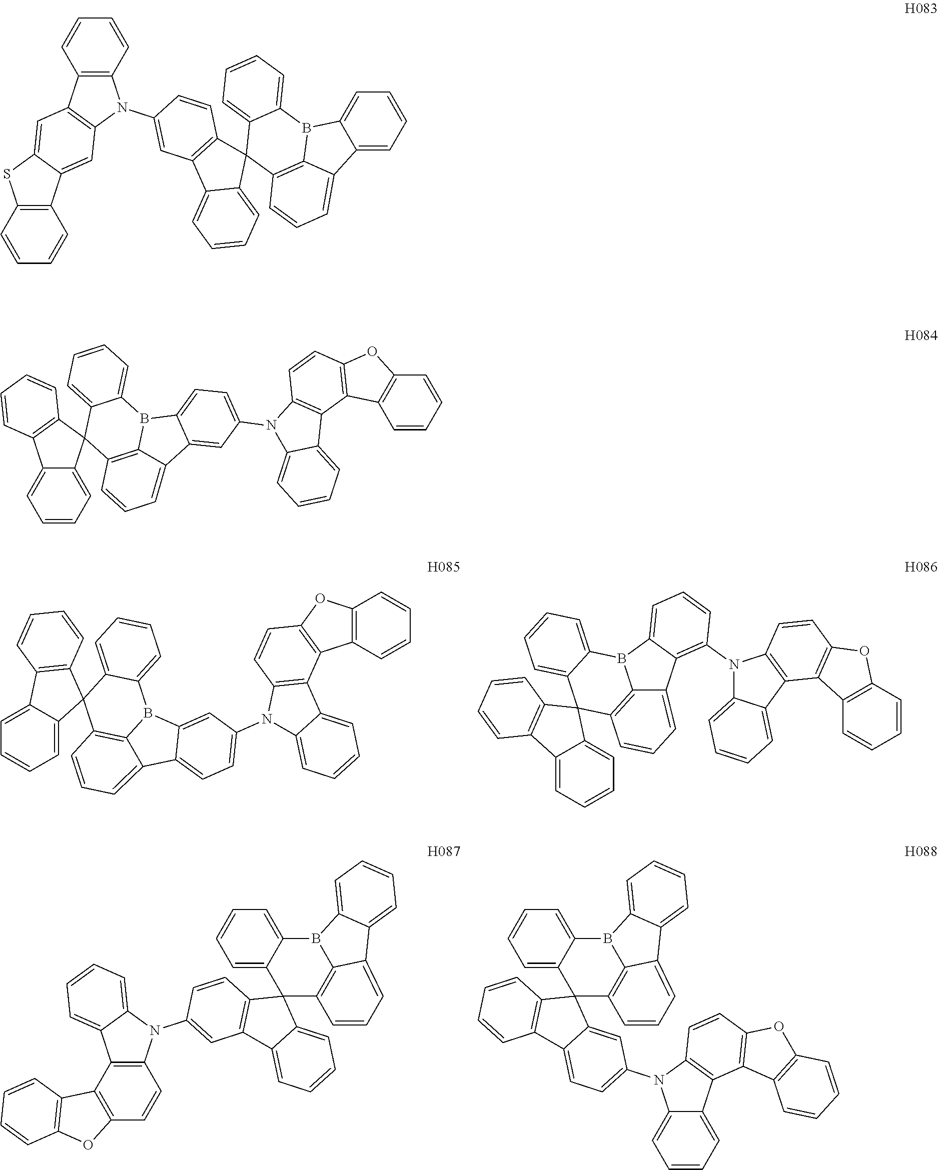

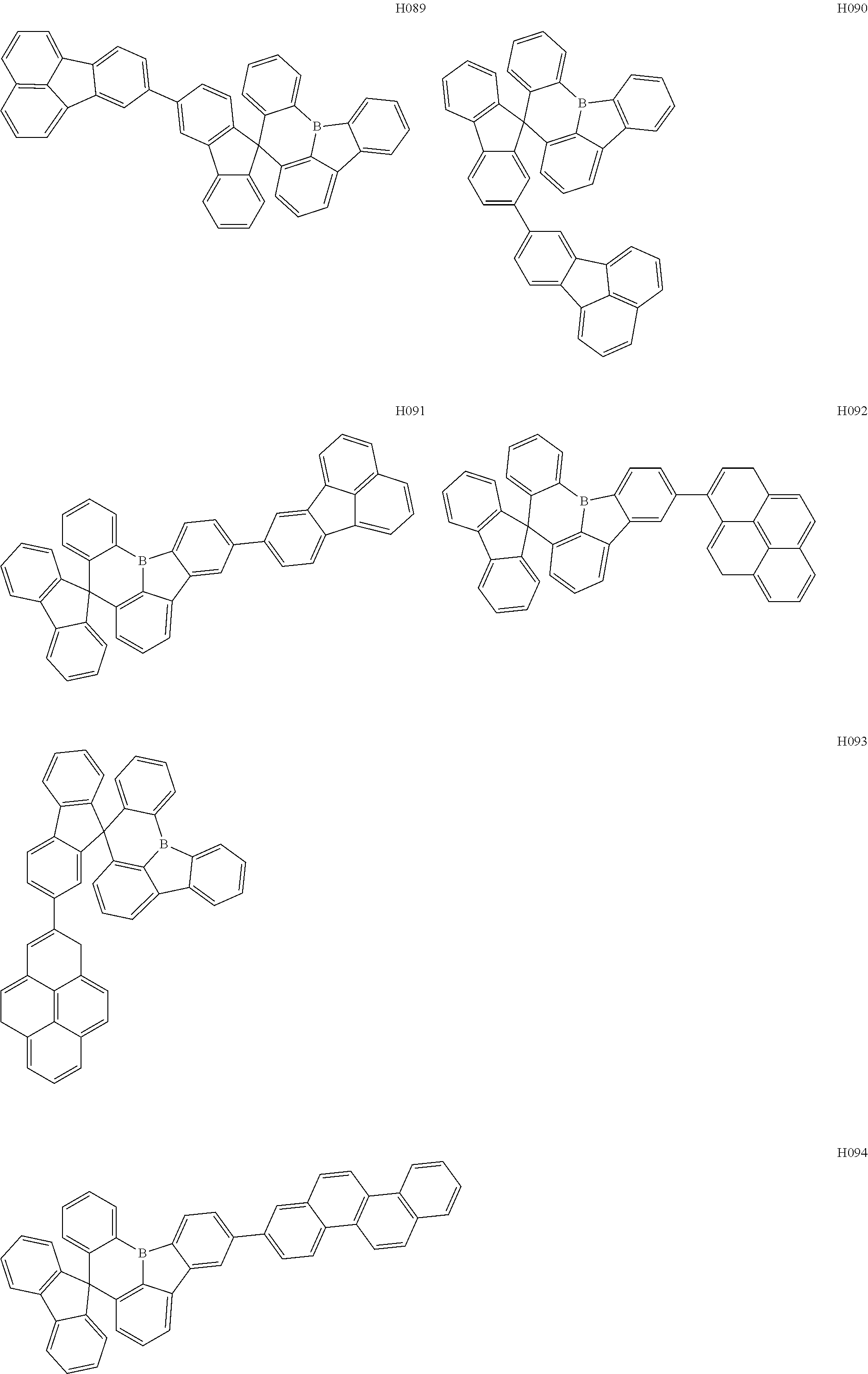

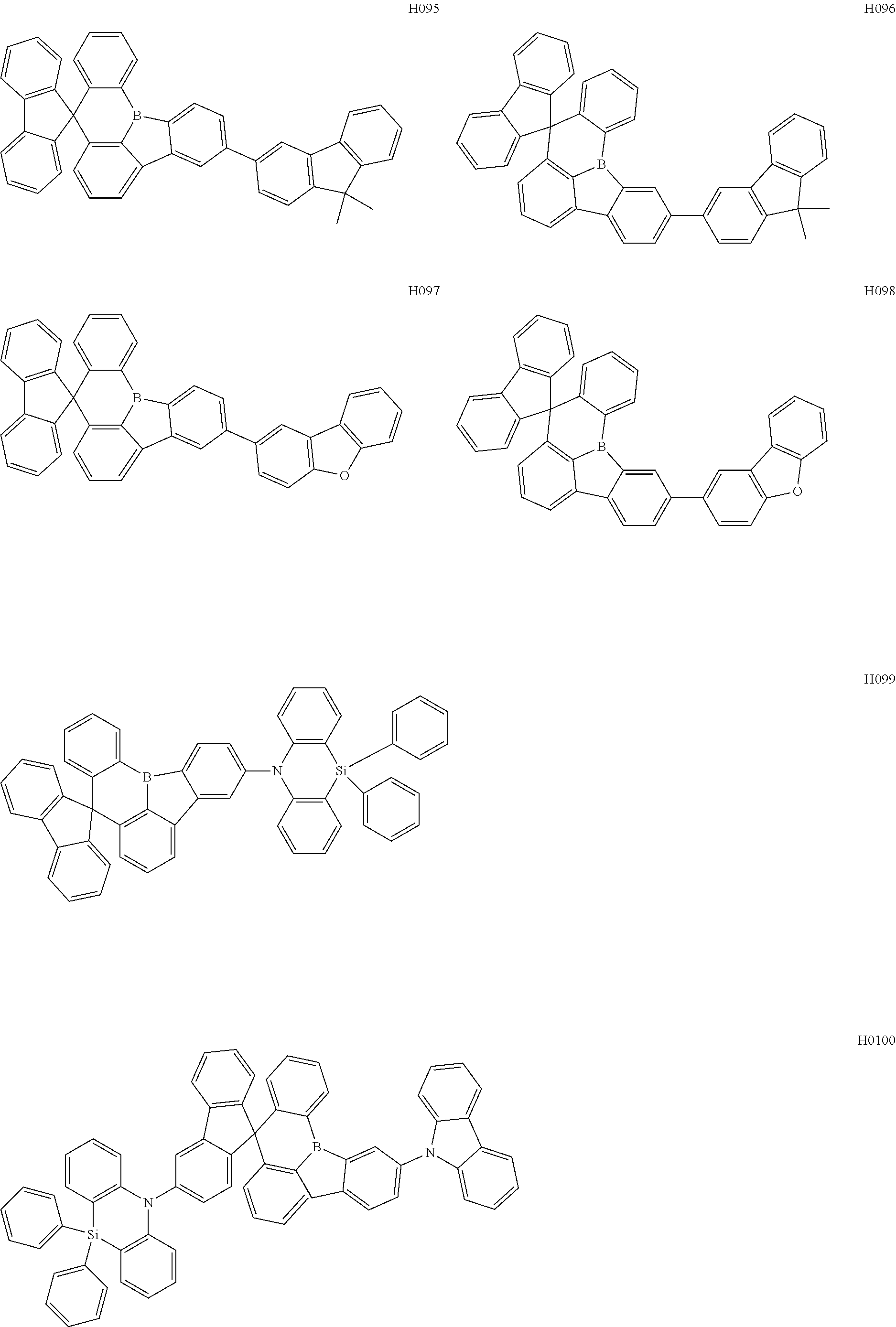

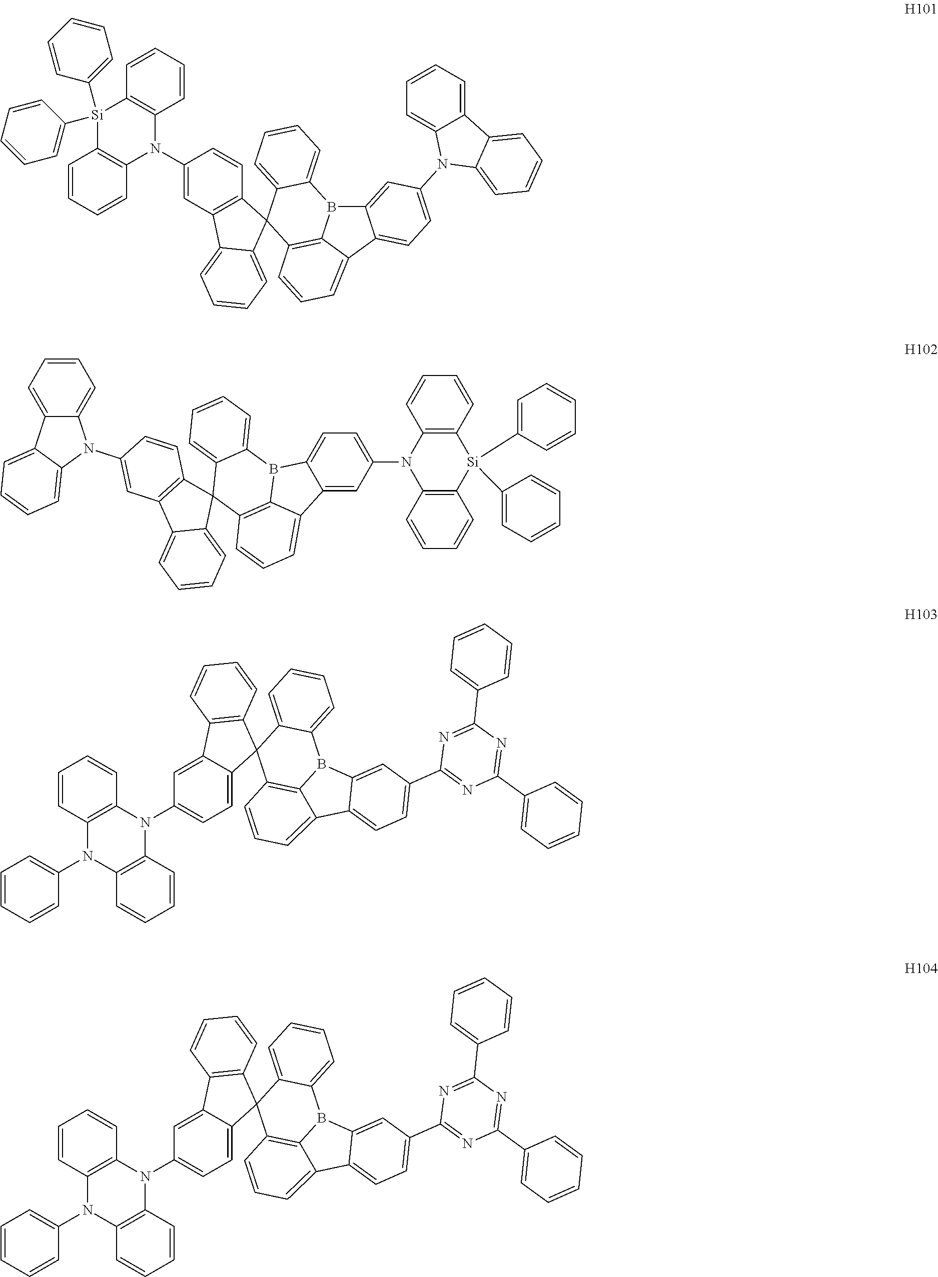 [SMILES: c1ccc([Si]2(c3ccccc3)c3ccccc3N(c3ccc4c(c3)-c3ccccc3C43c4ccccc4B4c5cc(-n6c7ccccc7c7ccccc76)ccc5-c5cccc3c54)c3ccccc32)cc1 ; c1ccc([Si]2(c3ccccc3)c3ccccc3N(c3ccc4c(c3)-c3cccc5c3B4c3ccccc3C53c4ccccc4-c4cc(-n5c6ccccc6c6ccccc65)ccc43)c3ccccc32)cc1 ; c1ccc(-c2nc(-c3ccccc3)nc(-c3ccc4c(c3)B3c5ccccc5C5(c6ccccc6-c6cc(N7c8ccccc8N(c8ccccc8)c8ccccc87)ccc65)c5cccc-4c53)n2)cc1 ; c1ccc(-c2nc(-c3ccccc3)nc(-c3ccc4c(c3)B3c5ccccc5C5(c6ccccc6-c6cc(N7c8ccccc8N(c8ccccc8)c8ccccc87)ccc65)c5cccc-4c53)n2)cc1]

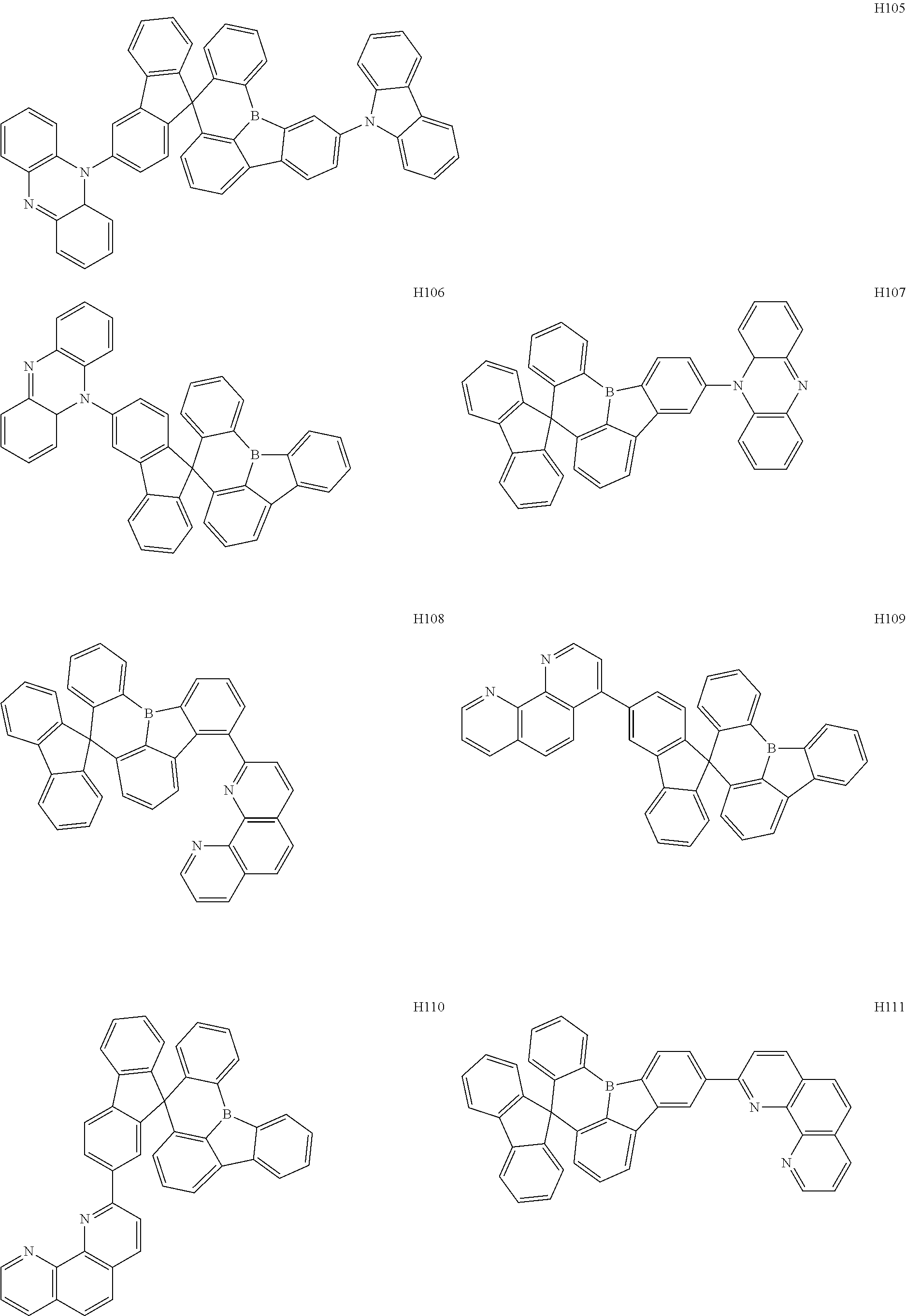

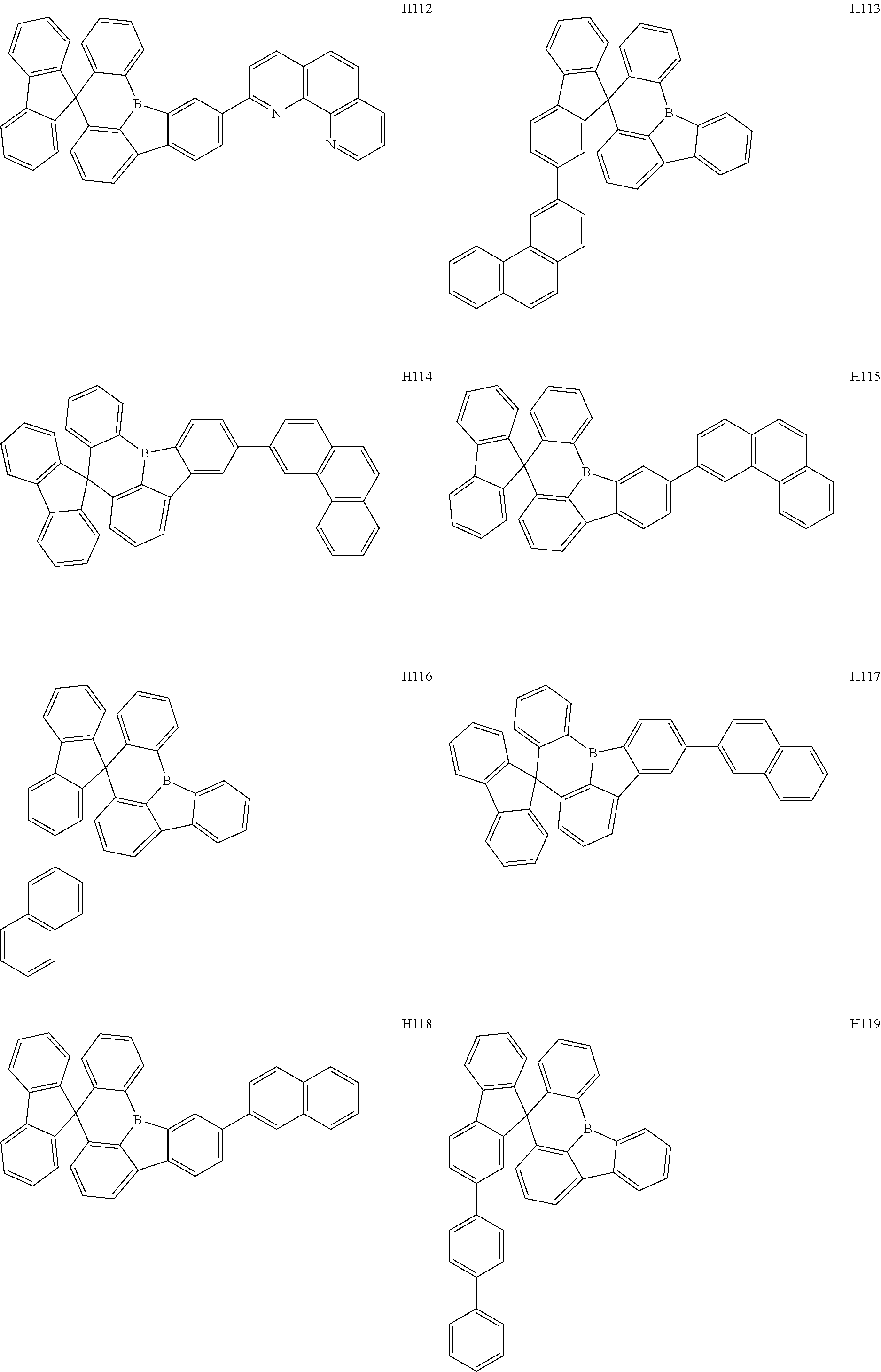

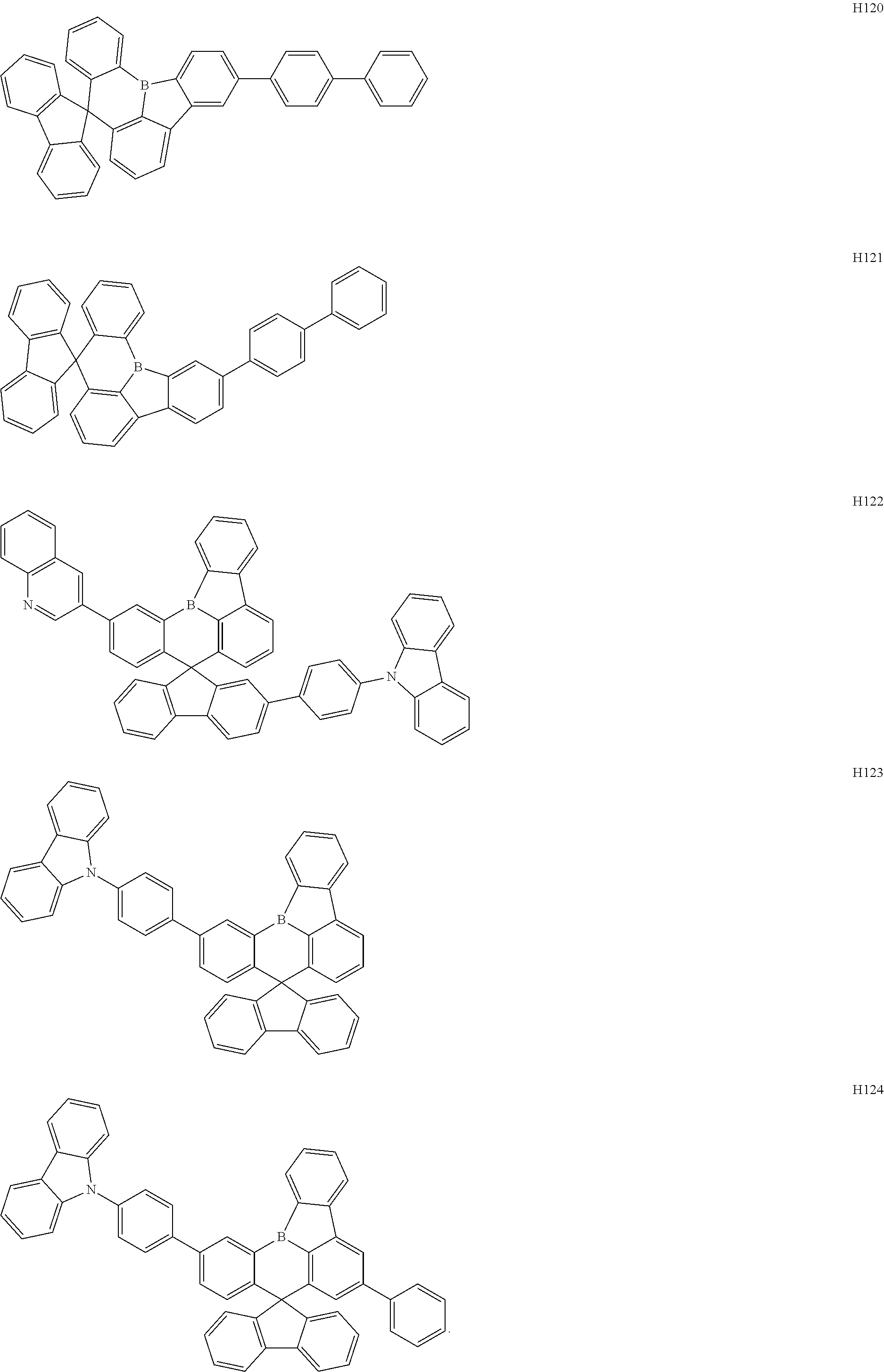 [SMILES: c1ccc(-c2ccc(-c3ccc4c(c3)-c3cccc5c3B4c3ccccc3C53c4ccccc4-c4ccccc43)cc2)cc1 ; c1ccc(-c2ccc(-c3ccc4c(c3)B3c5ccccc5C5(c6ccccc6-c6ccccc65)c5cccc-4c53)cc2)cc1 ; c1ccc2c(c1)B1c3cc(-c4cnc5ccccc5c4)ccc3C3(c4ccccc4-c4ccc(-c5ccc(-n6c7ccccc7c7ccccc76)cc5)cc43)c3cccc-2c31 ; c1ccc2c(c1)B1c3cc(-c4ccc(-n5c6ccccc6c6ccccc65)cc4)ccc3C3(c4ccccc4-c4ccccc43)c3cccc-2c31 ; c1ccc(-c2cc3c4c(c2)C2(c5ccc(-c6ccc(-n7c8ccccc8c8ccccc87)cc6)cc5B4c4ccccc4-3)c3ccccc3-c3ccccc32)cc1]

The present disclosure also provides preparation methods of exemplary compound H006, compound H024, compound H026, compound H038, compound H039, and compound H056, as described below.

### Example 1

Synthesis of Compound H006

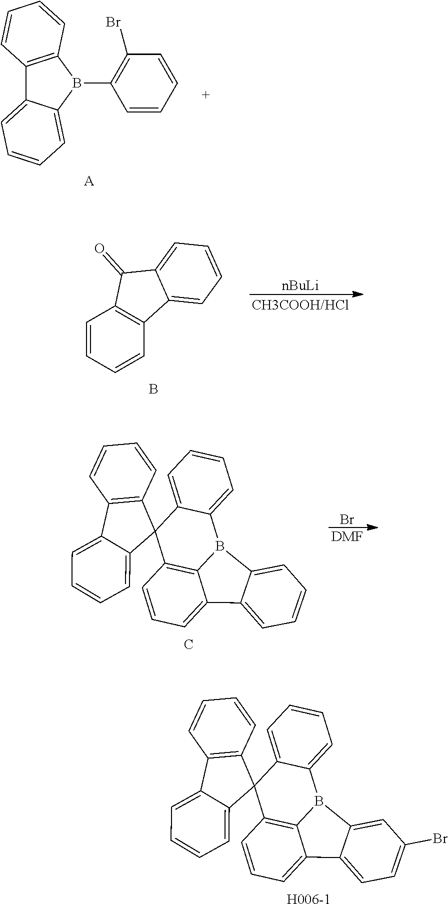

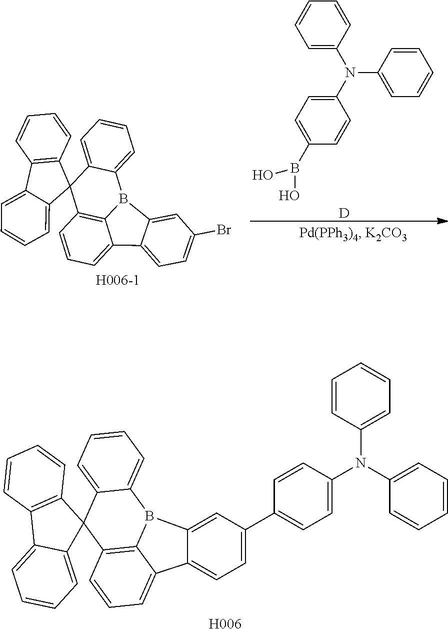

(1) Compound A (32 mmol) was added into a three-necked flask, dissolved with 200 mL of anhydrous tetrahydrofuran under stirring, and cooled to −78° C. under nitrogen protection. Then, 13 mL of 2M butyl lithium solution was added dropwise, and then stirred for 0.5 h. Subsequently, a tetrahydrofuran solution of compound B (32 mmol) was added dropwise into the reaction solution. Then, the temperature was raised to room temperature, the reaction was continued for 2 h under stirring and quenched by adding a saturated solution of ammonium chloride, water was added for liquid separation, and the organic phase was concentrated to obtain an oily product. The oily product was added to a mixture of 100 mL acetic acid and 20 mL HCl and stirred at reflux for 12 h. After cooling, saturated brine was added, and extraction was conducted with dichloromethane to obtain an organic phase. The organic phase was washed with water three times. The solvent was removed by evaporation and the residue was recrystallized with dichloromethane/petroleum ether to obtain a compound C.

(2) The compound C (20 mmol) was added into a three-necked flask, dissolved with 200 mL of N, N-dimethylformamide (DMF) under stirring, and under nitrogen protection, liquid bromine (10 mmol) was added dropwise at room temperature, then the reaction solution was stirred at room temperature for 2 h and filtered with suction, and the filter cake was recrystallized with ethanol to obtain a solid intermediate H006-1.

(3) The compound H006-1 (15 mmol) and a compound D (15 mmol) were added to a three-necked flask, dissolved with 100 mL toluene under stirring, and under nitrogen protection, Pd(PPh₃)₄ (0.75 mmol) and K₂CO₃ (30 mmol) were added. The reaction solution was stirred at reflux for 12 h. The obtained mixture was cooled to room temperature, added with water, and then filtered through a diatomite pad. The filtrate was extracted with dichloromethane, then washed with water, and dried with anhydrous magnesium sulfate. After filtration and evaporation, the crude product was purified with silica gel column chromatography to obtain the target product H006.

Characterization result of compound H006: molecular formula C₄₉H₃₂BN;

ESI-MS (m/z) [M+1]⁺ obtained by liquid chromatography-mass spectrometry: theoretical: 646.26, measured: 646.50;

Elemental analysis results: theoretical: C, 91.16; H, 5.00; B, 1.67; N, 2.17; measured: C, 91.15; H, 5.01; B, 1.66; N, 2.18.

### Example 2

Synthesis of Compound H024

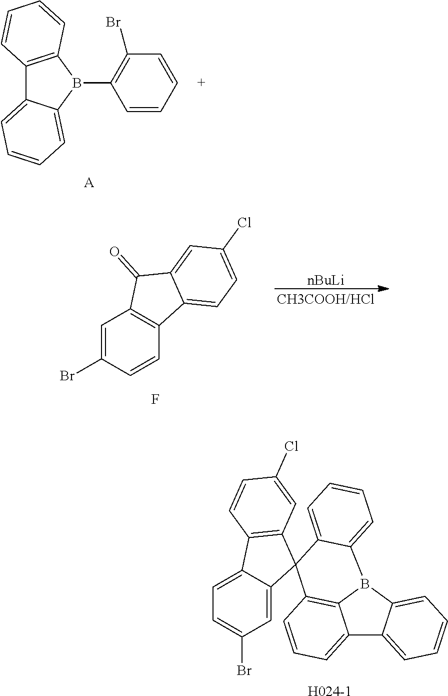

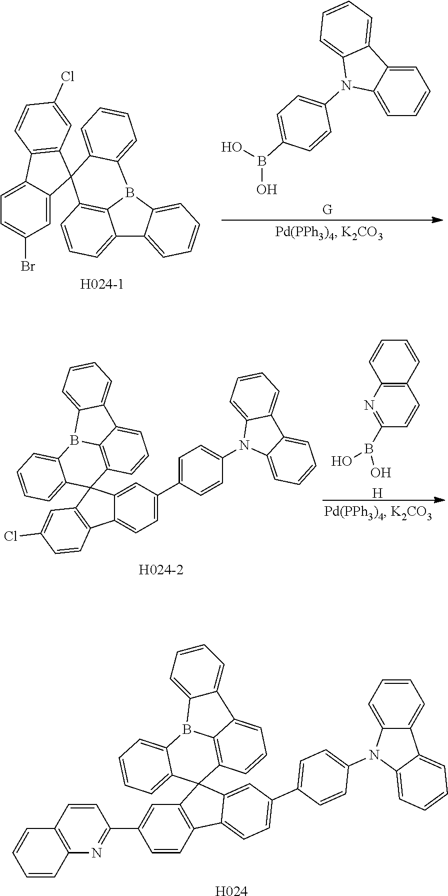

(1) Compound A (32 mmol) was added into a three-necked flask, dissolved with 200 mL of anhydrous tetrahydrofuran under stirring, and cooled to −78° C. under nitrogen protection. Then, 13 mL of 2M butyl lithium solution was added dropwise, and then stirred for 0.5 h. Subsequently, a tetrahydrofuran solution of compound F (35 mmol) was added dropwise into the reaction solution. Then, the temperature was raised to room temperature, the reaction was continued for 2 h under stirring and quenched by adding a saturated solution of ammonium chloride, water was added for liquid separation, and the organic phase was concentrated to obtain an oily product. The oily product was added to a mixed solution of 100 mL acetic acid and 20 mL HCl and stirred at reflux for 12 h. After cooling, saturated brine was added, and extraction was conducted with dichloromethane to obtain an organic phase. The organic phase was washed with water three times. The solvent was removed by evaporation and the residue was recrystallized with dichloromethane/petroleum ether to obtain an intermediate compound H024-1.

(2) The compound H024-1 (18 mmol) was dissolved in 100 mL of toluene in a three-necked flask under stirring, Pd(PPh₃)₄ (0.75 mmol) and K₂CO₃ (30 mmol) were then added under nitrogen protection, and compound G (15 mmol) was added slowly into the three-necked flask. The reaction solution was stirred at reflux for 12 h, and the obtained mixture was cooled to room temperature, added with water, and then filtered through a diatomite pad. The filtrate was extracted with dichloromethane, then washed with water, and dried with anhydrous magnesium sulfate. After filtration and evaporation, the crude product was purified with silica gel column chromatography to obtain an intermediate H024-2.

(3) Compound H024-2 (16 mmol) was dissolved in 100 mL of toluene in a three-necked flask under stirring, Pd(PPh₃)₄ (0.75 mmol) and (30 mmol) K₂CO₃ were then added under nitrogen protection, and compound H (15 mmol) was added slowly into the three-necked flask. The reaction solution was stirred at reflux for 12 h, and the obtained mixture was cooled to room temperature, added with water, and then filtered through a diatomite pad. The filtrate was extracted with dichloromethane, then washed with water, and dried with anhydrous magnesium sulfate. After filtration and evaporation, the crude product was purified with silica gel column chromatography to obtain the target product H024.

Characterization result of compound H024: molecular formula C₅₈H₃₅BN₂;

ESI-MS (m/z) [M+1]⁺ obtained by liquid chromatography-mass spectrometry: theoretical: 771.29, measured: 771.50;

Elemental analysis results: theoretical: C, 90.39; H, 4.58; B, 1.40; N, 3.63; measured: C, 90.40; H, 4.56; B, 1.41; N, 3.63.

### Example 3

Synthesis of Compound H026

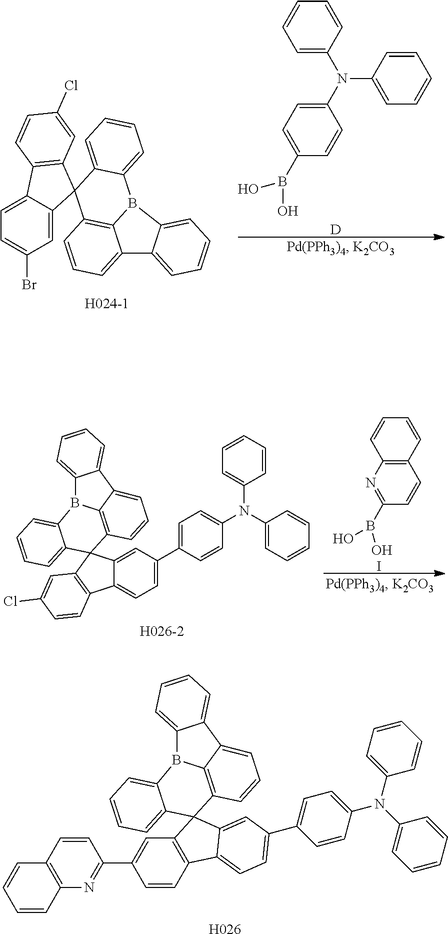

(1) Compound H024-2 (18 mmol) was dissolved in 100 mL of toluene in a three-necked flask under stirring, Pd(PPh₃)₄ (0.75 mmol) and K₂CO₃ (30 mmol) were then added under nitrogen protection, and compound D (15 mmol) was added slowly into the three-necked flask. The reaction solution was stirred at reflux for 12 h, and the obtained mixture was cooled to room temperature, added with water, and then filtered through a diatomite pad. The filtrate was extracted with dichloromethane, then washed with water, and dried with anhydrous magnesium sulfate. After filtration and evaporation, the crude product was purified with silica gel column chromatography to obtain the target product H026-2.

(2) Compound H026-2 (16 mmol) was dissolved in 100 mL of toluene in a three-necked flask under stirring, Pd(PPh₃)₄ (0.75 mmol) and K₂CO₃ (30 mmol) were then added under nitrogen protection, and compound I (15 mmol) was added slowly into the three-necked flask. The reaction solution was stirred at reflux for 12 h, and the obtained mixture was cooled to room temperature, added with water, and then filtered through a diatomite pad. The filtrate was extracted with dichloromethane, then washed with water, and dried with anhydrous magnesium sulfate. After filtration and evaporation, the crude product was purified with silica gel column chromatography to obtain the target product H026.

Characterization result of compound H026: molecular formula C₅₈H₃₇BN₂;

ESI-MS (m/z) [M+1]⁺ obtained by liquid chromatography-mass spectrometry: theoretical: 773.30, measured: 773.50;

Elemental analysis results: theoretical: C, 90.15; H, 4.83; B, 1.40; N, 3.63; measured: C, 90.13; H, 4.80; B, 1.45; N, 3.63.

### Example 4

Synthesis of Compound H038

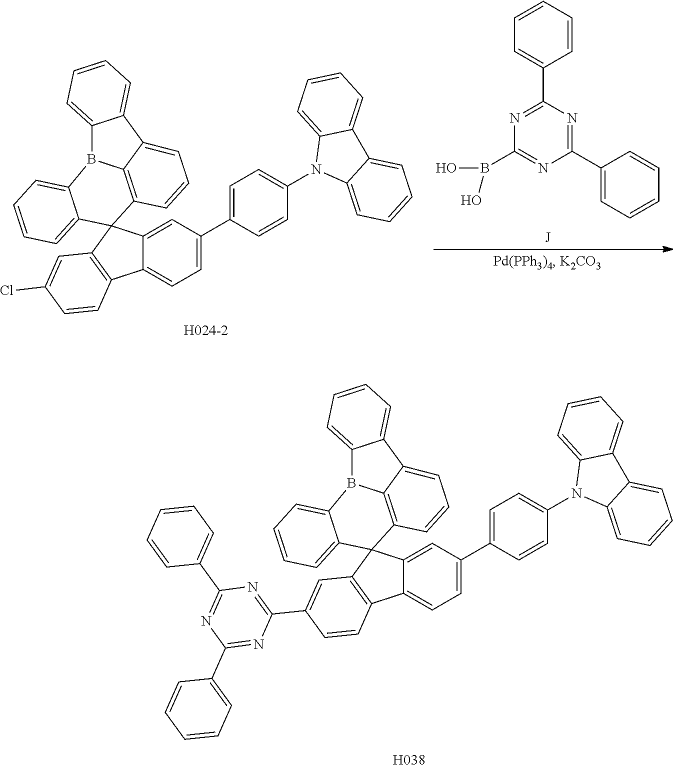

Compound H024-2 (16 mmol) was dissolved in 100 mL of toluene in a three-necked flask under stirring, Pd(PPh₃)₄ (0.75 mmol) and K₂CO₃ (30 mmol) were then added under nitrogen protection, and compound J (15 mmol) was added slowly into the three-necked flask. The reaction solution was stirred at reflux for 12 h, and the obtained mixture was cooled to room temperature, added with water, and then filtered through a diatomite pad. The filtrate was extracted with dichloromethane, then washed with water, and dried with anhydrous magnesium sulfate. After filtration and evaporation, the crude product was purified with silica gel column chromatography to obtain the target product H038.

Characterization result of compound H038: molecular formula C₆₄H₃₉BN₄;

ESI-MS (m/z) [M+1]⁺ obtained by liquid chromatography-mass spectrometry: theoretical: 875.33, measured: 875.53.

Elemental analysis results: theoretical: C, 87.87; H, 4.49; B, 1.24; N, 6.40; measured: C, 87.90; H, 4.46; B, 1.21; N, 6.37.

### Example 5

Synthesis of Compound H039

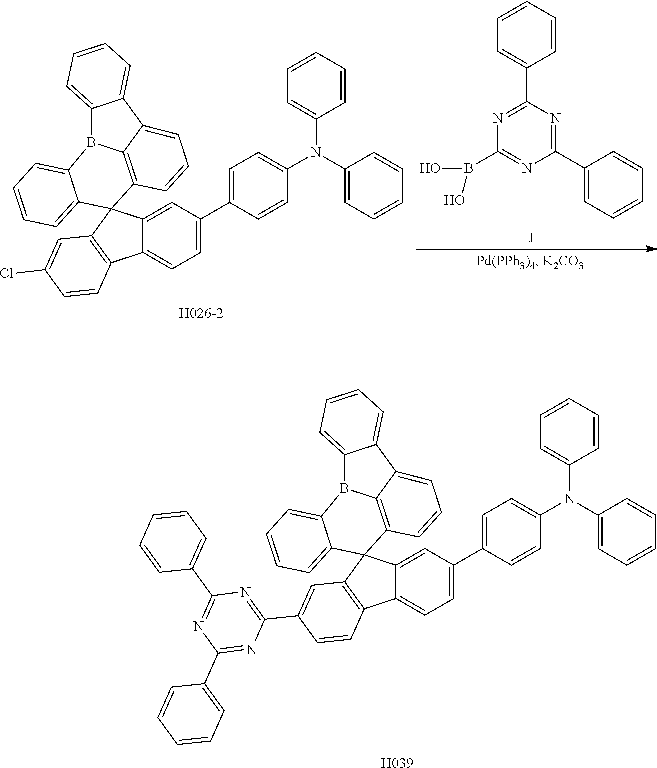

Compound H026-2 (16 mmol) was dissolved in 100 mL of toluene in a three-necked flask under stirring, Pd(PPh₃)₄ (0.75 mmol) and K₂CO₃ (30 mmol) were then added under nitrogen protection, and compound J (15 mmol) was added slowly into the three-necked flask. The reaction solution was stirred at reflux for 12 h, and the obtained mixture was cooled to room temperature, added with water, and then filtered through a diatomite pad. The filtrate was extracted with dichloromethane, then washed with water, and dried with anhydrous magnesium sulfate. After filtration and evaporation, the crude product was purified with silica gel column chromatography to obtain the target product H039.

Characterization result of compound H039: molecular formula C₆₄H₄₁BN₄;

ESI-MS (m/z) [M+1]⁺ obtained by liquid chromatography-mass spectrometry: theoretical: 877.34, measured: 877.52;

Elemental analysis results: theoretical: C, 87.66; H, 4.71; B, 1.23; N, 6.39; measured: C, 87.70; H, 4.70; B, 1.22; N, 6.38.

### Example 6

Synthesis of Compound H056

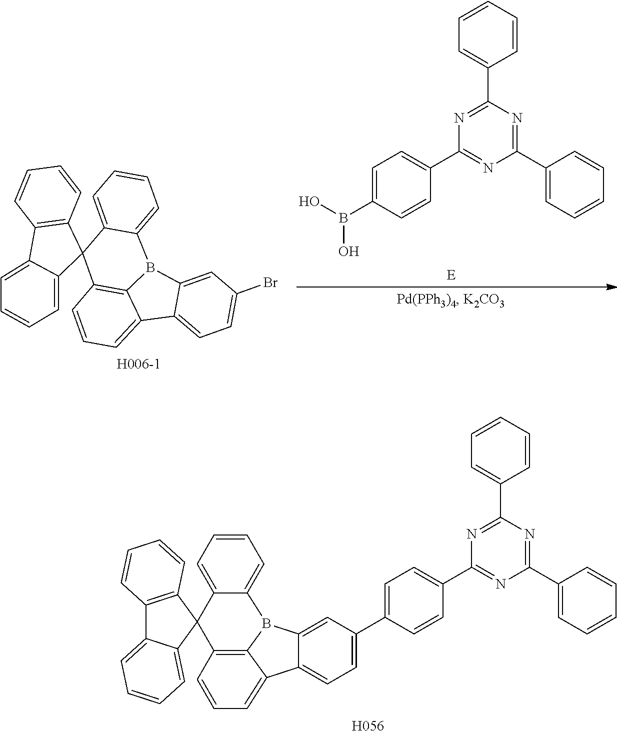

(1) Compound H006-1 (15 mmol) and compound E (15 mmol) were dissolved in 100 mL of toluene in a three-necked flask under stirring, and Pd(PPh₃)₄ (0.75 mmol) and (30 mmol) K₂CO₃ were then added under nitrogen protection. The reaction solution was stirred at reflux for 12 h, and the obtained mixture was cooled to room temperature, added with water, and then filtered through a diatomite pad. The filtrate was extracted with dichloromethane, then washed with water, and dried with anhydrous magnesium sulfate. After filtration and evaporation, the crude product was purified with silica gel column chromatography to obtain the target product H056.

Characterization result of compound H056: molecular formula C₅₂H₃₂BN₃;

ESI-MS (m/z) [M+1]⁺ obtained by liquid chromatography-mass spectrometry: theoretical: 710.27, measured: 711.00;

Elemental analysis results: theoretical: C, 88.01; H, 4.55; B, 1.52; N, 5.92; measured: C, 88.00; H, 4.59; B, 1.50; N, 5.91.

The present disclosure further provides a display panel. The display panel includes an organic light-emitting device. The organic light-emitting device includes an anode, a cathode arranged opposite to the anode, and a light-emitting layer located between the anode and the cathode. A host material of the light-emitting layer is one or more of the compounds of the present disclosure.

According to an embodiment of the display panel of the present disclosure, a singlet energy level Si of the host material is higher than a singlet energy level Si of a guest material of the light-emitting layer, and a triplet energy level T1 of the host material is higher than that of the guest material.

According to an embodiment of the display panel of the present disclosure, the organic light-emitting device further includes one or more of a hole injection layer, a hole transmission layer, an electron blocking layer, a hole blocking layer, an electron transmission layer or an electron injection layer.

The hole injection layer, the hole transmission layer, and the electron blocking layer can be made of a material selected from, but not limited to, 2,2′-dimethyl-N,N′-di-1-naphthyl-N,N′-diphenyl [1,1′-biphenyl]-4,4′-diamine (α-NPD), 4,4′,4″-tris(carbazol-9-yl)triphenylamine (TCTA), 1,3-bis(N-dicarbazolyl)benzene (mCP), 4,4′-bis(N-carbazolyl)-1,1′-biphenyl (CBP), 3,3′-bis(N-carbazolyl)-1,1′-biphenyl (mCBP), 2,3,6,7,10,11-hexacyano-1,4,5,8,9,12-hexaazatriphenylene (HATCN), 4,4′-cyclohexyldi[N, N-bis(4-methylphenyl)aniline (TAPC), N,N′-bis-(1-naphthalenyl)-N,N′-bis-phenyl-(1,1′-biphenyl)-4,4′-diamine (α-NPB), N,N′-bis(naphthalene-2-yl)-N,N′-bis(phenyl)benzidine (NPB), poly(3,4-ethylenedioxythiophene)-poly(styrenesulfonate) (PEDOT:PSS), polyvinylcarbazole (PVK), 9-phenyl-3,9-bicarbazole (CCP), molybdenum trioxide (MoO₃), or the like.

The hole blocking layer, the electron transmission layer, and the electron injection layer can be made of a material selected from, but not limited to, 2,8-bis(diphenylphosphoryl)dibenzothiophene (PPT), TSPO₁, 1,3,5-tris(1-phenyl-1H-benzimidazol-2-yl)benzene (TPBi), 2,8-bis(diphenylphosphoryl) dibenzofuran (PPF), bis[2-diphenylphosphino)phenyl]ether oxide (DPEPO), lithium fluoride (LiF), 4,6-bis(3,5-di(pyridin-3-yl)phenyl)-2-methylpyrimidine (B3PYMPM), 4,7-diphenyl-1, 10-phenanthroline (Bphen), 1,3,5-tris[(pyridin-3-yl)-3-phenyl]benzene (TmPyBP), tris[2,4,6-trimethyl-3-(pyridin-3-yl)phenyl]borane (3TPYMB), 1,3-bis(3,5-di(pyridin-3-yl)phenyl)benzene (B3PYPB), 1,3-bis[3,5-di(pyridin-3-yl)phenyl]benzene (BMPYPHB), 2,4,6-tris(biphenyl-3-yl)-1,3,5-triazine (T2T), diphenyl bis[4-(pyridin-3-yl)phenyl]silane (DPPS), cesium carbonate (Cs₂O₃), bis(2-methyl-8-quinolinolato-N1,O₈)-(1,1′-biphenyl-4-olato)aluminum (BAlq), 8-hydroxyquinolinolato-lithium (Liq), tris(8-hydroxyquinoline)aluminum (Alq₃), or the like.

In one embodiment of the display panel provided by the present disclosure, the light-emitting layer comprises a host material and a guest material. The host material is selected from the group consisting of 2,8-bis(diphenylphosphoryl)dibenzothiophene, 4,4′-bis(N-carbazolyl)-1,1′-biphenyl, 3,3′-bis(N-carbazolyl)-1,1′-biphenyl, 2,8-bis(diphenylphosphoryl)dibenzofuran bis(4-(9H-carbazolyl-9-yl)phenyl)diphenylsilane, 9-(4-tert-butylphenyl)-3,6-bis(triphenylsilyl)-9H-carbazole, bis[2-diphenylphosphino)phenyl]ether, 1,3-bis[3,5-di(pyridin-3-yl)phenyl]benzene, 4,6-bis(3,5-di(pyridin-3-yl)phenyl)-2-methylpyrimidine, 9-(3-(9H-carbazolyl-9-yl)phenyl)-9H-carbazole-3-carbonitrile, 9-phenyl-9-[4-(triphenylsilyl)phenyl]-9H-fluorene, 1,3,5-tris(1-phenyl-1H-benzimidazol-2-yl)benzene, diphenyl[4-(triphenylsilyl)phenyl]phosphine oxide, 4,4′,4″-tris(carbazol-9-yl)triphenylamine, 2,6-dicarbazole-1,5-pyridine, polyvinylcarbazole, polyfluorene, and combinations thereof. The guest material may be selected from the group consisting of a fluorescent material, a phosphorescent material, a thermally activated delayed fluorescent material, an aggregation-inducing light-emitting material, and combinations thereof.

In the display panel provided by the present disclosure, the anode of the organic light-emitting device can be made of a metal, for example, copper, gold, silver, iron, chromium, nickel, manganese, palladium, platinum, and alloys thereof. In an embodiment, the anode can be made of a metal oxide, such as indium oxide, zinc oxide, indium tin oxide (ITO), indium zinc oxide (IZO), etc. In an embodiment, the anode can be made of a conductive polymer, such as polyaniline, polypyrrole, poly(3-methylthiophene) and the like. In addition to the anode material mentioned above, the anode also can be made of any suitable materials known in the related art and combinations thereof, as long as the material of the anode is conductive to injecting holes.

In the display panel provided by the present disclosure, the cathode of the organic light-emitting device can be made of metal, such as aluminum, magnesium, silver, indium, tin, titanium, and alloys thereof. In an embodiment, the cathode can be made of a multiple-layer metal material, such as LiF/Al, LiO₂/Al, BaF₂/Al, etc. In addition to the cathode materials listed above, the cathode also can be made of any suitable materials known in the related art and combinations thereof, as long as the material of the cathode is conductive to injecting holes.

### Device Example 1

This example provides an OLED device and a preparation method thereof. The preparation method of the OLED is described below, with reference to FIG. 2.

The preparation steps of OLED devices are as follows:

(1) a glass substrate 1 was cut into a size of 50 mm×50 mm×0.7 mm, and ultrasonically treated respectively in isopropanol and deionized water for 30 min, and then exposed to ozone for cleaning for 10 min; and the obtained glass substrate with an indium tin oxide (ITO) anode layer 2 was mounted on a vacuum deposition apparatus;

(2) under a vacuum of 2×10−6 Pa, compound HAT-CN was vacuum-evaporated on the ITO anode 2 to form a first hole transmission layer 3 with a thickness of 10 nm;

(3) compound TAPC was vacuum-evaporated on the first hole transmission layer 3 to form a second hole transmission layer 4 with a thickness of 95 nm;

(4) a light-emitting layer 5 with a thickness of 30 nm was formed on the second hole transmission layer 4 by co-deposition, during which the organic compound H006 provided in Example 1 of the present disclosure was used as the host material of the light-emitting layer 5, Ir(piq)₂(acac) was used as the doping material, and a mass ratio of H006 to Ir(piq)₂(acac) was 19:1;

(5) compound BCP was vacuum-evaporated on the light-emitting layer 5 to form a first electron transmission layer 6 with a thickness of 35 nm;

(6) compound Alq3 was vacuum-evaporated on the first electron transmission layer 6 to form a second electron transmission layer 7 with a thickness of 5 nm;

(7) a magnesium-silver electrode was vacuum-evaporated on the second electron transmission layer 7 to form a cathode 8 with a thickness of 10 nm, in which a mass ratio of Mg to Ag was 1:9; and

(8) compound CBP having a high refractive index was vacuum-evaporated on the cathode 8 to form a cathode covering layer 9, referred as a capping layer (CPL), having a thickness of 100 nm.

The compounds used in the preparation of organic light-emitting devices are as follows:

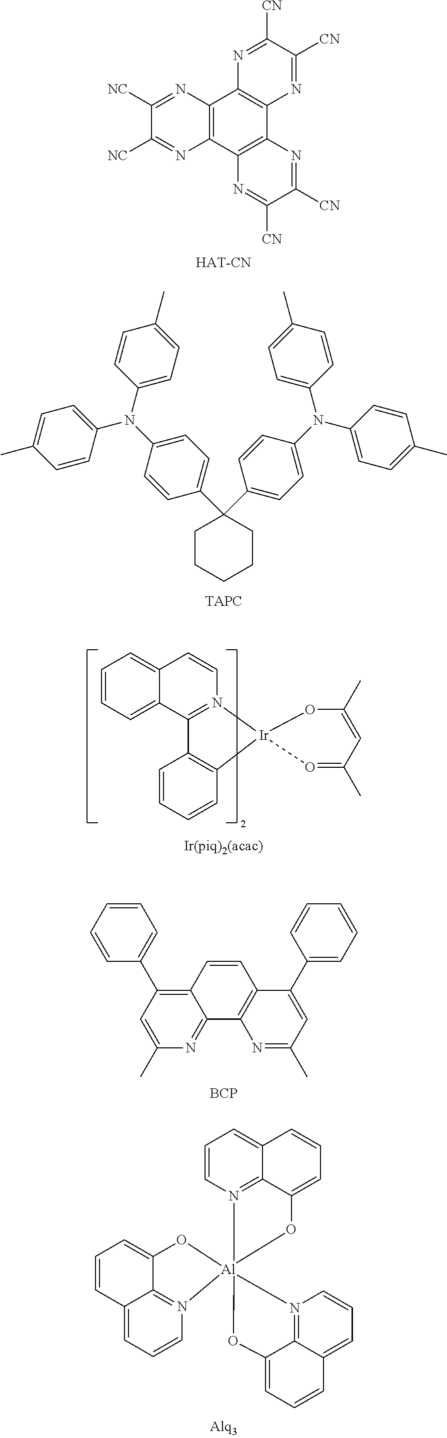

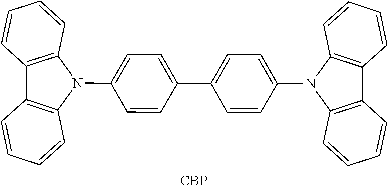 [SMILES: c1ccc2c(c1)c1ccccc1n2-c1ccc(-c2ccc(-n3c4ccccc4c4ccccc43)cc2)cc1 ; "CBP"]

### Device Example 2

This example differs from Device Example 1 in that compound H018 was used to replace compound H006.

### Device Example 3

This example differs from Device Example 1 in that compound H019 was used to replace compound H006.

### Device Example 4

This example differs from Device Example 1 in that compound H035 was used to replace compound H006.

### Device Example 5

This example differs from Device Example 1 in that compound H041 was used to replace compound H006.

### Device Example 6

This example differs from Device Example 1 in that compound H092 was used to replace compound H006.

### Device Example 7

This example differs from Device Example 1 in that compound H093 was used to replace compound H006.

### Device Example 8

This example differs from Device Example 1 in that compound H099 was used to replace compound H006.

### Device Example 9

This example differs from Device Example 1 in that compound H102 was used to replace compound H006.

### Device Example 10

This example differs from Device Example 1 in that compound H119 was used to replace compound H006.

### Device Comparative Example 1

This comparative example differs from Device Example 1 in that compound M1 was used to replace compound H006.

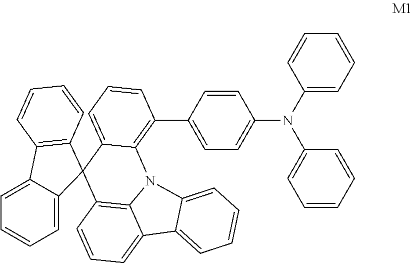 [SMILES: c1ccc(N(c2ccccc2)c2ccc(-c3cccc4c3-n3c5ccccc5c5cccc(c53)C43c4ccccc4-c4ccccc43)cc2)cc1]

### Device Comparative Example 2

This comparative example differs from Device Example 1 in that compound M2 was used to replace compound H006.

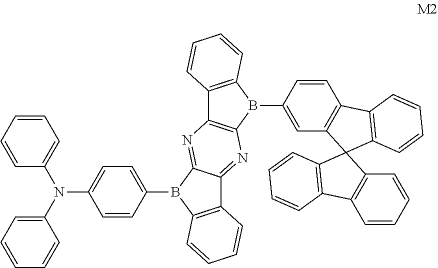 [SMILES: c1ccc(N(c2ccccc2)c2ccc(B3c4ccccc4-c4nc5c(nc43)-c3ccccc3B5c3ccc4c(c3)C3(c5ccccc5-c5ccccc53)c3ccccc3-4)cc2)cc1]

(1) Performance Evaluation of Organic Light-Emitting Display Devices

A Keithley 2365A digital nanovoltmeter was used to measure the currents of the display panels manufactured according to the examples and comparative examples at different voltages. The currents were divided by the light-emitting area to calculate current densities of the organic light-emitting device at different voltages. Konica Minolta CS-2000 spectroradiometer was used to measure the brightness and the radiant energy flux density of organic light-emitting devices manufactured according to the examples and comparative examples at different voltages. According to the current densities and brightness of the organic light-emitting devices at different voltages, an operating voltage Von, a current efficiency (CE, Cd/A), and an external quantum efficiency (EQE) under the same current density (10 mA/cm²) were obtained. The service life LT95 was obtained by measuring a lasting time period before the brightness of the organic light-emitting device was reduced to 95% of an initial brightness (measured at 50 mA/cm²).

The results of the performance test of the organic light-emitting devices are shown in TABLE 1.

TABLE 1

| | Host | Driving | CE | Lifetime |
|---|---|---|---|---|
| No. | material | voltage (V) | (cd/A) | LT95 |
| Device Example 1 | H006 | 3.87 | 44.9 | 150 |
| Device Example 2 | H018 | 3.86 | 45.4 | 151 |
| Device Example 3 | H019 | 3.82 | 46.1 | 155 |
| Device Example 4 | H035 | 3.88 | 44.8 | 150 |
| Device Example 5 | H041 | 3.83 | 46.0 | 154 |
| Device Example 6 | H092 | 3.86 | 45.4 | 152 |
| Device Example 7 | H093 | 3.85 | 45.7 | 154 |
| Device Example 8 | H099 | 3.86 | 45.3 | 151 |
| Device Example 9 | H102 | 3.88 | 45.1 | 150 |
| Device Example 10 | H119 | 3.82 | 46.0 | 155 |
| Device Comparative | Compound | 4.05 | 41.8 | 139 |
| Example 1 | M1 | | | |
| Device Comparative | Compound | 4.15 | 41.5 | 128 |
| Example 2 | M2 | | | |

As can be seen from Table 1, compared with Device Comparative Example 1 and Device Comparative Example 2, the organic light-emitting devices according to the present disclosure have lower driving voltages, higher luminous efficiencies and longer device lifetime. Regarding the organic light-emitting devices according to the present disclosure, the driving voltages are lower than 3.88V, and the current efficiencies are greater than 44.9 cd/A. The performances of organic light-emitting devices according to the present disclosure have been significantly improved over the comparative devices, mainly attributed to the bipolar characteristics of the materials of the present disclosure that simultaneously transmit holes and electrons. These compounds are conducive to the charge transfer balance in the light-emitting layer, broaden the exciton recombination region and improve the efficiency of the devices.

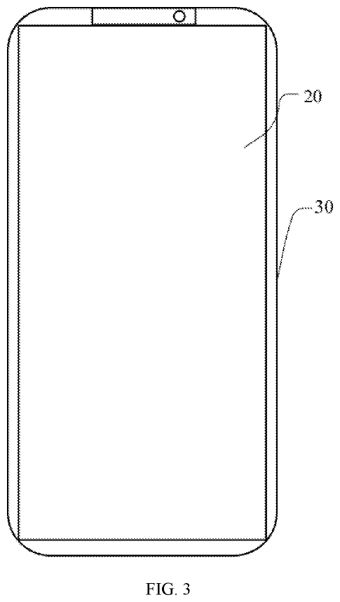

The present disclosure further provides a display apparatus, which includes the organic light-emitting display panel as described above. The display apparatus can be a display screen of a mobile phone, a computer, a TV, a smart watch, a smart car, a VR or AR helmet, or a display screen of any other smart devices. FIG. 3 is a schematic diagram of a display apparatus according to an embodiment of the present disclosure. In FIG. 3, 20 indicates a display panel of a mobile phone, and 30 indicates a display apparatus.

The above are preferred embodiments for illustrating the present disclosure, but not intended to limit the claims. Those skilled in the art can make changes and modifications without departing from the concept of the present disclosure. The protection scope shall be defined by the pending claims.

What is claimed is:

1. A compound, having a chemical structure represented by formula 1: 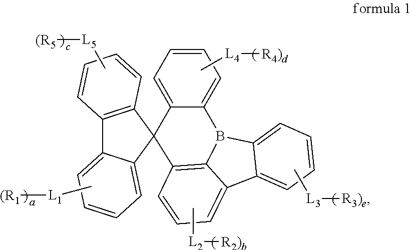
wherein L₁-L₅ are each a linking group independently selected from the group consisting of a single bond, C1-C10 alkylene, C6-C30 arylene, C6-C30 fused arylene, C4-C30 heteroarylene, and C4-C30 fused heteroarylene;
R₁-R₅ are each independently selected from the group consisting of hydrogen, a substituted or unsubstituted phenyl, a substituted or unsubstituted biphenyl, a substituted or unsubstituted naphthyl, a substituted or unsubstituted anthryl, a substituted or unsubstituted phenanthryl, a substituted or unsubstituted acenaphthylenyl, a substituted or unsubstituted pyrenyl, a substituted or unsubstituted perylenyl, a substituted or unsubstituted fluorenyl, a substituted or unsubstituted spirobifluorenyl, a substituted or unsubstituted chrysenyl, a substituted or unsubstituted triphenylenyl, a substituted or unsubstituted benzoanthryl, a substituted or unsubstituted fluoranthenyl, a substituted or unsubstituted picenyl, a substituted or unsubstituted furyl, a substituted or unsubstituted benzofuryl, a substituted or unsubstituted dibenzofuryl, a substituted or unsubstituted thienyl, a substituted or unsubstituted benzothienyl, a substituted or unsubstituted dibenzothienyl, a substituted or unsubstituted triazinyl, a substituted or unsubstituted phenanthrolinyl, a substituted or unsubstituted quinolinyl, carbazolyl and a carbazolyl-derived group, acridinyl and an acridinyl-derived group, diphenylamino and a diphenylamino-derived group, and triphenylamino and a triphenylamino-derived group; and
a, b, c, d, and e are each independently an integer selected from the group consisting of 0, 1, 2, and 3.

2. The compound according to claim 1, wherein L₁ and L₂ are each independently selected from the group consisting of phenylene, naphthylene, anthrylene, phenanthrylene, pyridylidene, furylidene, pyrimidinylidene, triazinylene, benzofurylene, thienylene, benzothienylene, pyrrolylene, indolylidene, carbazolylene, oxazolylene, benzoxazolylene, thiazolylene, benzothiazolylene, imidazolylene, benzoimidazolylene, indazolylene, quinolylene, and isoquinolylene.

3. The compound according to claim 1, wherein three of L₁-L₅ are each a single bond, and the other two of L₁-L₅ are each a connecting group selected from the group consisting of C1-C10 alkylene, C6-C30 arylene, C6-C30 fused arylene, C4-C30 heteroarylene, and C4-C30 fused heteroarylene; and
three of R₁-R₅ are each hydrogen, and the other two of R₁-R₅ are each a substituent other than hydrogen.

4. The compound according to claim 1, wherein R₁-R₅ are each independently selected from of the following groups: 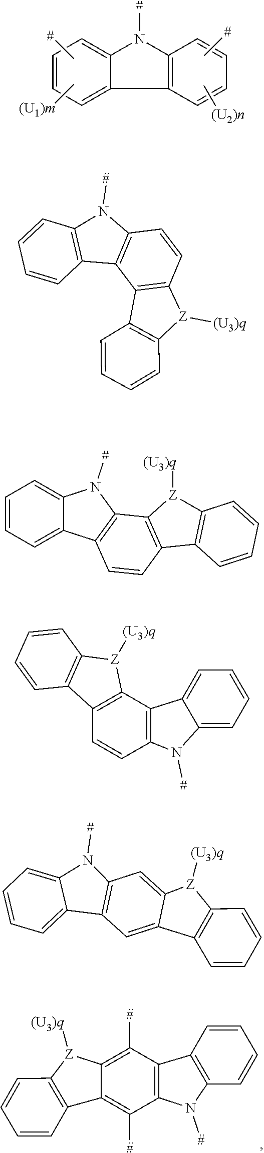
wherein U₁ and U₂ are each independently selected from the group consisting of hydrogen, C1-C6 alkyl, C1-C6 alkoxy, and C6-C12 aryl; and m and n are each independently 0, 1, or 2;
Z is a carbon atom, a nitrogen atom, an oxygen atom, or a sulfur atom;
U₃ is selected from the group consisting of hydrogen, C1-C6 alkyl, C1-C6 alkoxy, and C6-C12 aryl; and q is 0, 1, or 2; and
when Z is an oxygen atom or a sulfur atom, q is 0; and
# indicates a possible bonding position.

5. The compound according to claim 4, wherein R₁-R₅ are each independently selected from of the following groups:

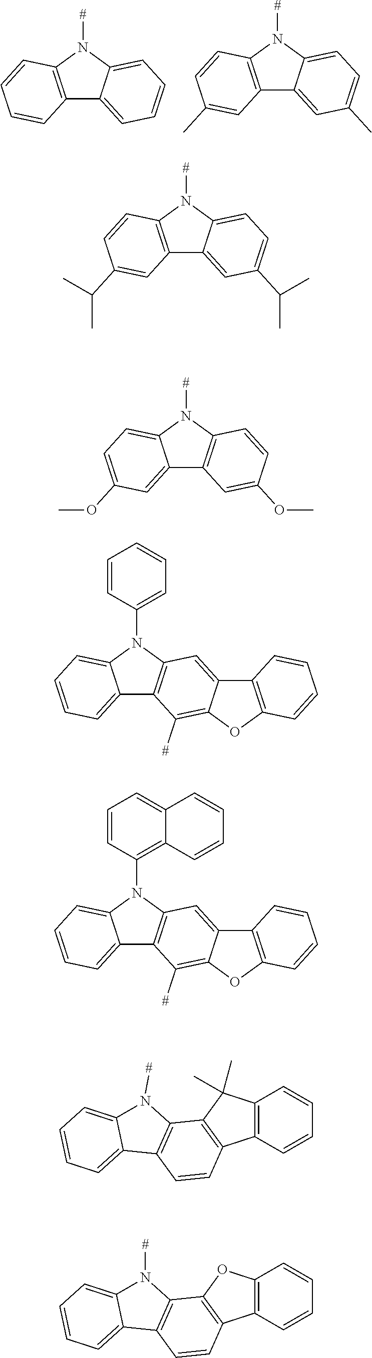

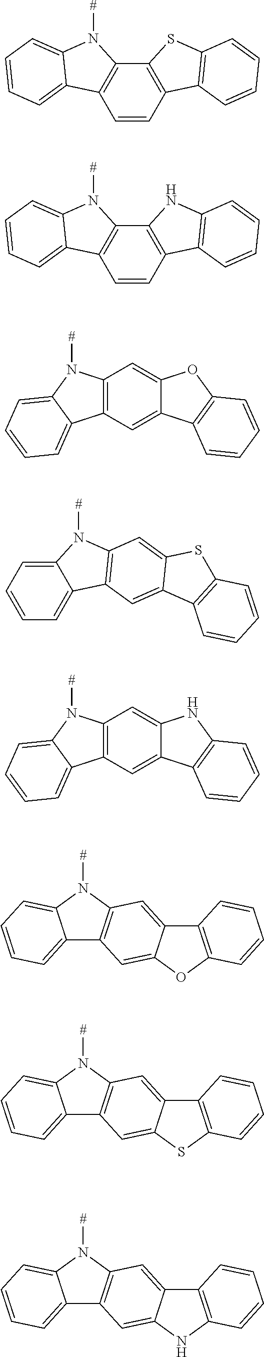

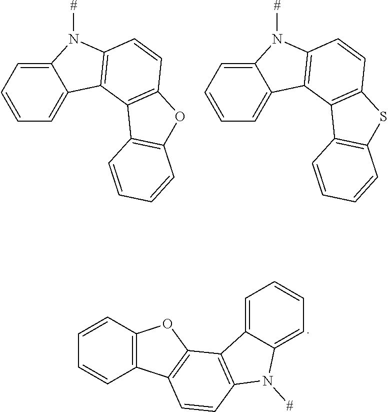

6. The compound according to claim 1, wherein D₁ and D₂ are each independently selected from the following groups: 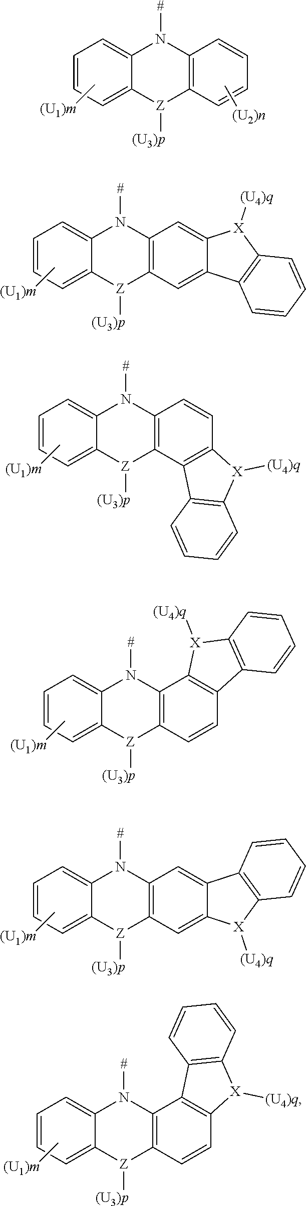
wherein U₁ and U₂ are each independently selected from the group consisting of hydrogen, C1-C6 alkyl, C3-C6 cycloalkyl, C1-C6 alkoxy, C6-C12 aryl, and a substituted or unsubstituted C12-C20 diphenylamino; and m and n are each independently 0, 1, or 2;
Z and X are each independently a carbon atom, a nitrogen atom, an oxygen atom, a sulfur atom or a silicon atom;
U₃ and U₄ are each independently selected from the group consisting of hydrogen, C1-C6 alkyl, C3-C6 cycloalkyl, C1-C6 alkoxy, C6-C12 aryl, and a substituted or unsubstituted C12-C20 diphenylamino; p and q are each independently 0, 1, or 2;
when Z is an oxygen atom or a sulfur atom, p is 0; or when X is an oxygen atom or a sulfur atom, q is 0; and
# indicates a bonding position.

7. The compound according to claim 6, wherein R₁-R₅ are each independently selected from the following groups: 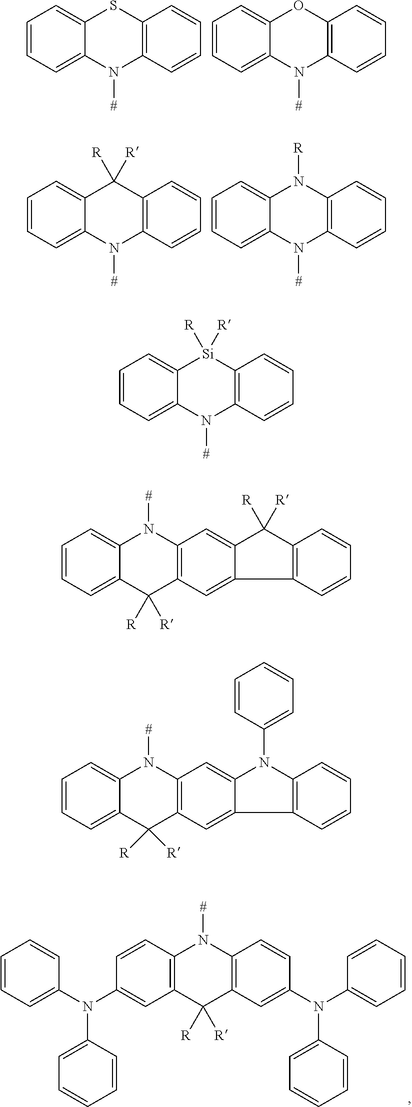
wherein R and R′ are each independently selected from the group consisting of hydrogen, C1-C6 alkyl, C1-C6 alkoxy, C1-C6 cycloalkyl, C6-C12 aryl, and C4-C12 heteroaryl.

8. The compound according to claim 1, wherein R₁-R₅ are each independently selected from the following groups: 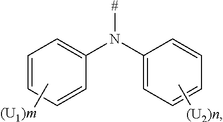
wherein U₁ and U₂ are each independently selected from the group consisting of hydrogen, C1-C6 alkyl, and C1-C6 alkoxy;
m and n are each independently 0, 1, or 2; and
# indicates a bonding position.

9. The compound according to claim 8, wherein R₁-R₅ are each independently selected from the following groups: 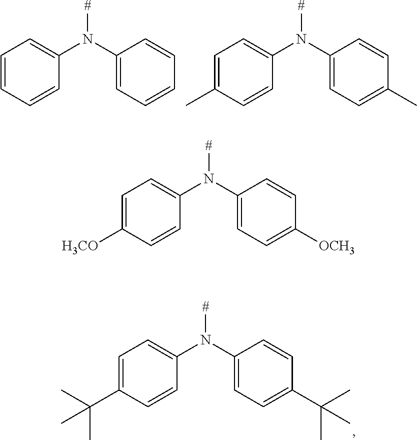
wherein # indicates a bonding position.

10. The compound according to claim 1, wherein one of R₁-R₅ is carbazolyl, and another one of R₁-R₅ is an azaaromatic group.

11. The compound according to claim 1, wherein one to four of R₁-R₅ are each selected from the group consisting of triphenylamino, carbazolyl, biphenyl, and naphthyl; and the rest of R₁-R₅ is each selected from the group consisting of hydrogen, phenanthrolinyl, and triazinyl.

12. The compound according to claim 1, wherein the compound is independently selected from of the following compounds:

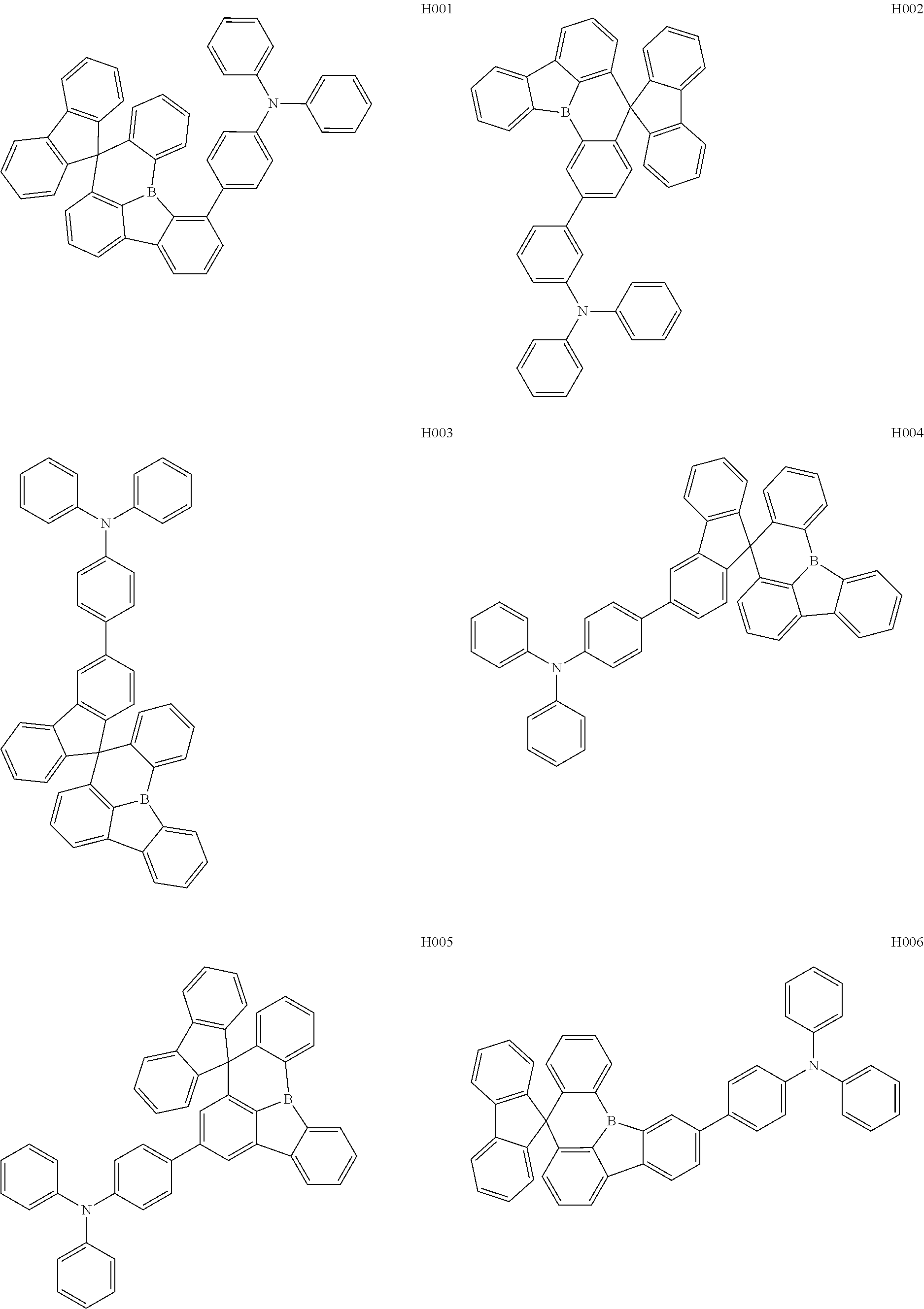

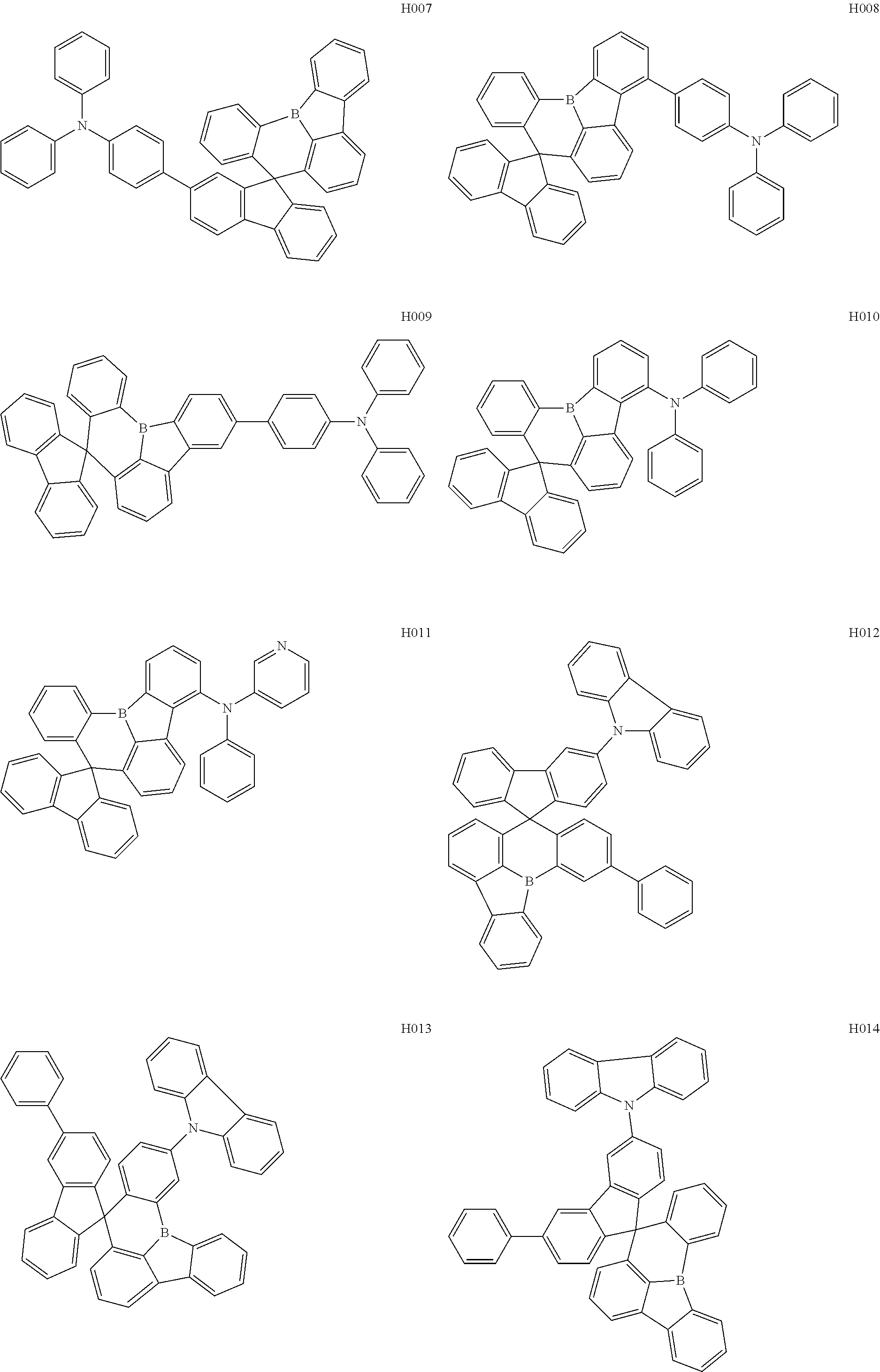

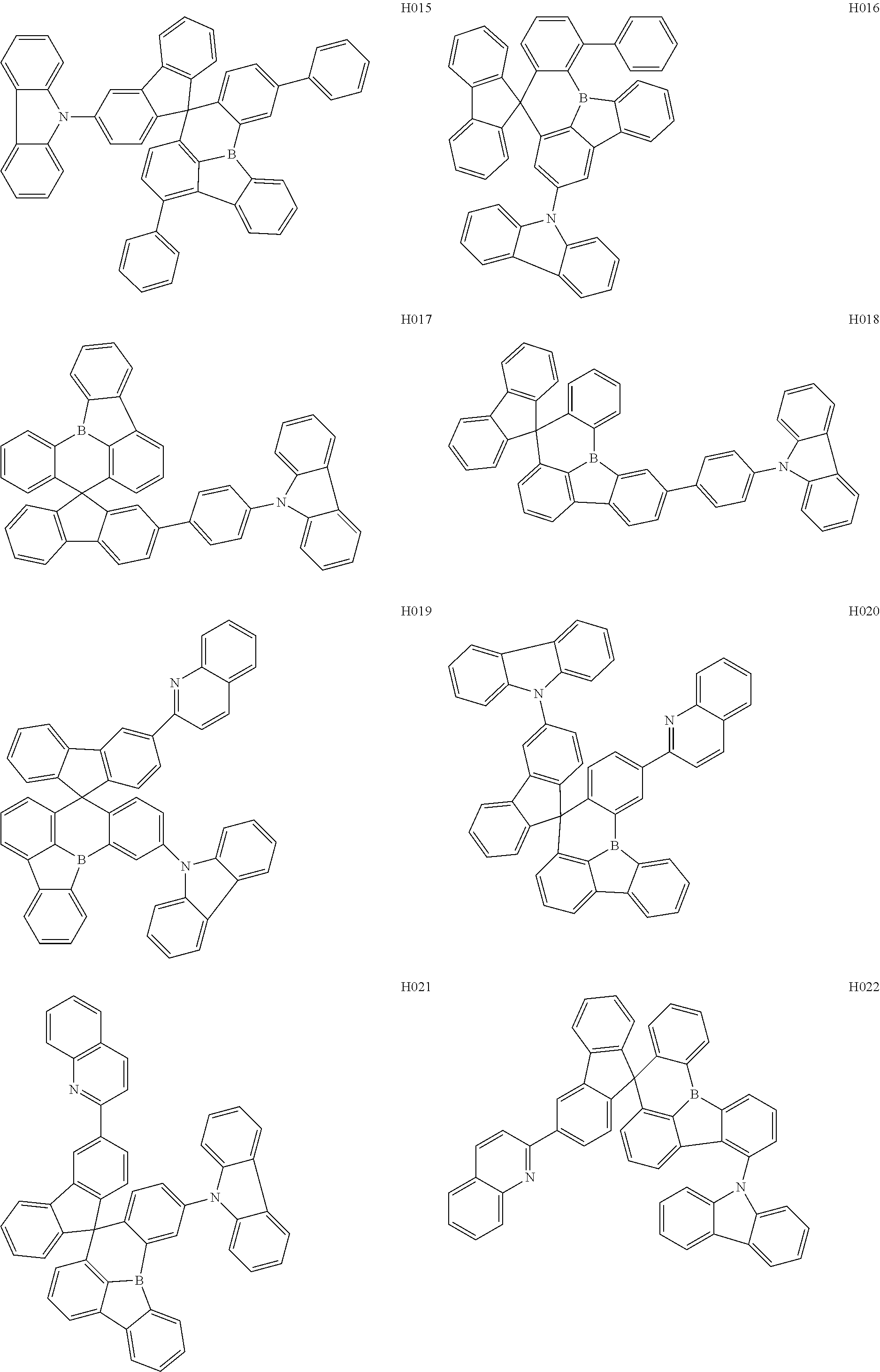

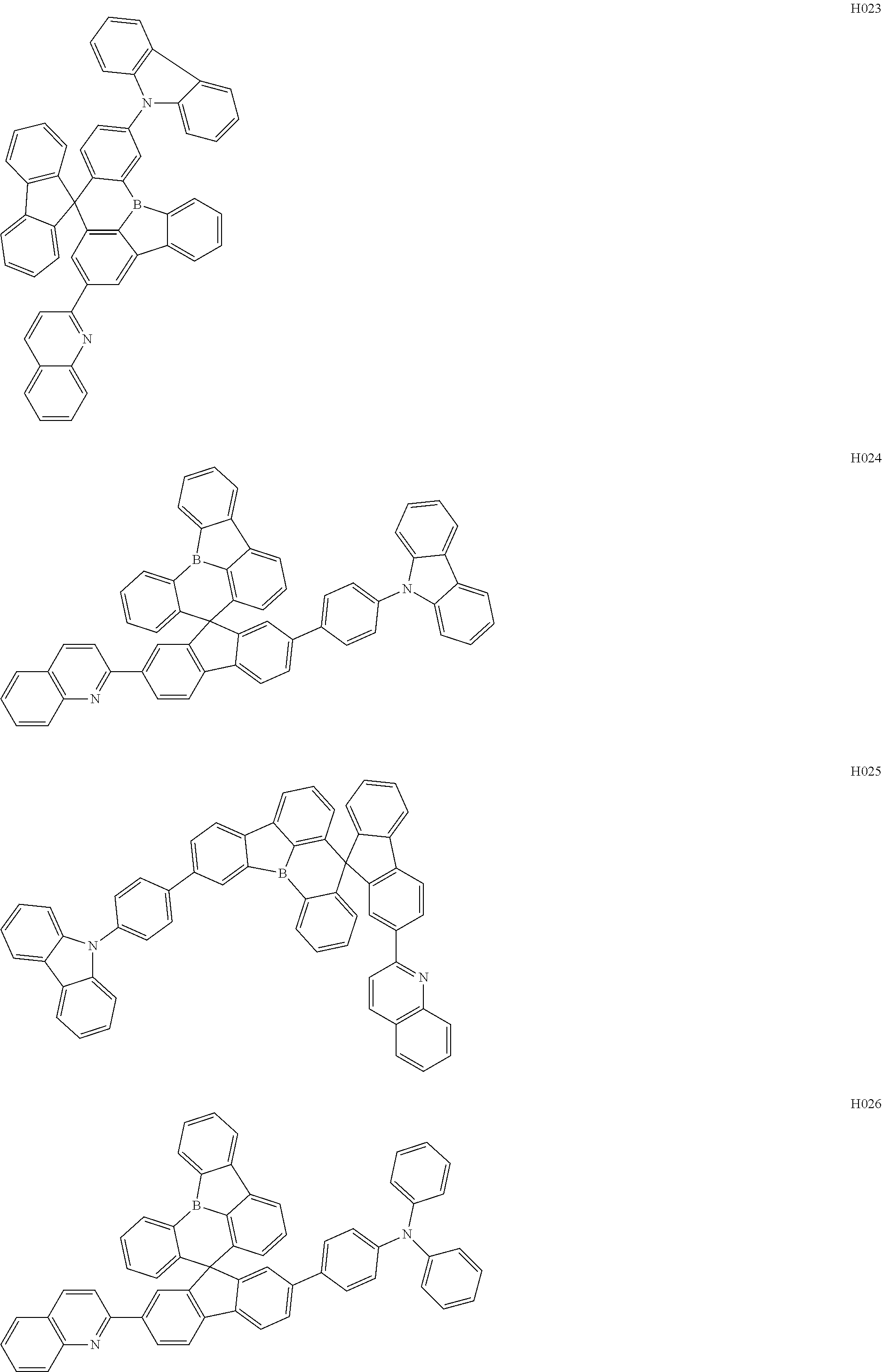 [SMILES: c1ccc2c(c1)B1c3cc(-n4c5ccccc5c5ccccc54)ccc3C3(c4ccccc4-c4ccccc43)c3cc(-c4ccc5ccccc5n4)cc-2c31 ; c1ccc2c(c1)B1c3ccccc3C3(c4cc(-c5ccc(-n6c7ccccc7c7ccccc76)cc5)ccc4-c4ccc(-c5ccc6ccccc6n5)cc43)c3cccc-2c31 ; c1ccc2c(c1)B1c3cc(-c4ccc(-n5c6ccccc6c6ccccc65)cc4)ccc3-c3cccc(c31)C21c2ccccc2-c2ccc(-c3ccc4ccccc4n3)cc21 ; c1ccc(N(c2ccccc2)c2ccc(-c3ccc4c(c3)C3(c5ccccc5B5c6ccccc6-c6cccc3c65)c3cc(-c5ccc6ccccc6n5)ccc3-4)cc2)cc1]

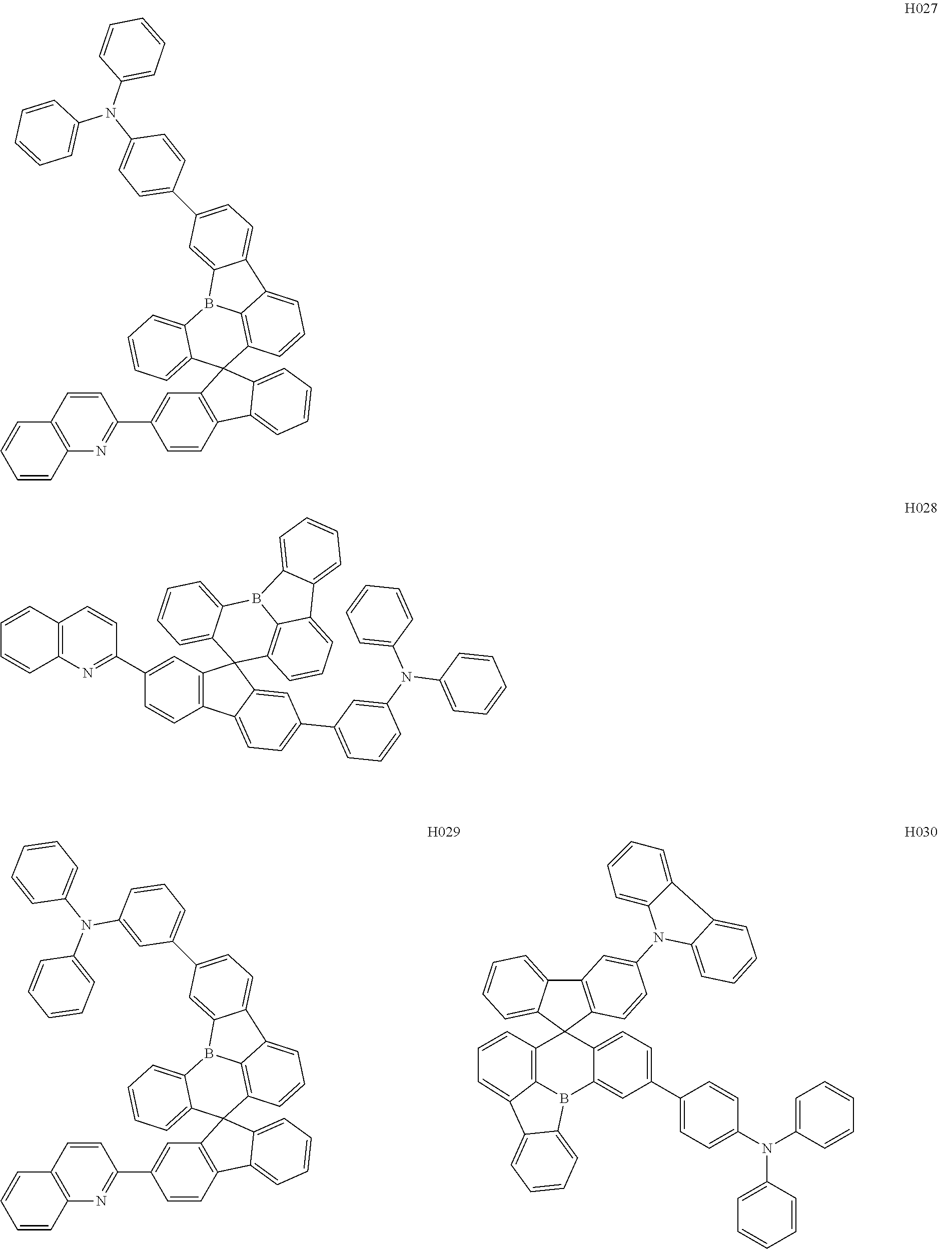 [SMILES: c1ccc(N(c2ccccc2)c2ccc(-c3ccc4c(c3)B3c5ccccc5C5(c6ccccc6-c6ccc(-c7ccc8ccccc8n7)cc65)c5cccc-4c53)cc2)cc1 ; c1ccc(N(c2ccccc2)c2cccc(-c3ccc4c(c3)C3(c5ccccc5B5c6ccccc6-c6cccc3c65)c3cc(-c5ccc6ccccc6n5)ccc3-4)c2)cc1 ; c1ccc(N(c2ccccc2)c2cccc(-c3ccc4c(c3)B3c5ccccc5C5(c6ccccc6-c6ccc(-c7ccc8ccccc8n7)cc65)c5cccc-4c53)c2)cc1 ; c1ccc(N(c2ccccc2)c2ccc(-c3ccc4c(c3)B3c5ccccc5-c5cccc(c53)C43c4ccccc4-c4cc(-n5c6ccccc6c6ccccc65)ccc43)cc2)cc1]

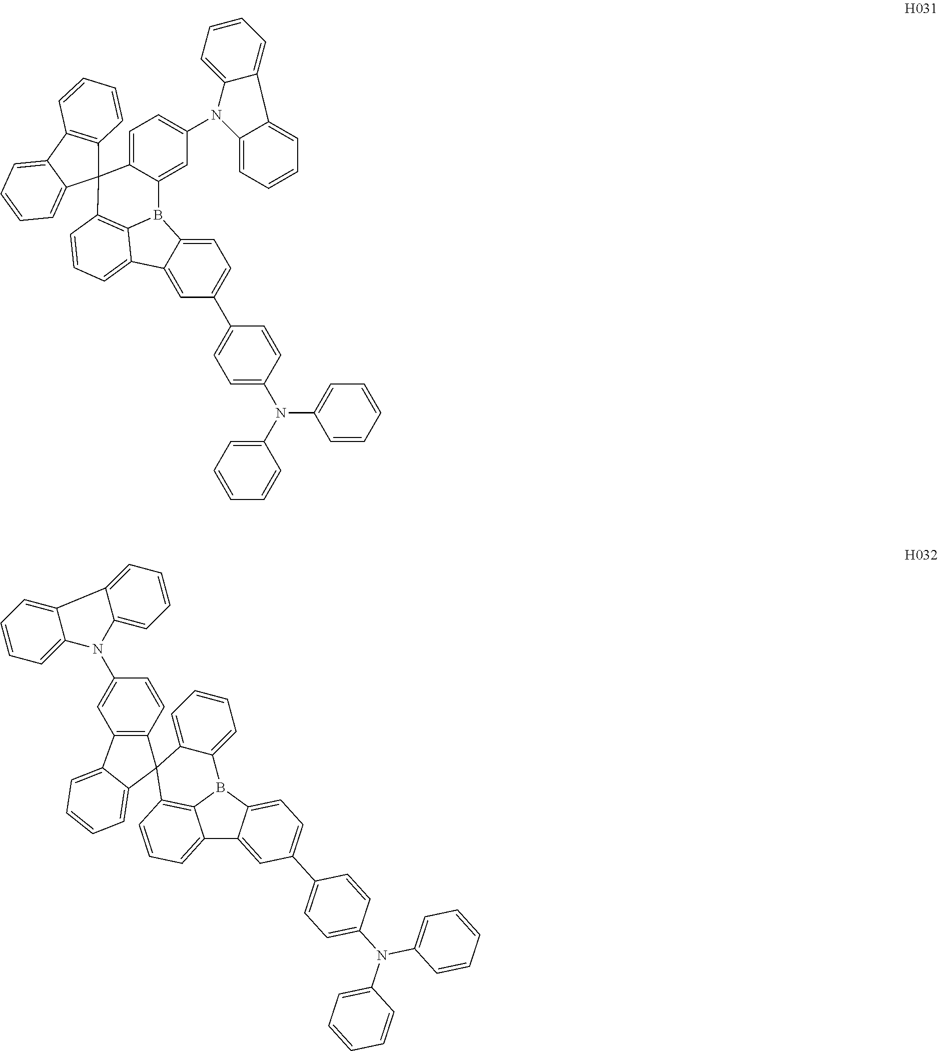 [SMILES: c1ccc(N(c2ccccc2)c2ccc(-c3ccc4c(c3)-c3cccc5c3B4c3cc(-n4c6ccccc6c6ccccc64)ccc3C53c4ccccc4-c4ccccc43)cc2)cc1 ; c1ccc(N(c2ccccc2)c2ccc(-c3ccc4c(c3)-c3cccc5c3B4c3ccccc3C53c4ccccc4-c4cc(-n5c6ccccc6c6ccccc65)ccc43)cc2)cc1]

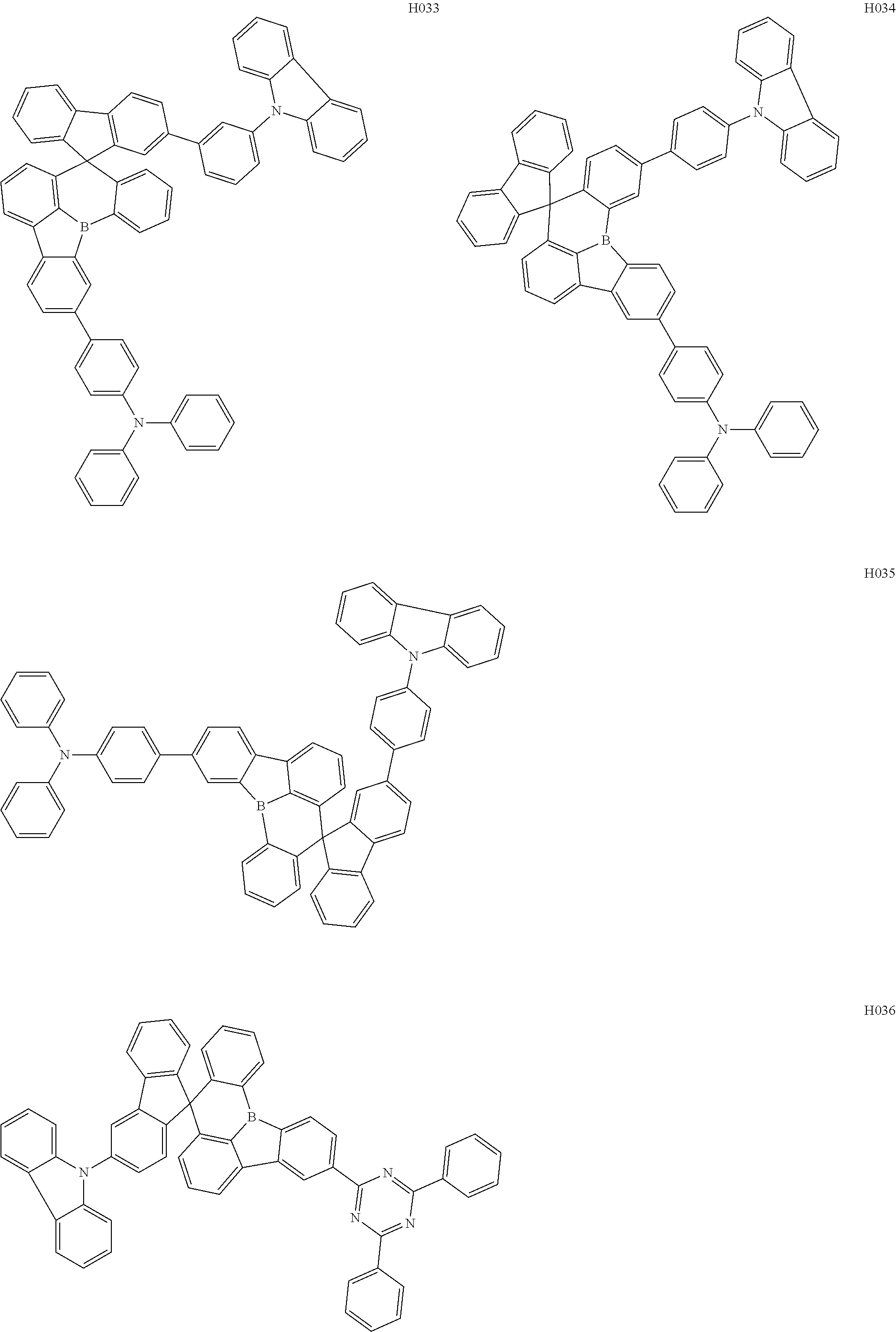 [SMILES: c1ccc(N(c2ccccc2)c2ccc(-c3ccc4c(c3)B3c5ccccc5C5(c6ccccc6-c6ccc(-c7cccc(-n8c9ccccc9c9ccccc98)c7)cc65)c5cccc-4c53)cc2)cc1 ; c1ccc(N(c2ccccc2)c2ccc(-c3ccc4c(c3)-c3cccc5c3B4c3cc(-c4ccc(-n6c7ccccc7c7ccccc76)cc4)ccc3C53c4ccccc4-c4ccccc43)cc2)cc1 ; c1ccc(N(c2ccccc2)c2ccc(-c3ccc4c(c3)B3c5ccccc5C5(c6ccccc6-c6ccc(-c7ccc(-n8c9ccccc9c9ccccc98)cc7)cc65)c5cccc-4c53)cc2)cc1 ; c1ccc(-c2nc(-c3ccccc3)nc(-c3ccc4c(c3)-c3cccc5c3B4c3ccccc3C53c4ccccc4-c4cc(-n5c6ccccc6c6ccccc65)ccc43)n2)cc1]

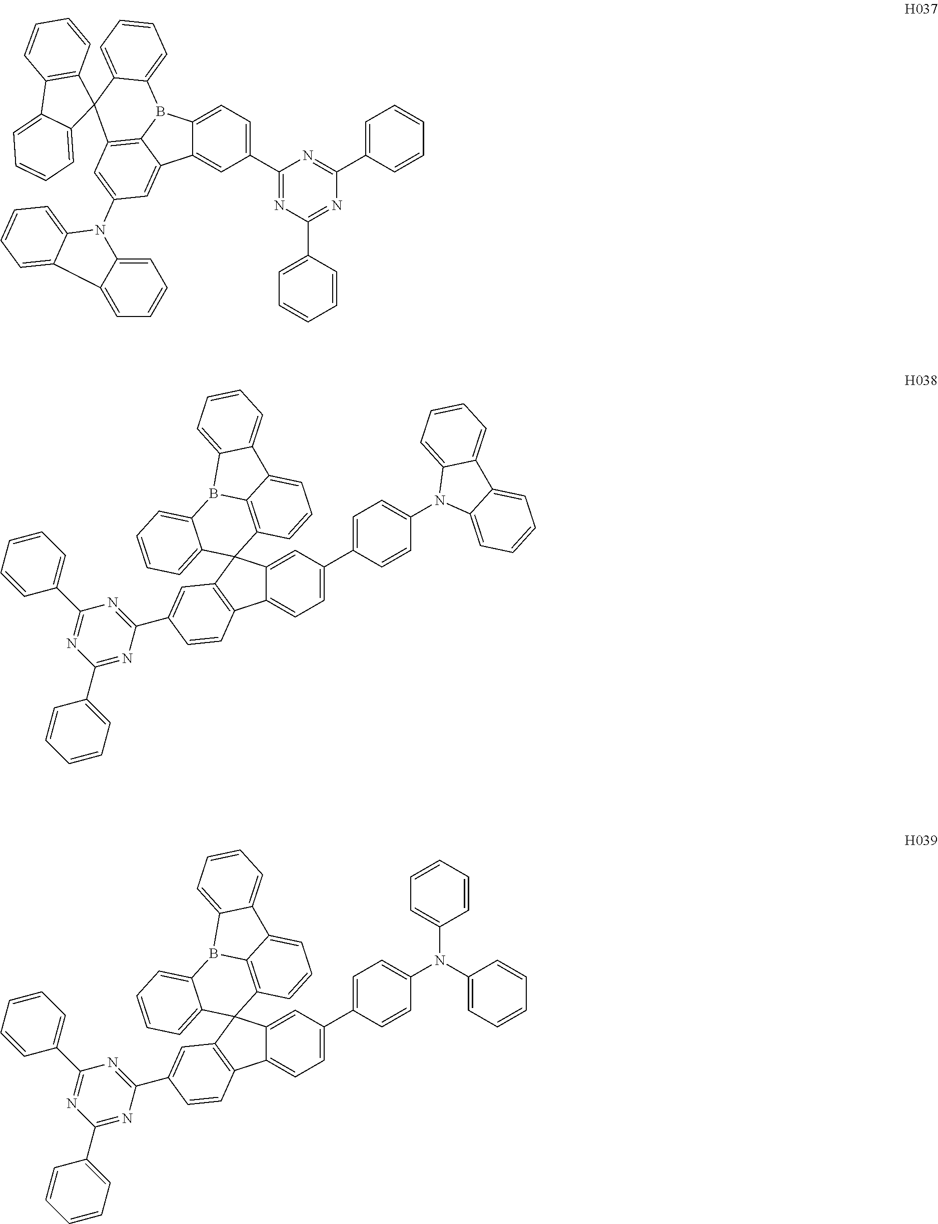 [SMILES: c1ccc(-c2nc(-c3ccccc3)nc(-c3ccc4c(c3)-c3cc(-n5c6ccccc6c6ccccc65)cc5c3B4c3ccccc3C53c4ccccc4-c4ccccc43)n2)cc1 ; c1ccc(-c2nc(-c3ccccc3)nc(-c3ccc4c(c3)C3(c5ccccc5B5c6ccccc6-c6cccc3c65)c3cc(-c5ccc(-n6c7ccccc7c7ccccc76)cc5)ccc3-4)n2)cc1 ; c1ccc(-c2nc(-c3ccccc3)nc(-c3ccc4c(c3)C3(c5ccccc5B5c6ccccc6-c6cccc3c65)c3cc(-c5ccc(N(c6ccccc6)c6ccccc6)cc5)ccc3-4)n2)cc1]

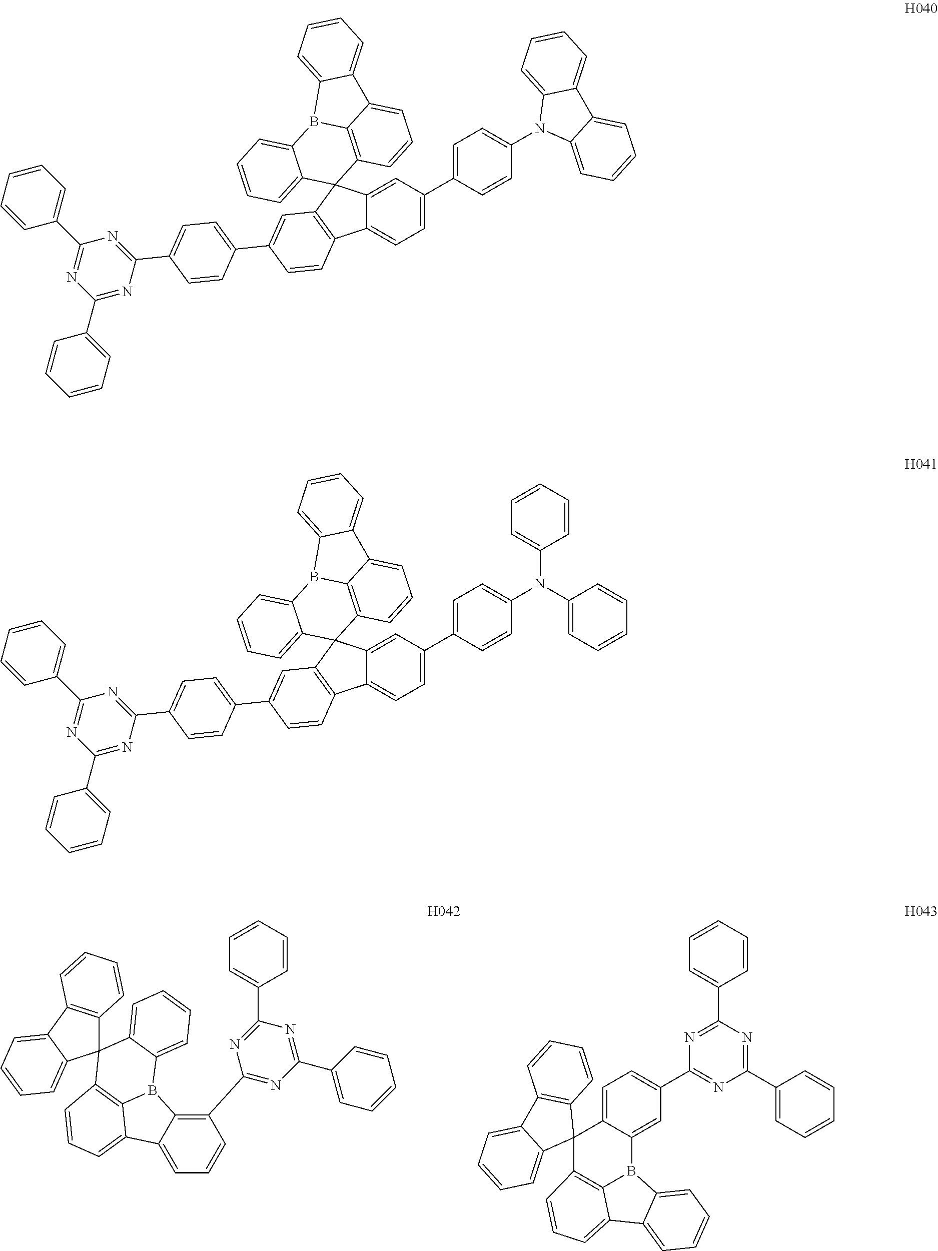 [SMILES: c1ccc(-c2nc(-c3ccccc3)nc(-c3ccc(-c4ccc5c(c4)C4(c6ccccc6B6c7ccccc7-c7cccc4c76)c4cc(-c6ccc(-n7c8ccccc8c8ccccc87)cc6)ccc4-5)cc3)n2)cc1 ; c1ccc(-c2nc(-c3ccccc3)nc(-c3ccc(-c4ccc5c(c4)C4(c6ccccc6B6c7ccccc7-c7cccc4c76)c4cc(-c6ccc(N(c7ccccc7)c7ccccc7)cc6)ccc4-5)cc3)n2)cc1 ; c1ccc(-c2nc(-c3ccccc3)nc(-c3cccc4c3B3c5ccccc5C5(c6ccccc6-c6ccccc65)c5cccc-4c53)n2)cc1 ; c1ccc(-c2nc(-c3ccccc3)nc(-c3ccc4c(c3)B3c5ccccc5-c5cccc(c53)C43c4ccccc4-c4ccccc43)n2)cc1]

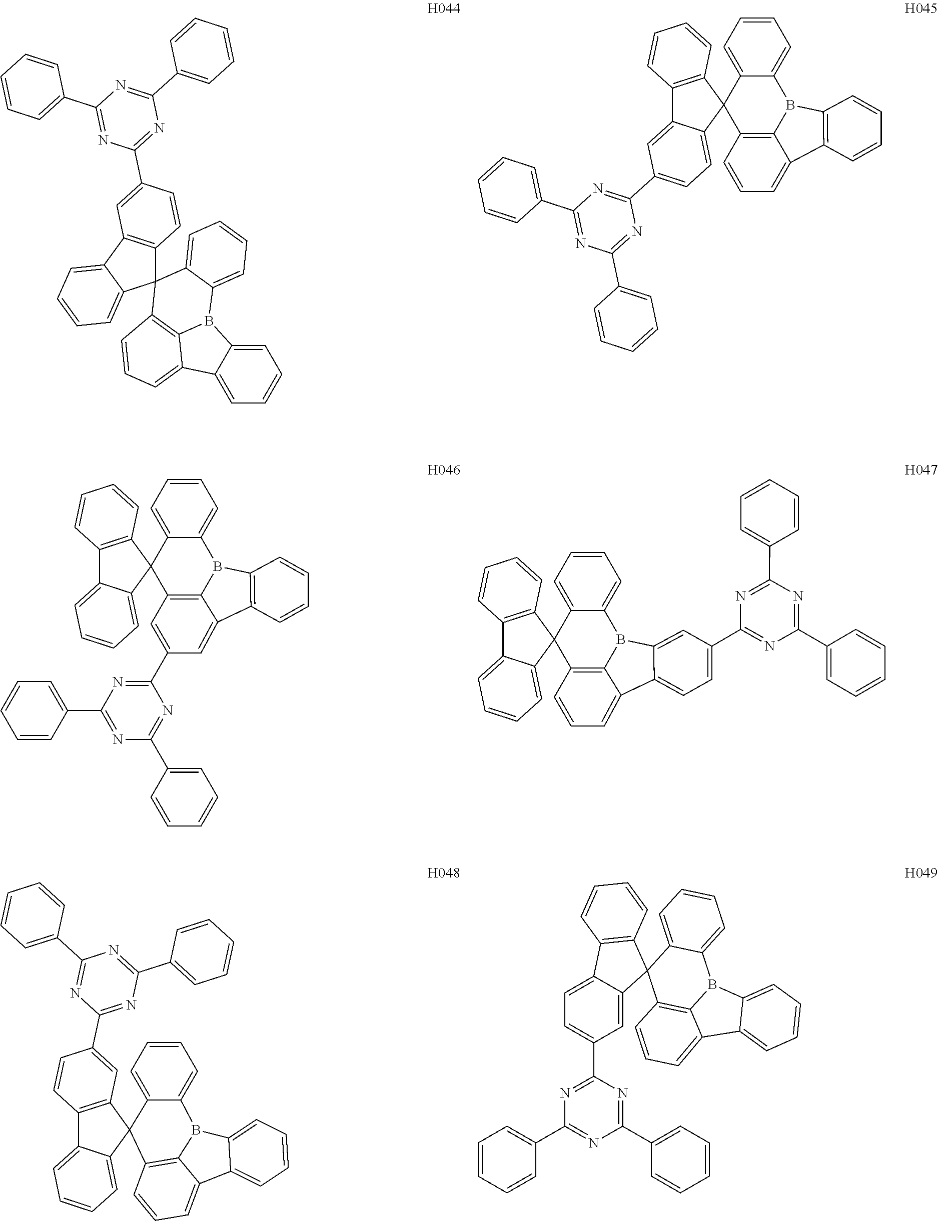

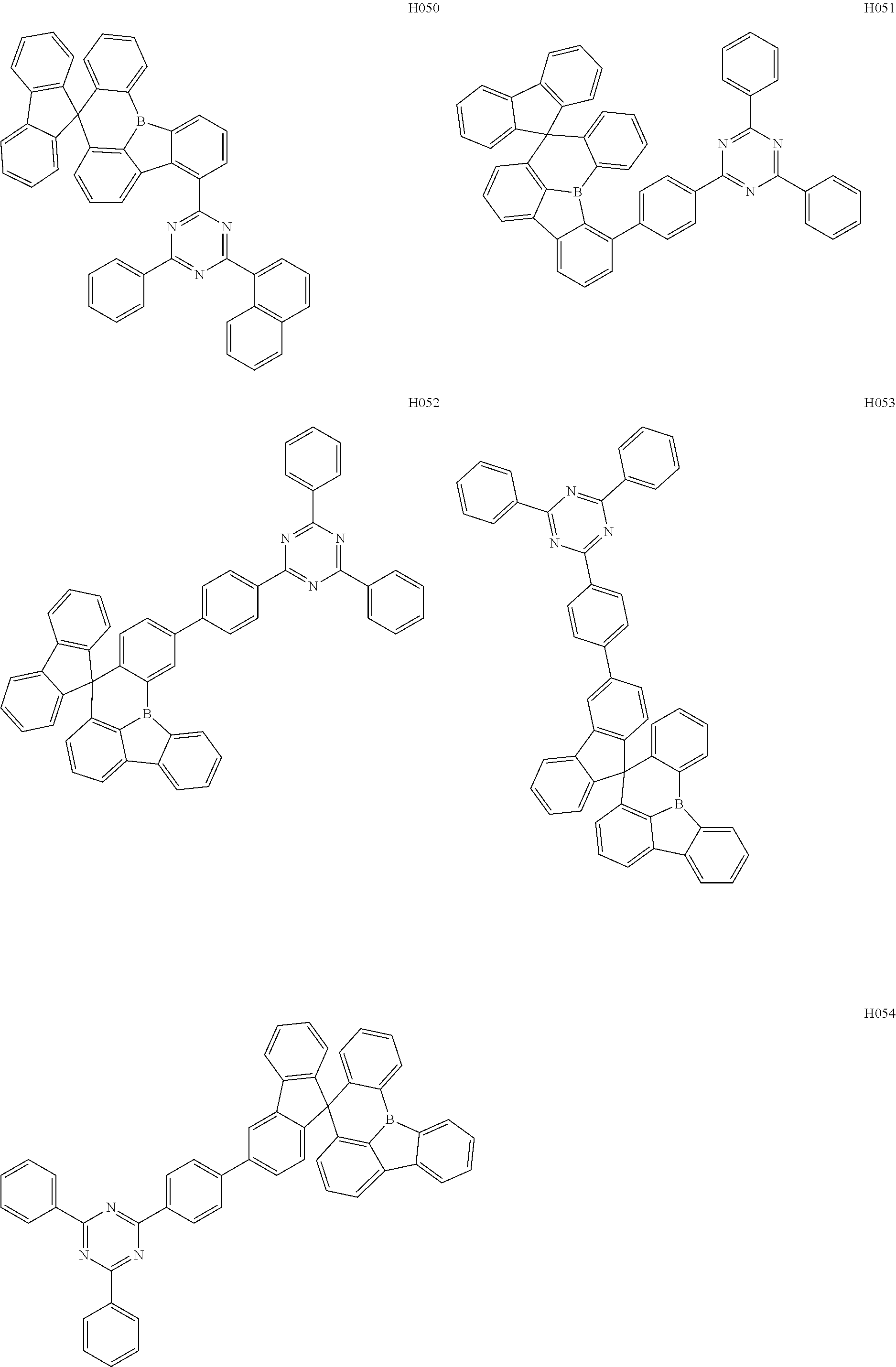 [SMILES: c1ccc(-c2nc(-c3cccc4c3-c3cccc5c3B4c3ccccc3C53c4ccccc4-c4ccccc43)nc(-c3cccc4ccccc34)n2)cc1 ; c1ccc(-c2nc(-c3ccccc3)nc(-c3ccc(-c4cccc5c4B4c6ccccc6C6(c7ccccc7-c7ccccc76)c6cccc-5c64)cc3)n2)cc1 ; c1ccc(-c2nc(-c3ccccc3)nc(-c3ccc(-c4ccc5c(c4)B4c6ccccc6-c6cccc(c64)C54c5ccccc5-c5ccccc54)cc3)n2)cc1 ; c1ccc(-c2nc(-c3ccccc3)nc(-c3ccc(-c4ccc5c(c4)-c4ccccc4C54c5ccccc5B5c6ccccc6-c6cccc4c65)cc3)n2)cc1 ; c1ccc(-c2nc(-c3ccccc3)nc(-c3ccc(-c4ccc5c(c4)-c4ccccc4C54c5ccccc5B5c6ccccc6-c6cccc4c65)cc3)n2)cc1]

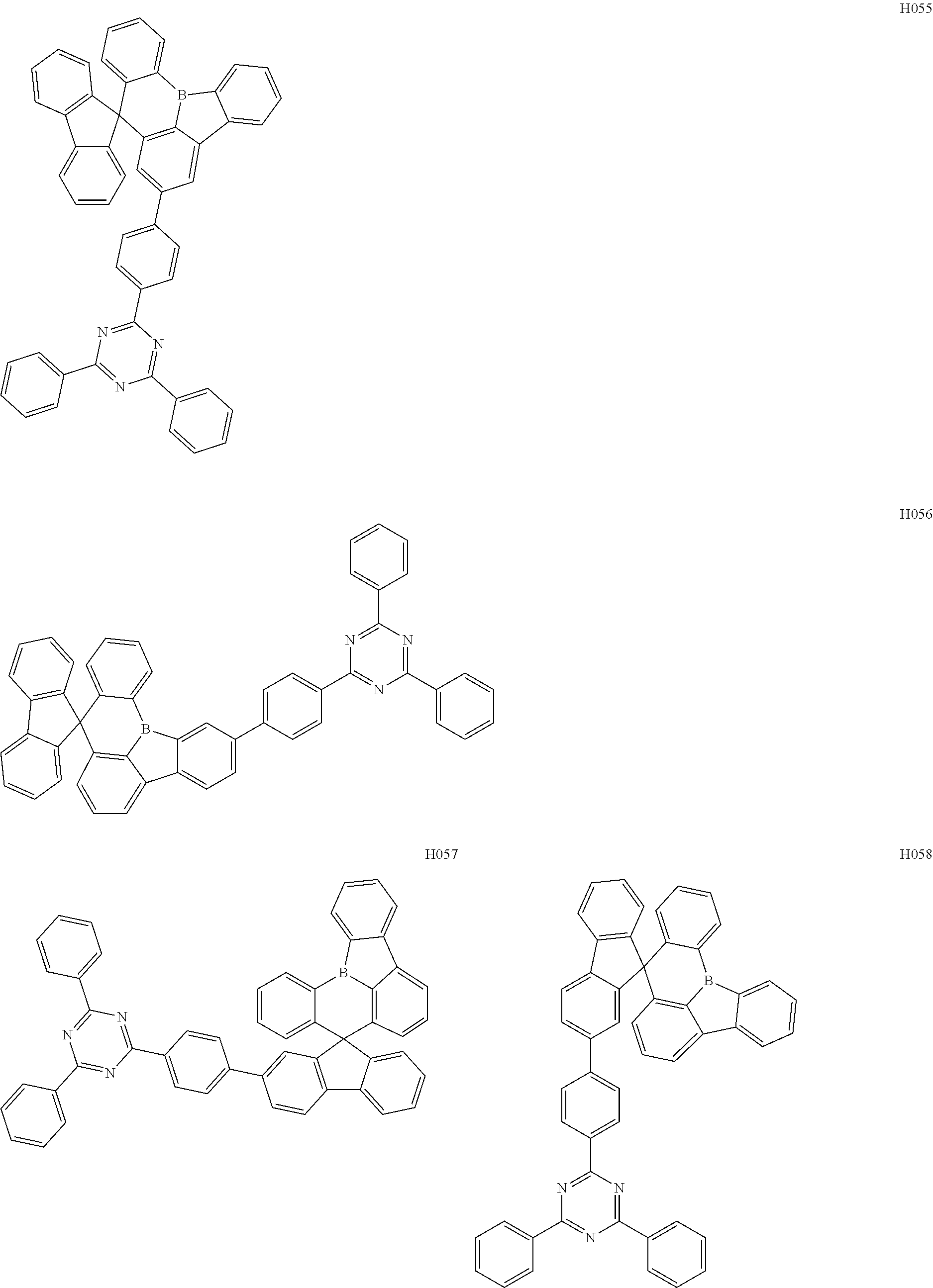 [SMILES: c1ccc(-c2nc(-c3ccccc3)nc(-c3ccc(-c4cc5c6c(c4)C4(c7ccccc7B6c6ccccc6-5)c5ccccc5-c5ccccc54)cc3)n2)cc1 ; c1ccc(-c2nc(-c3ccccc3)nc(-c3ccc(-c4ccc5c(c4)B4c6ccccc6C6(c7ccccc7-c7ccccc76)c6cccc-5c64)cc3)n2)cc1 ; c1ccc(-c2nc(-c3ccccc3)nc(-c3ccc(-c4ccc5c(c4)C4(c6ccccc6B6c7ccccc7-c7cccc4c76)c4ccccc4-5)cc3)n2)cc1 ; c1ccc(-c2nc(-c3ccccc3)nc(-c3ccc(-c4ccc5c(c4)C4(c6ccccc6B6c7ccccc7-c7cccc4c76)c4ccccc4-5)cc3)n2)cc1]

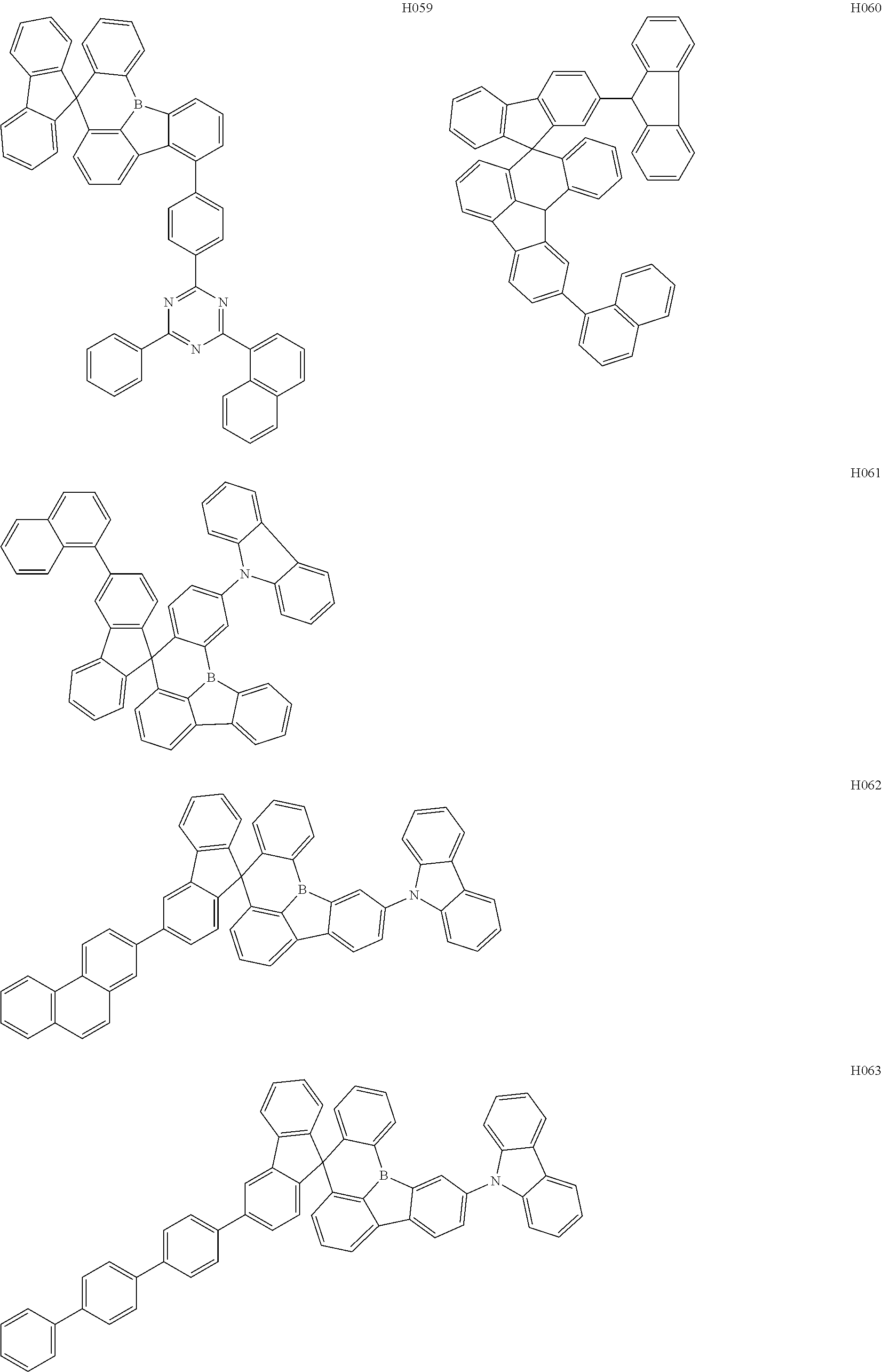

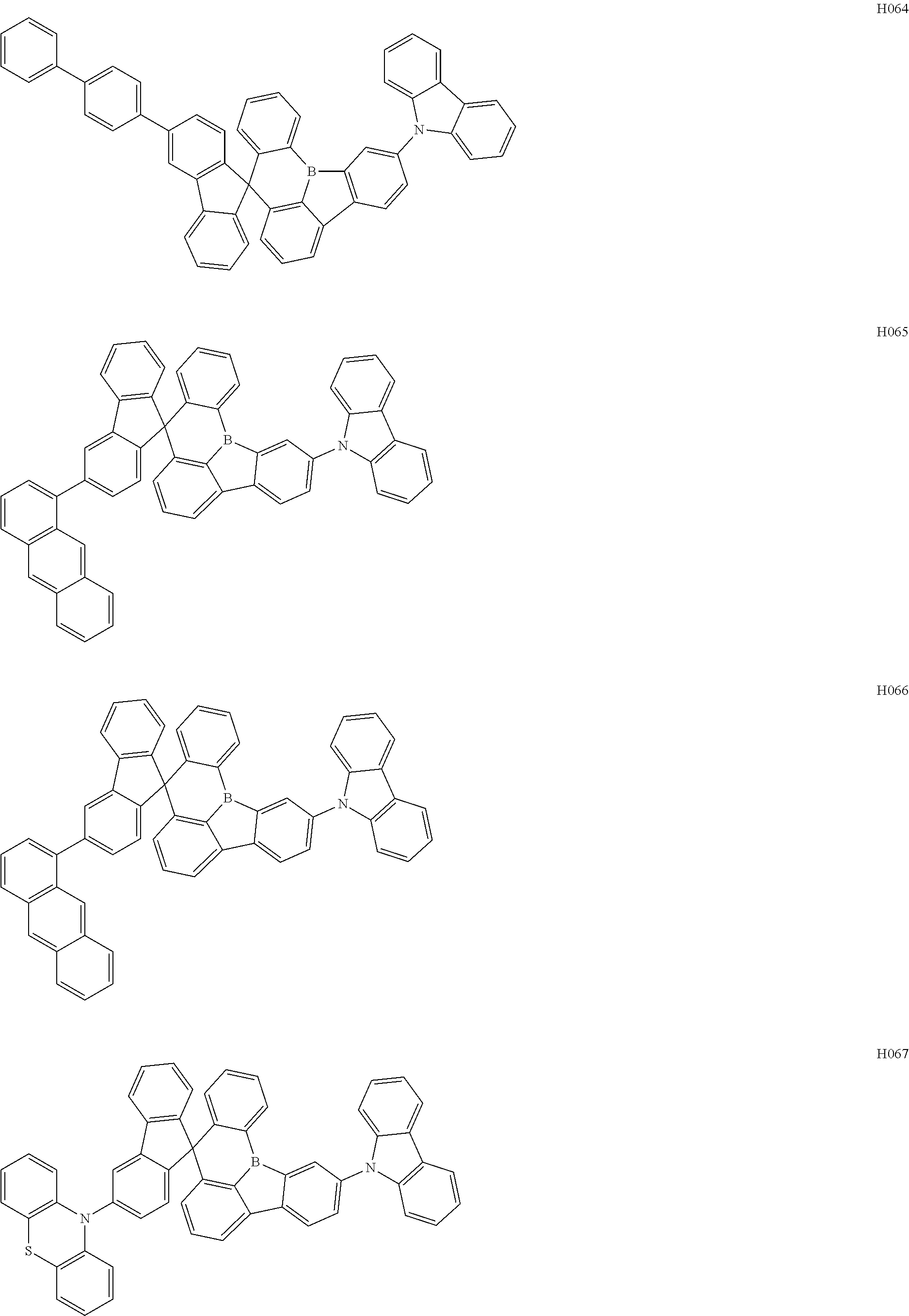 [SMILES: c1ccc(-c2ccc(-c3ccc4c(c3)-c3ccccc3C43c4ccccc4B4c5cc(-n6c7ccccc7c7ccccc76)ccc5-c5cccc3c54)cc2)cc1 ; c1ccc2c(c1)B1c3cc(-n4c5ccccc5c5ccccc54)ccc3-c3cccc(c31)C21c2ccccc2-c2cc(-c3cccc4cc5ccccc5cc34)ccc21 ; c1ccc2c(c1)B1c3cc(-n4c5ccccc5c5ccccc54)ccc3-c3cccc(c31)C21c2ccccc2-c2cc(-c3cccc4cc5ccccc5cc34)ccc21 ; c1ccc2c(c1)Sc1ccccc1N2c1ccc2c(c1)-c1ccccc1C21c2ccccc2B2c3cc(-n4c5ccccc5c5ccccc54)ccc3-c3cccc1c32]

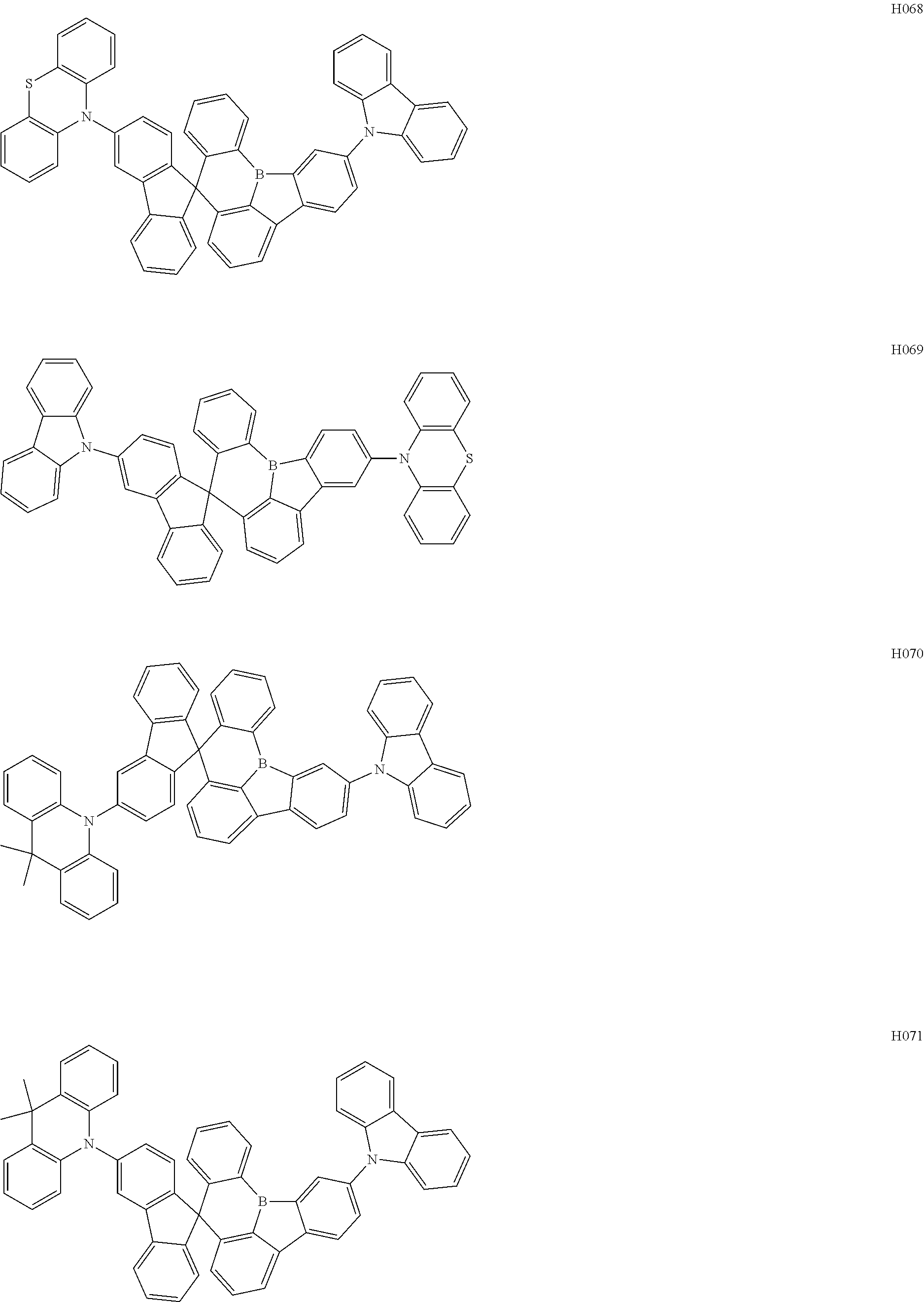 [SMILES: c1ccc2c(c1)Sc1ccccc1N2c1ccc2c(c1)-c1ccccc1C21c2ccccc2B2c3cc(-n4c5ccccc5c5ccccc54)ccc3-c3cccc1c32 ; c1ccc2c(c1)Sc1ccccc1N2c1ccc2c(c1)-c1cccc3c1B2c1ccccc1C31c2ccccc2-c2cc(-n3c4ccccc4c4ccccc43)ccc21 ; CC1(C)c2ccccc2N(c2ccc3c(c2)-c2ccccc2C32c3ccccc3B3c4cc(-n5c6ccccc6c6ccccc65)ccc4-c4cccc2c43)c2ccccc21 ; CC1(C)c2ccccc2N(c2ccc3c(c2)-c2ccccc2C32c3ccccc3B3c4cc(-n5c6ccccc6c6ccccc65)ccc4-c4cccc2c43)c2ccccc21]

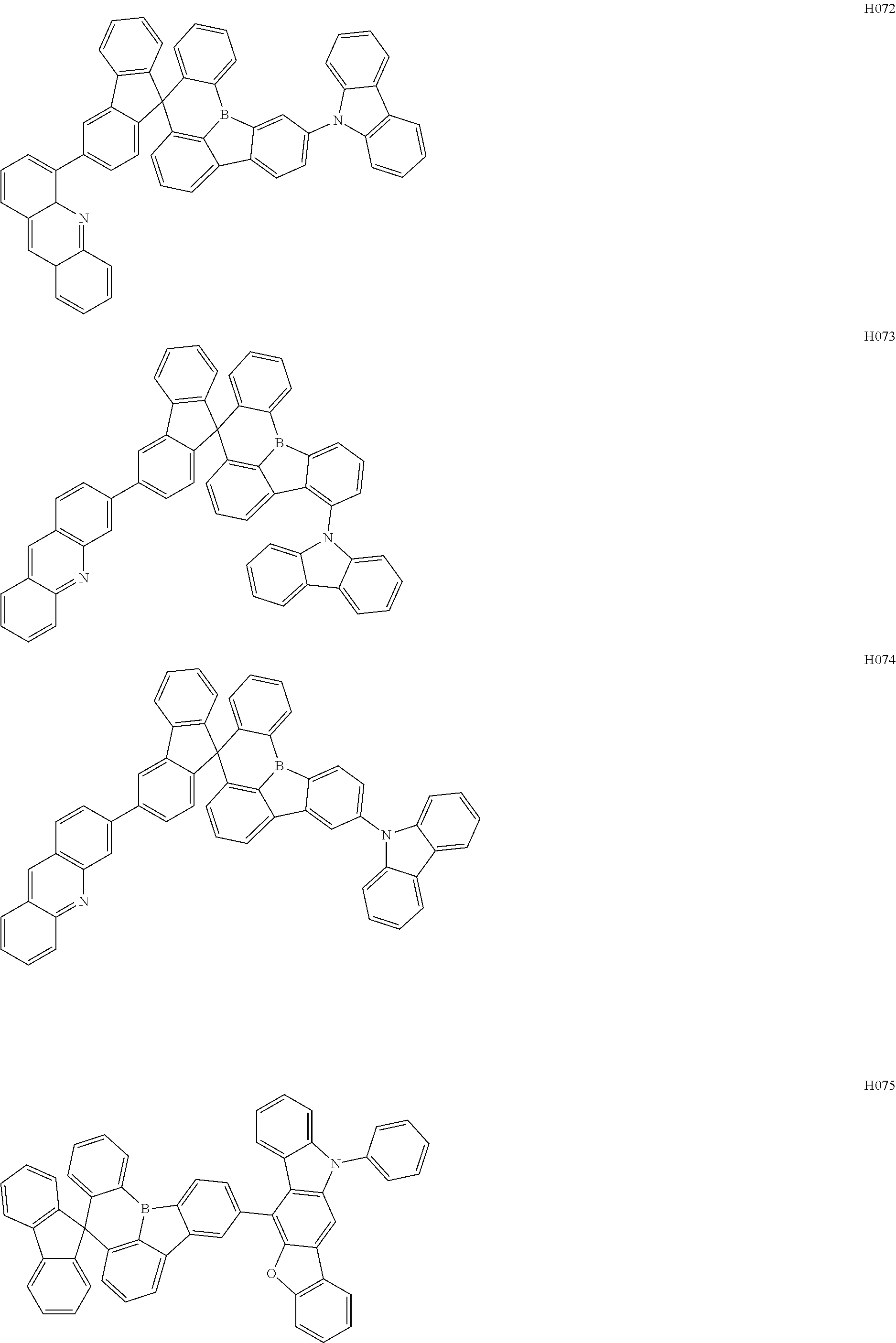 [SMILES: C1=CC2=CC3C=CC=CC3=NC2C(c2ccc3c(c2)-c2ccccc2C32c3ccccc3B3c4cc(-n5c6ccccc6c6ccccc65)ccc4-c4cccc2c43)=C1 ; c1ccc2c(c1)B1c3cccc(-n4c5ccccc5c5ccccc54)c3-c3cccc(c31)C21c2ccccc2-c2cc(-c3ccc4cc5ccccc5nc4c3)ccc21 ; c1ccc2c(c1)B1c3ccc(-n4c5ccccc5c5ccccc54)cc3-c3cccc(c31)C21c2ccccc2-c2cc(-c3ccc4cc5ccccc5nc4c3)ccc21 ; c1ccc(-n2c3ccccc3c3c(-c4ccc5c(c4)-c4cccc6c4B5c4ccccc4C64c5ccccc5-c5ccccc54)c4oc5ccccc5c4cc32)cc1]

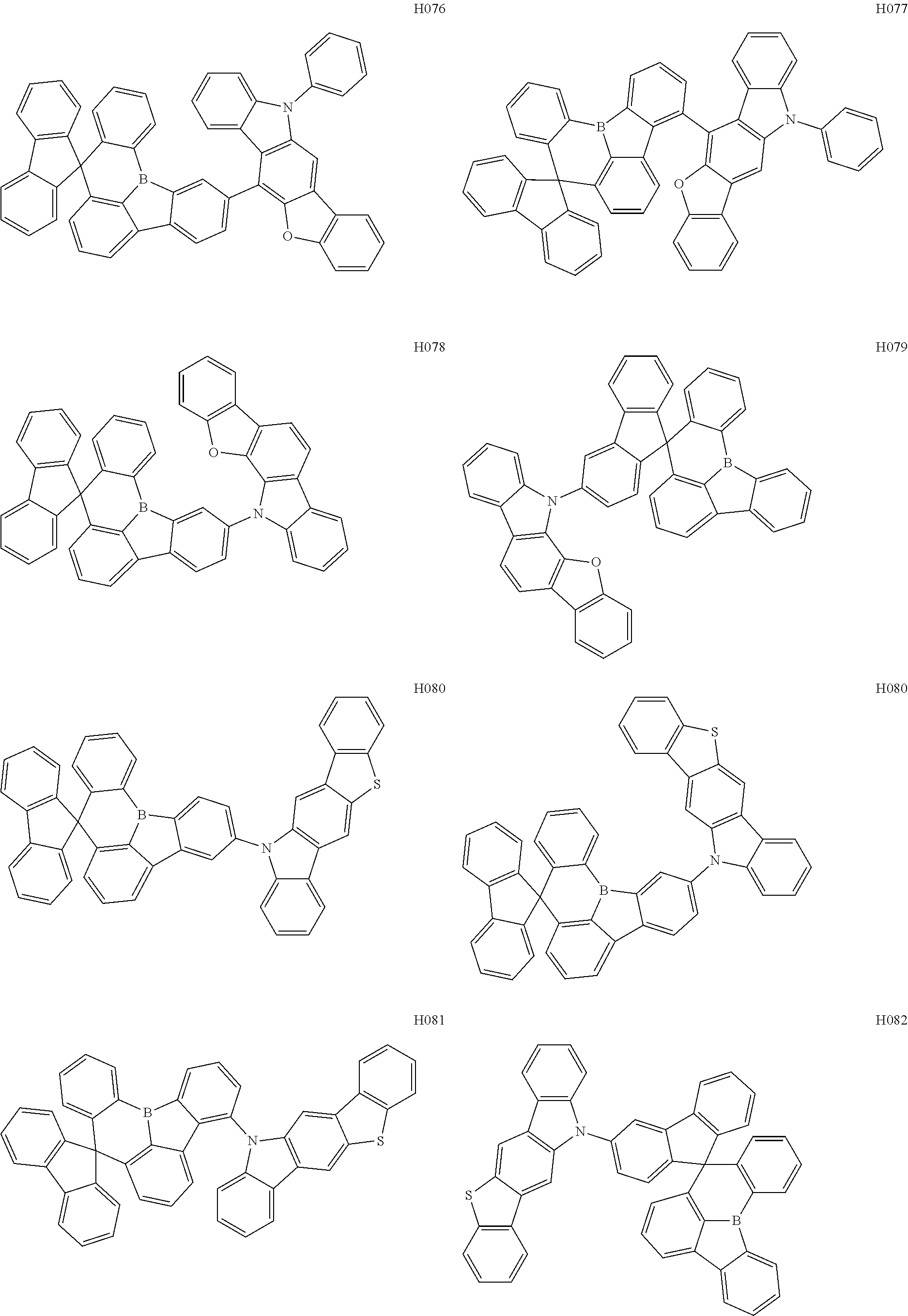

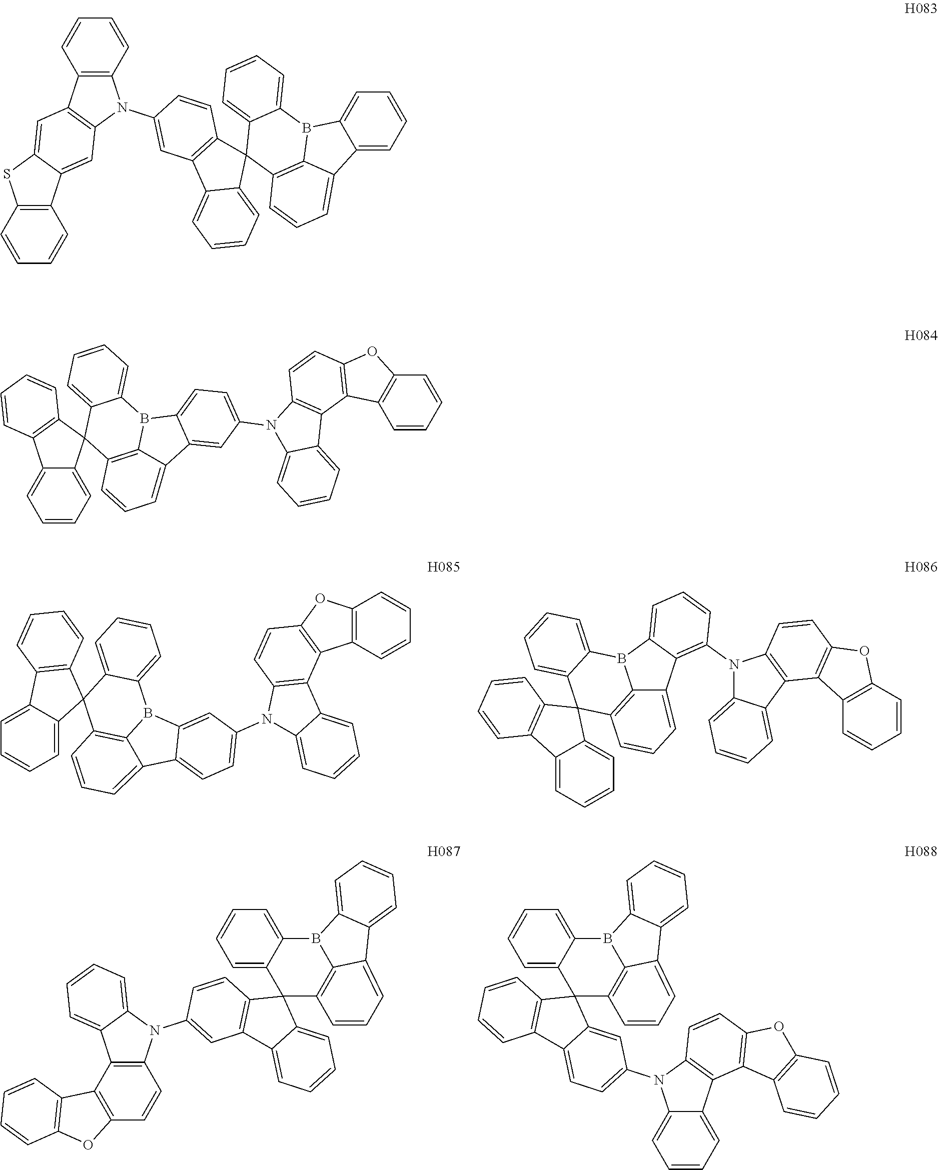

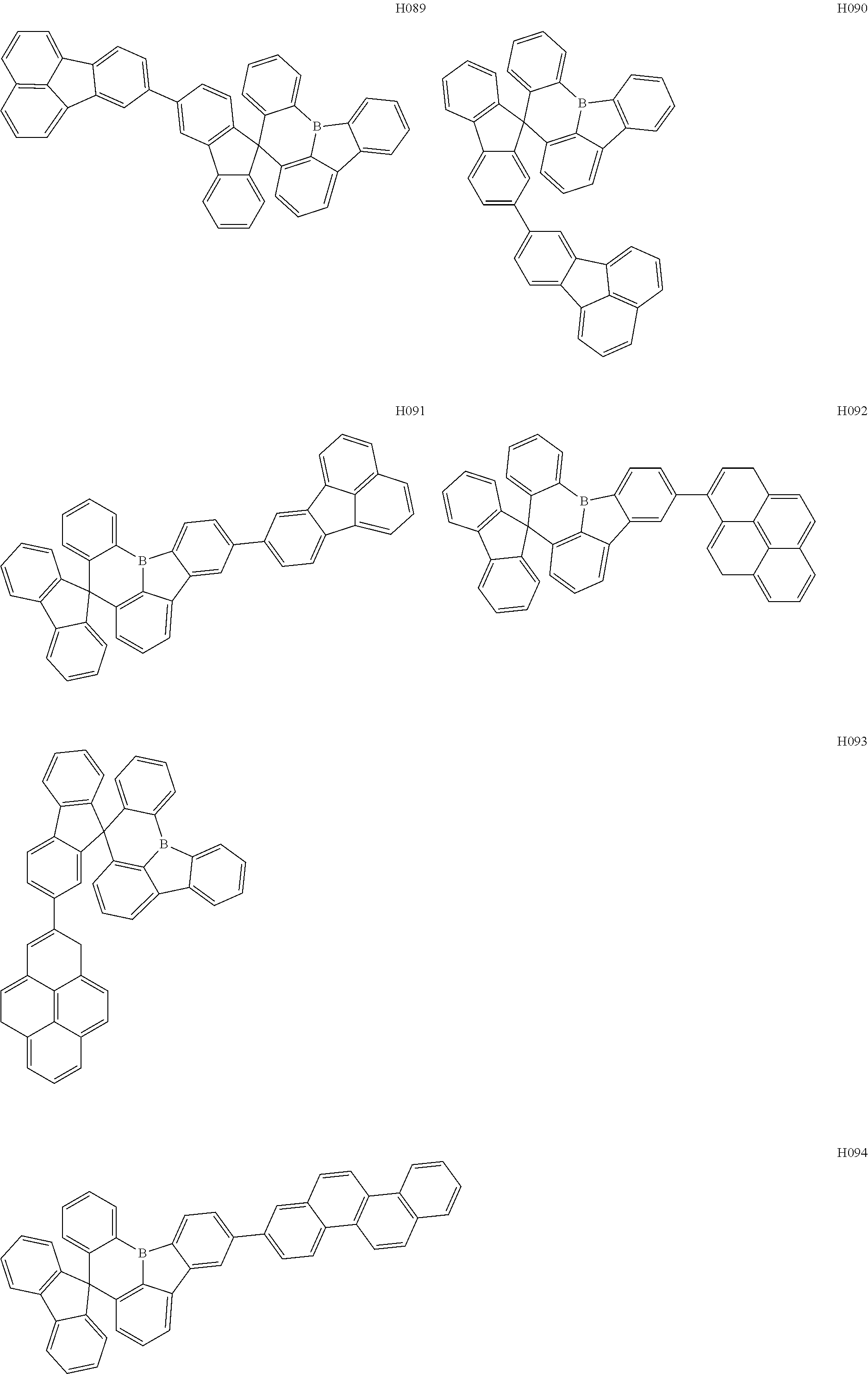

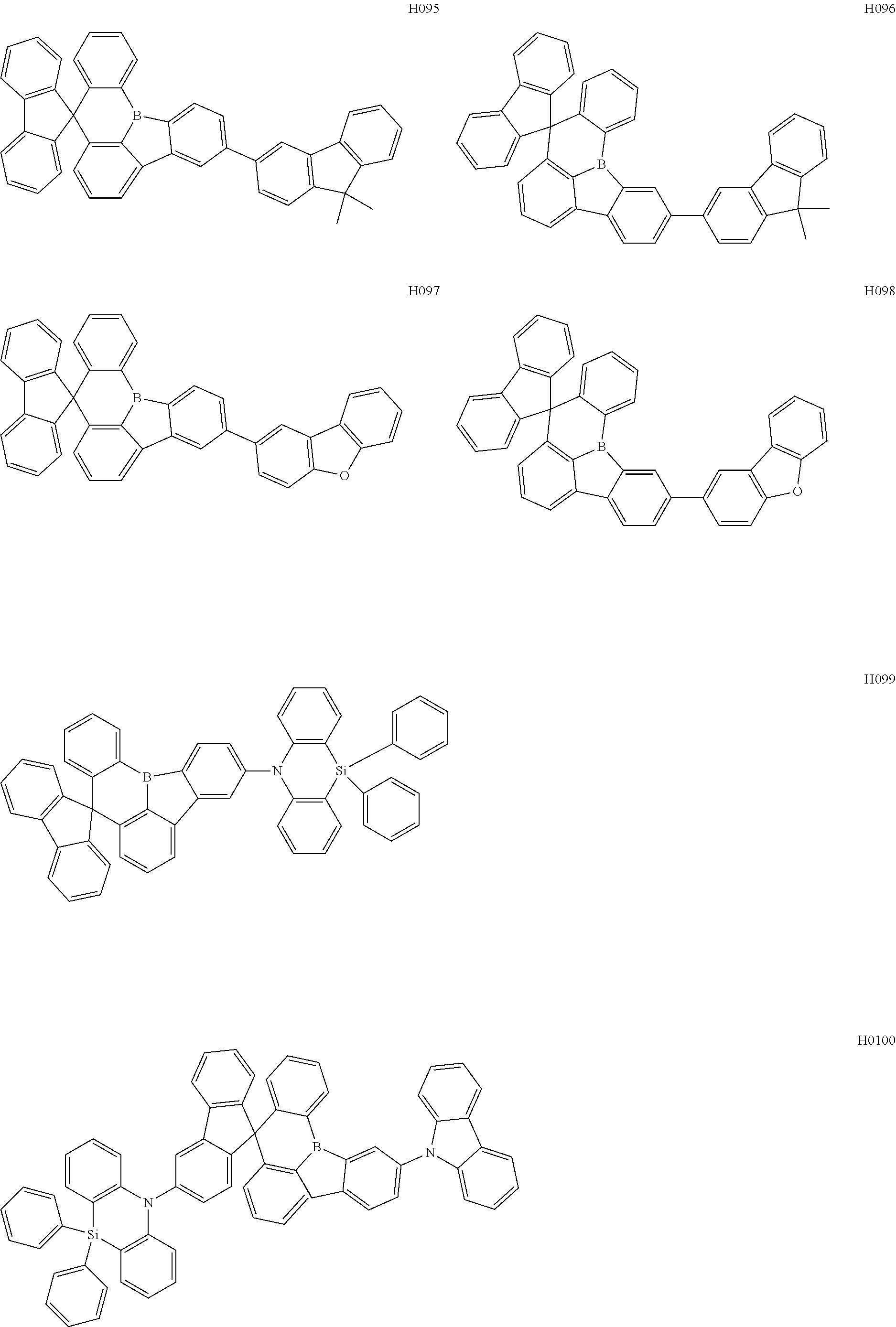

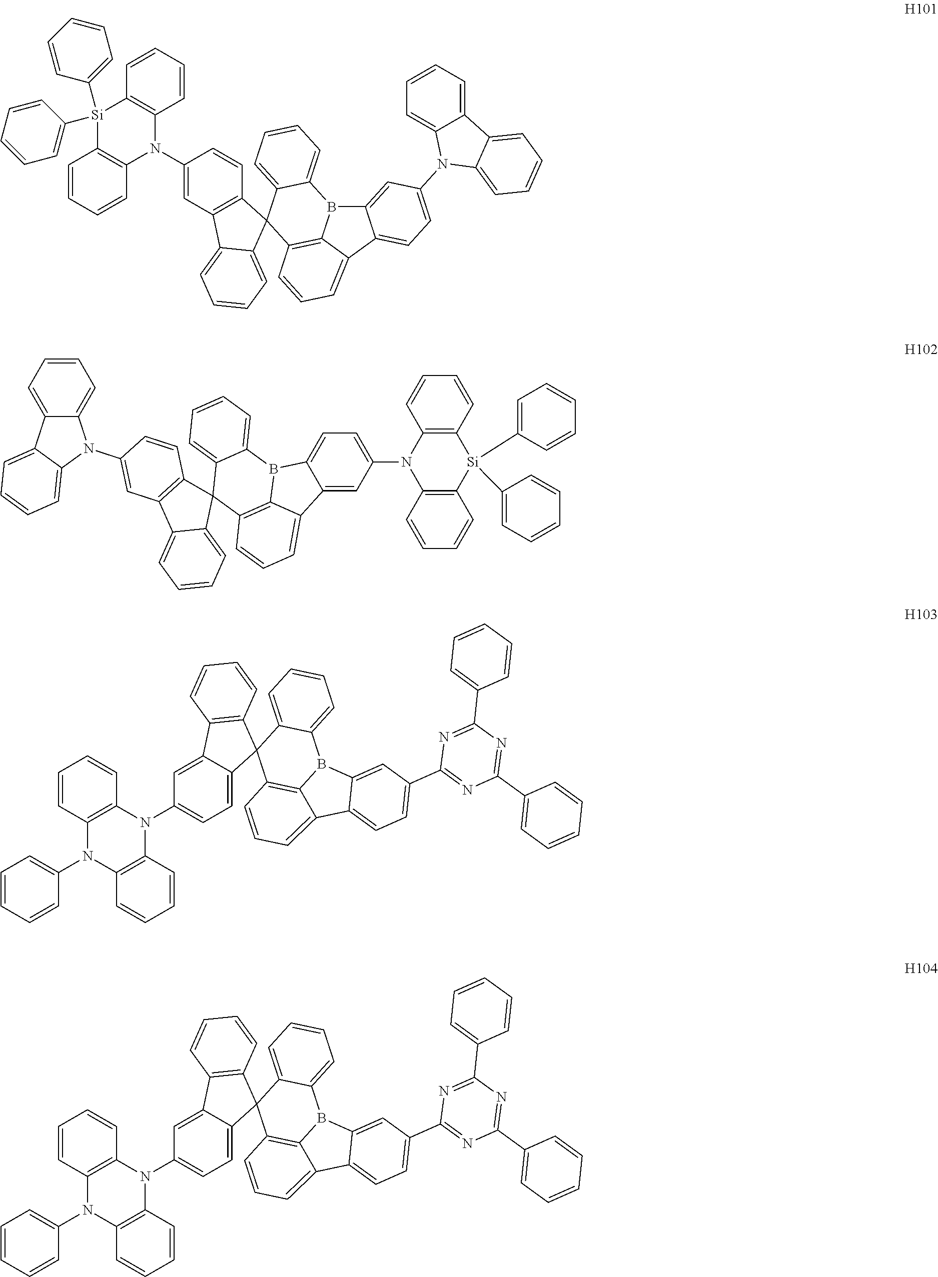 [SMILES: c1ccc([Si]2(c3ccccc3)c3ccccc3N(c3ccc4c(c3)-c3ccccc3C43c4ccccc4B4c5cc(-n6c7ccccc7c7ccccc76)ccc5-c5cccc3c54)c3ccccc32)cc1 ; c1ccc([Si]2(c3ccccc3)c3ccccc3N(c3ccc4c(c3)-c3cccc5c3B4c3ccccc3C53c4ccccc4-c4cc(-n5c6ccccc6c6ccccc65)ccc43)c3ccccc32)cc1 ; c1ccc(-c2nc(-c3ccccc3)nc(-c3ccc4c(c3)B3c5ccccc5C5(c6ccccc6-c6cc(N7c8ccccc8N(c8ccccc8)c8ccccc87)ccc65)c5cccc-4c53)n2)cc1 ; c1ccc(-c2nc(-c3ccccc3)nc(-c3ccc4c(c3)B3c5ccccc5C5(c6ccccc6-c6cc(N7c8ccccc8N(c8ccccc8)c8ccccc87)ccc65)c5cccc-4c53)n2)cc1]

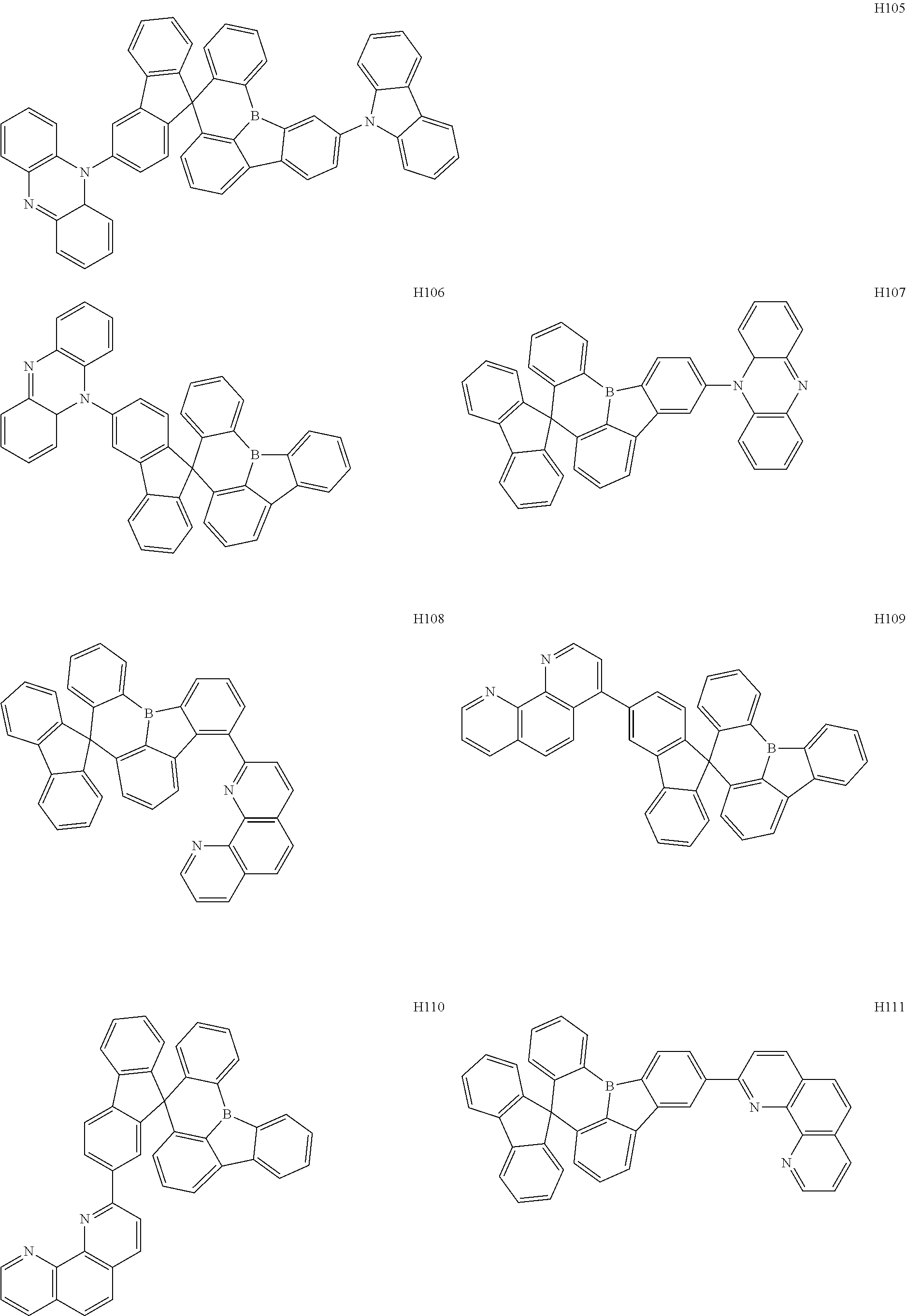

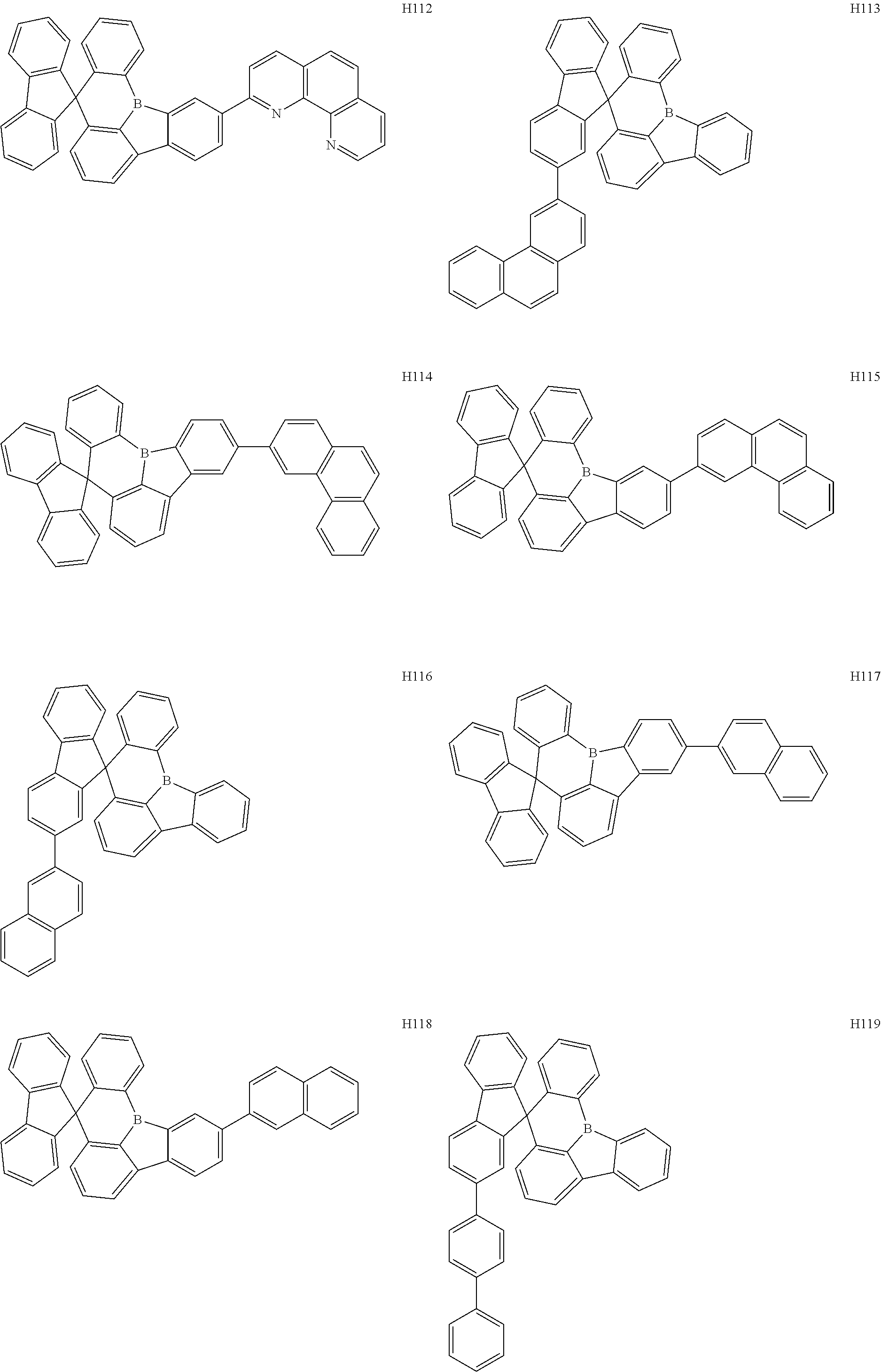

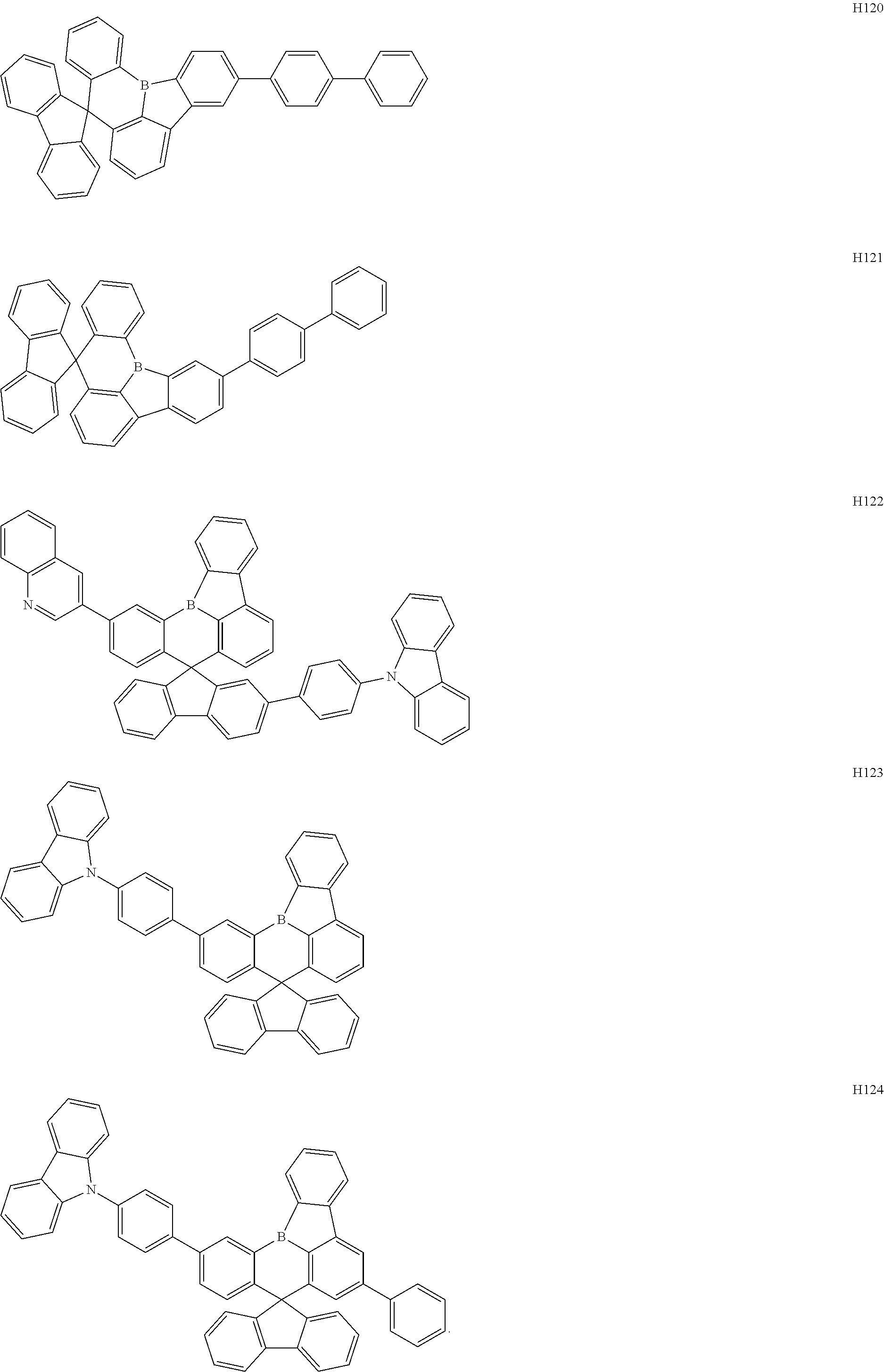 [SMILES: c1ccc(-c2ccc(-c3ccc4c(c3)-c3cccc5c3B4c3ccccc3C53c4ccccc4-c4ccccc43)cc2)cc1 ; c1ccc(-c2ccc(-c3ccc4c(c3)B3c5ccccc5C5(c6ccccc6-c6ccccc65)c5cccc-4c53)cc2)cc1 ; c1ccc2c(c1)B1c3cc(-c4cnc5ccccc5c4)ccc3C3(c4ccccc4-c4ccc(-c5ccc(-n6c7ccccc7c7ccccc76)cc5)cc43)c3cccc-2c31 ; c1ccc2c(c1)B1c3cc(-c4ccc(-n5c6ccccc6c6ccccc65)cc4)ccc3C3(c4ccccc4-c4ccccc43)c3cccc-2c31 ; c1ccc(-c2cc3c4c(c2)C2(c5ccc(-c6ccc(-n7c8ccccc8c8ccccc87)cc6)cc5B4c4ccccc4-3)c3ccccc3-c3ccccc32)cc1]

13. A display panel, comprising an organic light-emitting device, wherein the organic light-emitting device comprises:
an anode;
a cathode arranged opposite to the anode;
a light-emitting layer disposed between the anode and the cathode,
wherein the light-emitting layer comprises a host material and a guest material, and the host material of the light-emitting layer is one or more of the compounds, having a chemical structure represented by formula 1: 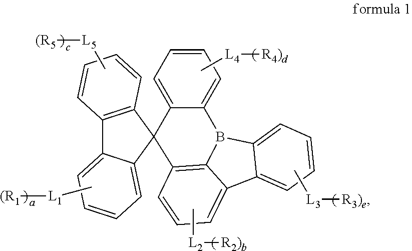
wherein L₁-L₅ are each a linking group independently selected from the group consisting of a single bond, C1-C10 alkylene, C6-C30 arylene, C6-C30 fused arylene, C4-C30 heteroarylene, and C4-C30 fused heteroarylene;
R₁-R₅ are each independently selected from the group consisting of hydrogen, a substituted or unsubstituted phenyl, a substituted or unsubstituted biphenyl, a substituted or unsubstituted naphthyl, a substituted or unsubstituted anthryl, a substituted or unsubstituted phenanthryl, a substituted or unsubstituted acenaphthylenyl, a substituted or unsubstituted pyrenyl, a substituted or unsubstituted perylenyl, a substituted or unsubstituted fluorenyl, a substituted or unsubstituted spirobifluorenyl, a substituted or unsubstituted chrysenyl, a substituted or unsubstituted triphenylenyl, a substituted or unsubstituted benzoanthryl, a substituted or unsubstituted fluoranthenyl, a substituted or unsubstituted picenyl, a substituted or unsubstituted furyl, a substituted or unsubstituted benzofuryl, a substituted or unsubstituted dibenzofuryl, a substituted or unsubstituted thienyl, a substituted or unsubstituted benzothienyl, a substituted or unsubstituted dibenzothienyl, a substituted or unsubstituted triazinyl, a substituted or unsubstituted phenanthrolinyl, a substituted or unsubstituted quinolinyl, carbazolyl and a carbazolyl-derived group, acridinyl and an acridinyl-derived group, diphenylamino and a diphenylamino-derived group, and triphenylamino and a triphenylamino-derived group; and
a, b, c, d, and e are each independently an integer selected from the group consisting of 0, 1, 2, and 3.

14. The display panel according to claim 13, wherein L₁ and L₂ are each independently selected from the group consisting of phenylene, naphthylene, anthrylene, phenanthrylene, pyridylidene, furylidene, pyrimidinylidene, triazinylene, benzofurylene, thienylene, benzothienylene, pyrrolylene, indolylidene, carbazolylene, oxazolylene, benzoxazolylene, thiazolylene, benzothiazolylene, imidazolylene, benzoimidazolylene, indazolylene, quinolylene, and isoquinolylene.

15. The display panel according to claim 13, wherein three of L₁-L₅ are each a single bond, and the other two of L₁-L₅ are each a connecting group selected from the group consisting of C1-C10 alkylene, C6-C30 arylene, C6-C30 fused arylene, C4-C30 heteroarylene, and C4-C30 fused heteroarylene; and
three of R₁-R₅ are each hydrogen, and the other two of R₁-R₅ are each a substituent other than hydrogen.

16. The display panel according to claim 13, wherein one of R₁-R₅ is carbazolyl, and another one of R₁-R₅ is an azaaromatic group.

17. The display panel according to claim 13, wherein one to four of R₁-R₅ are each selected from the group consisting of triphenylamino, carbazolyl, biphenyl, and naphthyl; and the rest of R₁-R₅ is each selected from the group consisting of hydrogen, phenanthrolinyl, and triazinyl.

18. The display panel according to claim 13, wherein the organic light-emitting device further comprises one or more selected from a hole injection layer, a hole transmission layer, an electron blocking layer, a hole blocking layer, an electron transmission layer, or an electron injection layer.

19. A display apparatus, comprising the display panel, wherein the display panel comprises:
an anode;
a cathode arranged opposite to the anode;
a light-emitting layer disposed between the anode and the cathode,
wherein the light-emitting layer comprises a host material and a guest material, and the host material of the light-emitting layer is one or more of the compounds, having a chemical structure represented by formula 1: 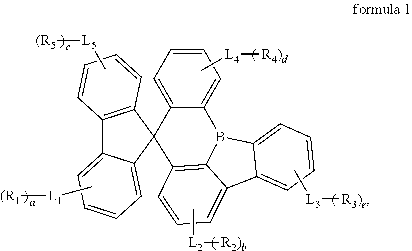
wherein L₁-L₅ are each a linking group independently selected from the group consisting of a single bond, C1-C10 alkylene, C6-C30 arylene, C6-C30 fused arylene, C4-C30 heteroarylene, and C4-C30 fused heteroarylene;
R₁-R₅ are each independently selected from the group consisting of hydrogen, a substituted or unsubstituted phenyl, a substituted or unsubstituted biphenyl, a substituted or unsubstituted naphthyl, a substituted or unsubstituted anthryl, a substituted or unsubstituted phenanthryl, a substituted or unsubstituted acenaphthylenyl, a substituted or unsubstituted pyrenyl, a substituted or unsubstituted perylenyl, a substituted or unsubstituted fluorenyl, a substituted or unsubstituted spirobifluorenyl, a substituted or unsubstituted chrysenyl, a substituted or unsubstituted triphenylenyl, a substituted or unsubstituted benzoanthryl, a substituted or unsubstituted fluoranthenyl, a substituted or unsubstituted picenyl, a substituted or unsubstituted furyl, a substituted or unsubstituted benzofuryl, a substituted or unsubstituted dibenzofuryl, a substituted or unsubstituted thienyl, a substituted or unsubstituted benzothienyl, a substituted or unsubstituted dibenzothienyl, a substituted or unsubstituted triazinyl, a substituted or unsubstituted phenanthrolinyl, a substituted or unsubstituted quinolinyl, carbazolyl and a carbazolyl-derived group, acridinyl and an acridinyl-derived group, diphenylamino and a diphenylamino-derived group, and triphenylamino and a triphenylamino-derived group; and
a, b, c, d, and e are each independently an integer selected from the group consisting of 0, 1, 2, and 3.
